(19) United States
(12) Patent Application Publication
(10) Pub. No.: US 2025/0336672 A1
(43) Pub. Date: Oct. 30, 2025

(54) METHOD FOR FORMING METAL OXIDE LAYER AND METHOD FOR MANUFACTURING SEMICONDUCTOR DEVICE

(71) Applicant: Semiconductor Energy Laboratory Co., Ltd., Atsugi-shi (JP)

(72) Inventors: Shunpei YAMAZAKI, Setagaya (JP); Toshikazu OHNO, Atsugi (JP); Yuji EGI, Atsugi (JP); Fumito ISAKA, Zama (JP)

(21) Appl. No.: 19/175,127

(22) Filed: Apr. 10, 2025

(30) Foreign Application Priority Data
Apr. 26, 2024 (JP) 2024-073124
May 10, 2024 (JP) 2024-077515
May 10, 2024 (JP) 2024-077556
Jan. 28, 2025 (JP) 2025-012375

(51) Int. Cl. H01L 21/02; C30B 25/16; C30B 25/18; C30B 29/16

(52) U.S. Cl. CPC H01L 21/02565; C30B 25/165; C30B 25/186; C30B 29/16

(57) ABSTRACT

A metal oxide layer with high carrier mobility and a method for forming the metal oxide layer are provided. The method for forming the metal oxide layer includes a first step of forming a crystal part and a second step of forming a crystalline metal oxide layer using the crystal part as a nucleus. The metal oxide layer contains indium. The metal oxide layer is formed by an atomic layer deposition method, and a substrate heating temperature is higher than or equal to 150° C. and lower than or equal to 250° C. A crystal orientation of a crystal grain included in the metal oxide layer is <111>, and a crystal orientation of the crystal part is <001>.

### BACKGROUND OF THE INVENTION

### 1. Field of the Invention

One embodiment of the present invention relates to a metal oxide layer, a semiconductor device, a memory device, a display device, and an electronic device. One embodiment of the present invention relates to a method for forming a metal oxide layer and a method for manufacturing a semiconductor device.

Note that one embodiment of the present invention is not limited to the above technical field. Examples of the technical field of one embodiment of the present invention include a semiconductor device, a display device, a light-emitting device, a power storage device, a memory device, an electronic device, a lighting device, an input device (e.g., a touch sensor), an input/output device (e.g., a touch panel), a method for driving any of them, and a method for manufacturing any of them.

In this specification and the like, a semiconductor device means a device that utilizes semiconductor characteristics, and refers to a circuit including a semiconductor element (e.g., a transistor, a diode, or a photodiode), a device including the circuit, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting device, a lighting device, and an electronic device themselves are semiconductor devices and also include a semiconductor device.

### 2. Description of the Related Art

A technique by which a transistor is formed using a semiconductor thin film formed over a substrate having an insulating surface has been attracting attention. The transistor is used in a wide range of electronic devices such as an integrated circuit (IC) and a display device. As semiconductor materials usable for the transistor, silicon-based semiconductor materials have been widely used, but oxide semiconductors have been attracting attention as alternative materials.

A transistor including an oxide semiconductor is known to have an extremely low leakage current in the off state. For example, Patent Document 1 discloses a low-power-consumption central processing unit (CPU) utilizing a characteristic of a low leakage current of the transistor including an oxide semiconductor. For another example, Patent Document 2 discloses a memory device that can retain stored data for a long time by utilizing a characteristic of a low leakage current of the transistor including an oxide semiconductor.

Examples of an oxide semiconductor that can be used for an active layer of a transistor include indium oxide and indium gallium zinc oxide. Non-Patent Document 1 discloses a thin film transistor in which hydrogenated polycrystalline indium oxide formed by low-temperature solid phase crystallization is used for an active layer.

### REFERENCES

### Patent Document

[Patent Document 1] Japanese Published Patent Application No. 2012-257187
[Patent Document 2] Japanese Published Patent Application No. 2011-151383

### Non-Patent Documents

[Non-Patent Document 1] Y. Magari, et al., “High-mobility hydrogenated polycrystalline In₂O₃ (In₂O₃:H) thin-film transistors”, Nature Communications, 13, 1078 (2022)
[Non-Patent Document 2] N. Preissler et al., “Electrical transport, electrothermal transport, and effective electron mass in single-crystalline In₂O₃ films”, Phys. Rev. B, 88, 085305 (2013)
[Non-Patent Document 3] Takashi Koida, “High-mobility transparent conductive film”, National Institute of Advanced Industrial Science and Technology, AIST Photovoltaic Technology Research Symposium 2019, Internet URL: https://unit.aist.go.jp/rpd-envene/PV/ja/results/2019/oral/T13.pdf

### SUMMARY OF THE INVENTION

An object of one embodiment of the present invention is to provide a metal oxide layer with high carrier mobility. An object of one embodiment of the present invention is to provide a novel metal oxide layer. An object of one embodiment of the present invention is to provide a transistor, a semiconductor device, a memory device, or a display device including a metal oxide layer.

An object of one embodiment of the present invention is to provide a transistor with favorable electrical characteristics. An object of one embodiment of the present invention is to provide a transistor with a high on-state current. An object of one embodiment of the present invention is to provide a transistor with small parasitic capacitance. An object of one embodiment of the present invention is to provide a highly reliable transistor, semiconductor device, memory device, or display device. An object of one embodiment of the present invention is to provide a transistor, a semiconductor device, or a memory device which can be miniaturized or highly integrated. An object of one embodiment of the present invention is to provide a semiconductor device, a memory device, or a display device with low power consumption. An object of one embodiment of the present invention is to provide a memory device with high operating speed. An object of one embodiment of the present invention is to provide a method for manufacturing the above-described transistor, semiconductor device, memory device, or display device.

Note that the description of these objects does not preclude the existence of other objects. One embodiment of the present invention does not necessarily achieve all of these objects. Other objects can be derived from the description of the specification, the drawings, and the claims.

One embodiment of the present invention is a method for forming a metal oxide layer including a first step of forming a crystal part and a second step of forming a crystalline metal oxide layer using the crystal part as a nucleus. The metal oxide layer contains indium.

In the method for forming a metal oxide layer, the crystal part is preferably formed from one of grains of a polycrystalline film in the first step.

The method for forming a metal oxide layer preferably further includes a third step of forming an amorphous metal oxide film before the first step. At this time, the crystal part is preferably formed over the amorphous metal oxide film in the first step. Furthermore, the amorphous metal oxide film is preferably crystallized to form the metal oxide layer in the second step.

In the method for forming a metal oxide layer, the metal oxide layer is preferably formed by an atomic layer deposition (ALD) method, and a substrate heating temperature is preferably higher than or equal to 100° C. and lower than or equal to 300° C.

In the method for forming a metal oxide layer, the metal oxide layer is preferably formed by an atomic layer deposition method, and a substrate heating temperature is preferably higher than or equal to 150° C. and lower than or equal to 250° C.

One embodiment of the present invention is a method for forming a metal oxide layer including a first step of forming a crystal part over an insulating layer and a second step of forming a crystalline metal oxide layer over the crystal part. The metal oxide layer contains indium. A top surface of the insulating layer is planarized by a chemical mechanical polishing method before the second step to make an average roughness of the top surface of the insulating layer greater than or equal to 0 nm and less than 3 nm.

In the method for forming a metal oxide layer, crystal growth in a lateral direction is preferably performed in the metal oxide layer on or after the second step.

In the method for forming a metal oxide layer, in the first step, a film to be the crystal part is preferably formed and processed by a wet etching method to form the crystal part.

In the method for forming a metal oxide layer, a crystal orientation of a crystal grain included in the metal oxide layer is preferably <111>.

In the method for forming a metal oxide layer, a crystal orientation of the crystal part is preferably <001>.

In the method for forming a metal oxide layer, the crystal part preferably contains indium, gallium, and zinc, and the crystal part preferably has an atomic ratio of In:Ga:Zn=1:1:1 or in the neighborhood thereof or an atomic ratio of In:Ga:Zn=1:3:2 or in the neighborhood thereof.

In the method for forming a metal oxide layer, a crystal orientation of a crystal grain included in the metal oxide layer is preferably aligned or substantially aligned with a crystal orientation of the crystal part.

In the method for forming a metal oxide layer, the crystal part preferably contains indium.

One embodiment of the present invention is a method for manufacturing a semiconductor device including a first step of forming a crystal part over a first insulating layer, a second step of forming a crystalline metal oxide layer using the crystal part as a nucleus, a third step of processing the metal oxide layer into an island shape, a fourth step of forming a second insulating layer covering the metal oxide layer, a fifth step of forming an opening portion overlapping with the metal oxide layer in the second insulating layer, a sixth step of forming a third insulating layer in the opening portion, and a seventh step of forming a conductive layer over the third insulating layer. The metal oxide layer contains indium.

In the method for manufacturing a semiconductor device, the crystal part is preferably formed from one of grains of a polycrystalline film in the first step.

In the method for manufacturing a semiconductor device, the metal oxide layer is preferably formed by an atomic layer deposition method, and a substrate heating temperature is preferably higher than or equal to 100° C. and lower than or equal to 300° C.

In the method for manufacturing a semiconductor device, the metal oxide layer is preferably formed by an atomic layer deposition method, and a substrate heating temperature is preferably higher than or equal to 150° C. and lower than or equal to 250° C.

One embodiment of the present invention is a method for manufacturing a semiconductor device including a first step of forming a crystal part over a first insulating layer, a second step of forming a crystalline metal oxide layer over the crystal part, a third step of processing the metal oxide layer into an island shape, a fourth step of forming a second insulating layer covering the metal oxide layer, a fifth step of forming an opening portion overlapping with the metal oxide layer in the second insulating layer, a sixth step of forming a third insulating layer in the opening portion, and a seventh step of forming a conductive layer over the third insulating layer. The metal oxide layer contains indium. A top surface of the insulating layer is planarized by a chemical mechanical polishing method before the second step to make an average roughness of the top surface of the insulating layer greater than or equal to 0 nm and less than 3 nm.

In the method for manufacturing a semiconductor device, crystal growth in a lateral direction is preferably performed in the metal oxide layer on or after the second step.

In the method for manufacturing a semiconductor device, in the first step, a film to be the crystal part is preferably formed and processed by a wet etching method to form the crystal part.

In the method for manufacturing a semiconductor device, a crystal orientation of a crystal grain included in the metal oxide layer is preferably <111>.

In the method for manufacturing a semiconductor device, a crystal orientation of the crystal part is preferably <001>.

In the method for manufacturing a semiconductor device, the crystal part preferably contains indium, gallium, and zinc, and the crystal part preferably has an atomic ratio of In:Ga:Zn=1:1:1 or in the neighborhood thereof or an atomic ratio of In:Ga:Zn=1:3:2 or in the neighborhood thereof.

In the method for manufacturing a semiconductor device, a crystal orientation of a crystal grain included in the metal oxide layer is preferably aligned or substantially aligned with a crystal orientation of the crystal part.

In the method for manufacturing a semiconductor device, the crystal part preferably contains indium.

One embodiment of the present invention is a metal oxide layer over an insulating layer, where the metal oxide layer contains indium; the concentration of gallium and the concentration of zinc in the metal oxide layer are each lower than or equal to 0.1 atomic %; the metal oxide layer includes a crystal having a cubic structure; the crystal orientation of the crystal with respect to a top surface of the insulating layer is <111>; and the average roughness of the top surface of the insulating layer is greater than or equal to 0 nm and less than 3 nm.

With one embodiment of the present invention, a metal oxide layer with high carrier mobility can be provided. With one embodiment of the present invention, a novel metal oxide layer can be provided. With one embodiment of the present invention, a transistor, a semiconductor device, a memory device, or a display device including a metal oxide layer can be provided.

With one embodiment of the present invention, a transistor with favorable electrical characteristics can be provided. With one embodiment of the present invention, a transistor with a high on-state current can be provided. With one embodiment of the present invention, a transistor with small parasitic capacitance can be provided. With one embodiment of the present invention, a highly reliable transistor, semiconductor device, memory device, or display device can be provided. With one embodiment of the present invention, a transistor, a semiconductor device, or a memory device which can be miniaturized or highly integrated can be provided. With one embodiment of the present invention, a semiconductor device, a memory device, or a display device with low power consumption can be provided. With one embodiment of the present invention, a memory device with high operating speed can be provided. With one embodiment of the present invention, a method for manufacturing the above-described transistor, semiconductor device, memory device, or display device can be provided.

Note that the description of these effects does not preclude the existence of other effects. One embodiment of the present invention does not necessarily have all of these effects. Other effects can be derived from the description of the specification, the drawings, and the claims.

### BRIEF DESCRIPTION OF THE DRAWINGS

FIGS. 1A to 1E are schematic perspective views illustrating an example of a semiconductor device, and FIG. 1F is a schematic cross-sectional view illustrating the example of the semiconductor device.

FIG. 2A is a cross-sectional view illustrating an indium oxide film, and FIGS. 2B and 2C show the carrier concentration dependence of Hall mobility.

FIG. 3 shows the carrier concentration dependence of the mobility of indium oxide disclosed in Non-Patent Document 2.

FIGS. 4A to 4E illustrate a crystal structure of a metal oxide.

FIG. 5 illustrates crystallinity of a metal oxide.

FIGS. 6A, 6C, 6D, and 6F are schematic perspective views illustrating examples of a semiconductor device, and FIGS. 6B and 6E are schematic cross-sectional views illustrating the examples of the semiconductor device.

FIG. 7 is a diagram for explaining a top surface shape of a layer.

FIGS. 8A to 8C are schematic cross-sectional views illustrating examples of a semiconductor device.

FIGS. 9A, 9C, 9E, and 9G are schematic perspective views illustrating an example of a method for manufacturing a semiconductor device, and FIGS. 9B, 9D, 9F, and 9H are schematic cross-sectional views illustrating the example of the method for manufacturing the semiconductor device.

FIGS. 10A and 10C are schematic perspective views illustrating the example of the method for manufacturing the semiconductor device, and FIGS. 10B and 10D are schematic cross-sectional views illustrating the example of the method for manufacturing the semiconductor device.

FIGS. 11A, 11C, 11E, and 11G are schematic perspective views illustrating examples of a method for manufacturing a semiconductor device, and FIGS. 11B, 11D, 11F, and 11H are schematic cross-sectional views illustrating the examples of the method for manufacturing the semiconductor device.

FIGS. 12A to 12E and FIG. 12G are schematic perspective views illustrating an example of a method for manufacturing a semiconductor device, and FIG. 12F is a schematic cross-sectional view illustrating the example of the method for manufacturing the semiconductor device.

FIGS. 13A to 13D are schematic perspective views illustrating an example of a method for manufacturing a semiconductor device.

FIGS. 14A, 14B, and 14D are schematic perspective views illustrating an example of a method for manufacturing semiconductor device, and FIG. 14C is a schematic cross-sectional view illustrating an example of a semiconductor device.

FIG. 15A is a plan view illustrating an example of a semiconductor device, and FIGS. 15B to 15D are cross-sectional views illustrating the example of the semiconductor device.

FIG. 16A is a plan view illustrating an example of a semiconductor device, and FIGS. 16B to 16D are cross-sectional views illustrating the example of the semiconductor device.

FIG. 17A is a plan view illustrating an example of a semiconductor device, and FIGS. 17B to 17D are cross-sectional views illustrating the example of the semiconductor device.

FIG. 18 is a cross-sectional view illustrating an example of a semiconductor device.

FIGS. 19A to 19C are cross-sectional views illustrating examples of a semiconductor device.

FIG. 20A is a plan view illustrating an example of a semiconductor device, and FIGS. 20B to 20D are cross-sectional views illustrating the example of the semiconductor device.

FIG. 21A is a plan view illustrating an example of a semiconductor device, and FIGS. 21B to 21D are cross-sectional views illustrating the example of the semiconductor device.

FIGS. 22A to 22C are cross-sectional views illustrating examples of a semiconductor device.

FIG. 23A is a plan view illustrating an example of a semiconductor device, and FIGS. 23B to 23D are cross-sectional views illustrating the example of the semiconductor device.

FIG. 24 is a cross-sectional view illustrating an example of a semiconductor device.

FIG. 25A is a plan view illustrating an example of a semiconductor device, and FIGS. 25B to 25D are cross-sectional views illustrating the example of the semiconductor device.

FIG. 26A is a plan view illustrating an example of a semiconductor device, and FIGS. 26B to 26D are cross-sectional views illustrating the example of the semiconductor device.

FIG. 27 is a block diagram illustrating a structure example of a semiconductor device.

FIGS. 28A to 28G illustrate circuit structure examples of a memory cell.

FIG. 29 is a cross-sectional view illustrating an example of a semiconductor device.

FIGS. 30A and 30B are perspective views illustrating structure examples of a semiconductor device.

FIG. 31 is a cross-sectional view illustrating an example of a semiconductor device.

FIG. 32 is a block diagram illustrating a CPU.

FIGS. 33A and 33B are perspective views of a semiconductor device.

FIGS. 34A and 34B are perspective views of semiconductor devices.

FIG. 35 is a conceptual diagram showing a hierarchy of memory devices.

FIGS. 36A and 36B are perspective views illustrating an example of a display device.

FIG. 37 is a cross-sectional view illustrating an example of a display device.

FIG. 38 is a cross-sectional view illustrating an example of a display device.

FIGS. 39A and 39B illustrate examples of an electronic component.

FIGS. 40A to 40C illustrate an example of a large computer, FIG. 40D illustrates an example of space equipment, and FIG. 40E illustrates an example of a storage system that can be used in a data center.

FIGS. 41A to 41F illustrate examples of electronic devices.

FIGS. 42A to 42G illustrate examples of electronic devices.

FIGS. 43A to 43F illustrate examples of electronic devices.

FIG. 44 shows results of measurement with an AFM in Example.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Thus, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of a current or a voltage, switching operation for controlling conduction or non-conduction, and the like. A transistor in this specification includes, in its category, an insulated-gate field effect transistor (IGFET) and a thin film transistor (TFT).

In this specification and the like, a transistor including an oxide semiconductor or a metal oxide in its semiconductor layer and a transistor including an oxide semiconductor or a metal oxide in its channel formation region are each sometimes referred to as an oxide semiconductor (OS) transistor. A transistor including silicon in its channel formation region is sometimes referred to as a Si transistor.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that in this specification and the like, an oxynitride refers to a material in which an oxygen content is higher than a nitrogen content. A nitride oxide refers to a material in which a nitrogen content is higher than an oxygen content. For example, silicon oxynitride refers to a material that contains more oxygen than nitrogen, and silicon nitride oxide refers to a material that contains more nitrogen than oxygen.

Note that in this specification and the like, the term “content percentage” refers to the proportion of a component contained in a film. In the case where an oxide semiconductor layer contains a metal element X, a metal element Y, and a metal element Z whose atomic numbers are respectively represented by A_{X}, A_{Y}, and A_{Z}, the content percentage of the metal element X can be represented by A_{X}/(A_{X}+A_{Y}+A_{Z}). Moreover, in the case where the atomic ratio of the metal element X to the metal element Y to the metal element Z contained in an oxide semiconductor layer is represented by B_{X}:B_{Y}:B_{Z}, the content percentage of the metal element X can be represented by B_{X}/(B_{X}+B_{Y}+B_{Z}).

Note that the terms “film” and “layer” can be used interchangeably depending on the case or the circumstances. For example, the term “conductive layer” can be replaced with the term “conductive film”. As another example, the term “insulating film” can be replaced with the term “insulating layer”.

In this specification and the like, the term “parallel” indicates that the angle subtended between two straight lines is greater than or equal to −10° and less than or equal to 10°. Thus, the case where the angle is greater than or equal to −5° and less than or equal to 5° is also included. The term “substantially parallel” indicates that the angle subtended between two straight lines is greater than or equal to −20° and less than or equal to 20°. The term “perpendicular” indicates that the angle subtended between two straight lines is greater than or equal to 80° and less than or equal to 100°. Thus, the case where the angle is greater than or equal to 85° and less than or equal to 95° is also included. In addition, the term “substantially perpendicular” indicates that the angle subtended between two straight lines is greater than or equal to 70° and less than or equal to 110°.

In this specification and the like, the term “electrically connected” includes the case where components are connected through an “object having any electric function”. There is no particular limitation on the “object having any electric function” as long as electric signals can be transmitted and received between components that are connected through the object. Examples of the “object having any electric function” are a switching element such as a transistor, a resistor, a coil, and an element with a variety of functions as well as an electrode and a wiring.

Note that in this specification and the like, “electrical connection” does not include the case where two nodes are connected to each other with an insulator (e.g., a dielectric of a capacitor, a gate insulating film of a transistor, or an interlayer insulating film) provided between the two nodes.

Note that in this specification and the like, a tapered shape refers to a shape such that at least part of a side surface of a component is inclined with respect to a substrate surface or a formation surface of the component. For example, a tapered shape preferably includes a region where the angle subtended between the inclined side surface and the substrate surface or the formation surface (such an angle is also referred to as a taper angle) is greater than 0° and less than 90°. Note that the side surface of the component, the substrate surface, and the formation surface are not necessarily completely flat and may be substantially planar with a slight curvature or slight unevenness.

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other.

In this specification and the like, a crystal structure of a cubic crystal system is sometimes referred to as a cubic crystal, a cubic crystal structure, or the like. The same applies to the other crystal systems (e.g., a hexagonal crystal system, a trigonal crystal system, a tetragonal crystal system, an orthorhombic crystal system, a monoclinic crystal system, and a triclinic crystal system).

### Embodiment 1

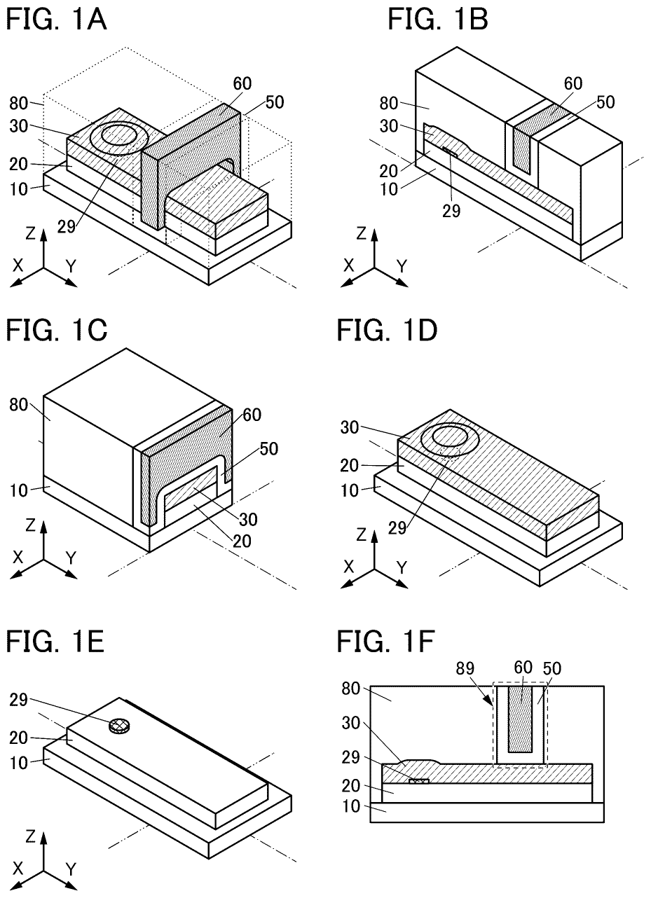

In this embodiment, a semiconductor device of one embodiment of the present invention and a method for manufacturing the semiconductor device will be described with reference to FIG. 1A to FIG. 14D. The semiconductor device of one embodiment of the present invention includes a transistor including a semiconductor layer.

### <Structure of Semiconductor Device>

FIGS. 1A to 1E are schematic perspective views of a semiconductor device. For some components (e.g., insulating layers), only the outlines are indicated by dotted lines in FIG. 1A. FIG. 1B is a schematic perspective view of a portion of FIG. 1A cut along the YZ plane including a dashed-dotted line. FIG. 1C is a schematic perspective view of a portion of FIG. 1A cut along the XZ plane including a dashed double-dotted line. In FIG. 1A to FIG. 1C, the X direction, the Y direction, and the Z direction are indicated by arrows. Although the same reference signs X, Y, and Z are used in

FIGS. 1A to 1C, the directions are not necessarily the same among FIGS. 1A to 1C. Also in the other drawings referred to herein, the X direction, the Y direction, and the Z direction are not necessarily the same among the drawings.

The semiconductor device illustrated in FIGS. 1A to 1C includes a substrate 10, an insulating layer 20 over the substrate 10, a semiconductor layer 30 over the insulating layer 20, an insulating layer 50 over the semiconductor layer 30, and a conductive layer 60 over the insulating layer 50. The semiconductor device includes an insulating layer 80. Note that the semiconductor device of one embodiment of the present invention may include a layer 29.

FIG. 1D illustrates the substrate 10, the insulating layer 20, the layer 29, and the semiconductor layer 30 among the components of the semiconductor device. FIG. 1E illustrates the substrate 10, the insulating layer 20, and the layer 29 among the components of the semiconductor device. FIG. 1F is a cross-sectional view of a portion of FIG. 1A cut along the YZ plane including a dashed-dotted line. As illustrated in FIG. 1F, the insulating layer 80 includes an opening portion 89.

In the transistor of one embodiment of the present invention, the conductive layer 60 functions as a gate electrode, and the insulating layer 50 functions as a gate insulating layer. The semiconductor layer 30 includes a channel formation region. At least part of a region of the semiconductor layer that overlaps with the conductive layer 60 with the insulating layer 50 therebetween functions as the channel formation region.

In the transistor of one embodiment of the present invention, the semiconductor layer 30 including the channel formation region includes a metal oxide functioning as a semiconductor (such a metal oxide is also referred to as an oxide semiconductor). That is, the transistor can be regarded as an OS transistor. In this specification and the like, a semiconductor layer including an oxide semiconductor can be referred to as an oxide semiconductor layer. Since the semiconductor layer 30 includes a metal oxide, the semiconductor layer 30 can be referred to as a metal oxide layer.

When oxygen vacancies (V_{O}) and impurities are in the channel formation region of the oxide semiconductor in an OS transistor, electrical characteristics of the OS transistor easily vary and the reliability thereof may worsen in some cases. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a low carrier concentration.

When an excess amount of oxygen is supplied to the semiconductor layer 30, an electron trap due to excess oxygen is formed in the insulating layer 50. Accordingly, the OS transistor is likely to suffer from positive drift degradation in a positive gate bias-temperature (+GBT) stress test. In other words, the amount of positive drift degradation in the +GBT stress test increases. Thus, in the semiconductor device of one embodiment of the present invention, the impurity concentration in the semiconductor layer 30 is preferably low. An appropriate amount of oxygen is preferably supplied to the semiconductor layer 30. Furthermore, the amount of excess oxygen in the semiconductor layer 30 is preferably reduced.

Indium oxide is preferably used for the semiconductor layer 30. In this case, the semiconductor layer 30 contains indium and oxygen. By increasing the proportion of the number of indium atoms in the total number of atoms of all the metal elements included in the metal oxide, the field-effect mobility of the transistor can be increased. Accordingly, when indium oxide is used for the semiconductor layer 30, the transistor can have a high on-state current and excellent frequency characteristics.

Furthermore, the indium oxide film preferably has crystallinity. For example, the indium oxide film preferably includes a crystal grain. Examples of the film including a crystal grain include a single crystal film, a polycrystalline film, and an amorphous film including a crystal grain. A polycrystalline film is regarded as being formed of two or more crystal grains, whereas a single crystal film is regarded as being formed of one crystal grain. A crystal grain boundary (also referred to as a grain boundary) is observed in the polycrystalline film, whereas a crystal grain boundary is not observed in the single crystal film.

Note that unlike in a polycrystalline film, a crystal grain boundary is not observed in a channel formation region in a single crystal film. Impurities that block the carrier flow (typically, an insulating impurity, an insulating oxide, or the like) are likely to be segregated at a crystal grain boundary. Thus, in the case where a crystal grain boundary exists in a channel formation region, a variation in transistor characteristics is large. Meanwhile, a single crystal film of one embodiment of the present invention where no crystal grain boundary is observed in a channel formation region produces an excellent effect of inhibiting a variation in transistor characteristics due to a crystal grain boundary.

In this specification and the like, a semiconductor layer where no crystal grain boundary is observed in a channel formation region, a semiconductor layer where a channel formation region is included in one crystal grain, or a semiconductor layer where the directions of crystal axes of at least two regions in a channel formation region are the same can be referred to as a single crystal film. Furthermore, a semiconductor layer where at least one crystal orientation faces the same direction in a channel formation region can be referred to as a single crystal film.

Note that a channel formation region refers to a region of a semiconductor layer that overlaps with (or faces) a gate electrode with a gate insulating layer therebetween and is positioned between a region in contact with a source electrode and a region in contact with a drain electrode. Note that a semiconductor layer where no crystal grain boundary is observed in a region between a region in contact with a source electrode and a region in contact with a drain electrode, a semiconductor layer where a region between a region in contact with a source electrode and a region in contact with a drain electrode is included in one crystal grain, or a semiconductor layer where the directions of crystal axes of at least two regions, which are positioned between a region in contact with a source electrode and a region in contact with a drain electrode, are the same can also be referred to as a single crystal film. Furthermore, a semiconductor layer where at least one crystal orientation faces the same direction in a region between a region in contact with a source electrode and a region in contact with a drain electrode can be referred to as a single crystal film.

Note that in the channel formation region, a current path is the shortest distance between a source electrode and a drain electrode. Thus, a crystal grain, a crystal grain boundary, a crystal axis, a crystal orientation, and the like in the above-described channel formation region or the region positioned between the region in contact with the source electrode and the region in contact with the drain electrode can be confirmed by observation of a cross section including the semiconductor layer, the source electrode, and the drain electrode.

The crystallinity of the semiconductor layer 30 can be analyzed with X-ray diffractometry (XRD), transmission electron microscopy (TEM), or electron diffraction (ED), for example. Alternatively, these methods may be combined to be employed for analysis.

A crystal grain can be observed in a high-resolution transmission electron microscope (TEM) image, for example. In addition, a crystal grain boundary can sometimes be observed in a high-resolution TEM image, for example. That is, a crystal grain and a crystal grain boundary of a film having crystallinity can sometimes be observed in a high-resolution TEM image. The total magnification at the time of obtaining a TEM image is preferably greater than or equal to 2000000 times, further preferably greater than or equal to 4000000 times.

The indium oxide film is further preferably a single crystal. Since a single crystal does not include a crystal grain boundary, carrier scattering or the like at a crystal grain boundary can be inhibited, and a transistor having high field-effect mobility can be achieved. In addition, the transistor can have high reliability.

The indium oxide film may be polycrystalline or may be amorphous with crystal grains. In that case, it is preferable that no crystal grain boundary be observed or the number of grain boundary components be small in the channel formation region. For example, when one crystal grain is positioned in a channel formation region, a structure where no crystal grain boundary is observed in the channel formation region can be obtained. Such a structure can also have an effect similar to that of the structure in which the indium oxide film is a single crystal.

Two or more crystal grains can be positioned in the channel formation region. For example, in the case where a first crystal grain and a second crystal grain are positioned in the channel formation region, it is preferable that the crystal orientation of the first crystal grain be aligned or substantially aligned with the crystal orientation of the second crystal grain. In the case where the crystal orientation of the first crystal grain is aligned or substantially aligned with the crystal orientation of the second crystal grain, a crystal grain boundary is sometimes not observed at the boundary between the first crystal grain and the second crystal grain. When the crystal orientation of the first crystal grain is aligned or substantially aligned with the crystal orientation of the second crystal grain, the formation of the crystal grain boundary between the first crystal grain and the second crystal grain can be inhibited. Thus, such a structure can also produce an effect similar to that of the structure in which the indium oxide film is a single crystal. Note that a state where the crystal orientation of the first crystal grain is aligned or substantially aligned with the crystal orientation of the second crystal grain can sometimes be observed in a high-resolution TEM image, for example. Specifically, this state can be observed in a high-resolution TEM image showing continuous connection between the lattice fringes of the first crystal grain and the lattice fringes of the second crystal grain at the boundary between the first crystal grain and the second crystal grain.

In this specification and the like, a crystal grain boundary refers to a boundary between adjacent crystal grains with different crystal orientations, for example. Thus, in this specification and the like, a crystal grain boundary does not include a boundary between adjacent crystal grains with the same crystal orientation. For example, in the case where a boundary is observed between two crystal grains in a high-resolution TEM image but the crystal orientations of the two crystal grains are aligned or substantially aligned with each other, the boundary is not referred to as a crystal grain boundary in some cases.

The crystal orientation can be analyzed with a diffraction pattern obtained by nanobeam electron diffraction (NBED) (the diffraction pattern is also referred to as a nanobeam electron diffraction pattern). The crystal orientation can also be analyzed with a pattern obtained by performing fast Fourier transform (FFT) processing on a TEM image (the pattern is also referred to as an FFT pattern). The FFT pattern reflects reciprocal lattice space information like the above-mentioned diffraction pattern.

For example, in the case where the difference in the angle of the FFT pattern between the FFT pattern of the first crystal grain and the FFT pattern of the second crystal grain is greater than or equal to −5° and less than or equal to 5°, preferably greater than or equal to −3° and less than or equal to 3°, further preferably greater than or equal to −2° and less than or equal to 2°, it can be said that the crystal orientation of the first crystal grain and the crystal orientation of the second crystal grain are aligned or substantially aligned with each other. Note that the angle of the FFT pattern in the direction refers to, for example, an acute angle formed by an approximate straight line between one or both of a spot derived from the (222) plane and a spot derived from the (−2−2−2) plane and a spot at the center and a reference line (e.g., a vertically extending straight line).

The degree of the polycrystallinity of an indium oxide film can be evaluated from a crystal grain size. The crystal grain size can be calculated, for example, as the diameter of a perfect circle assumed to have an area equivalent to the calculated area of the crystal grain. The diameter here is sometimes referred to as an equivalent circular area diameter or the like.

The degree of the polycrystallinity of an indium oxide film can also be evaluated from the extension length of a grain boundary. The extension length of a grain boundary can be calculated as, for example, the total length of crystal grain boundaries observed in a field of view of a specific area extracted from a TEM image of a film obtained at a total magnification at which the crystal grain boundaries can be observed. An indium oxide film in which the extension length of a grain boundary is 0 nm can be regarded as a single crystal. As the extension length of a grain boundary is longer, the number of grain boundary components is larger.

The extension length of a grain boundary in an indium oxide film is preferably longer than or equal to 0 nm and shorter than or equal to 1500 nm, further preferably longer than or equal to 0 nm and shorter than or equal to 1000 nm, still further preferably longer than or equal to 0 nm and shorter than or equal to 800 nm. When the semiconductor layer 30 includes an indium oxide film in which the extension length of a grain boundary falls within the above-described range, a structure where no crystal grain boundary is observed or the number of grain boundary components is small in a channel formation region can be achieved. In this specification and the like, the area of a field of view used to calculate the extension length of a grain boundary is 90 nm square, unless otherwise specified.

The thickness of the semiconductor layer 30 is preferably greater than or equal to 2 nm and less than or equal to 50 nm, further preferably greater than or equal to 2.5 nm and less than or equal to 30 nm, still further preferably greater than or equal to 2.5 nm and less than or equal to 20 nm, yet further preferably greater than or equal to 5 nm and less than or equal to 20 nm, yet still further preferably greater than or equal to 5 nm and less than or equal to 10 nm. Note that the semiconductor layer 30 at least partly includes a region with the above-described thickness. For example, the channel formation region in the semiconductor layer 30 includes a region with the above-described thickness. When the thickness of the semiconductor layer 30 is increased, the on-state current of the transistor can be increased. Meanwhile, when the thickness of the semiconductor layer 30 is too large, the extension length of the grain boundary is increased, which might cause the on-state current of the transistor to be lowered owing to the influence of carrier scattering at the crystal grain boundary. When the thickness of the semiconductor layer 30 is reduced, a reduction in threshold voltage can be inhibited, so that the transistor can be normally-off. Meanwhile, when the thickness of the semiconductor layer 30 is too small, the crystallinity of the semiconductor layer 30 might vary in the substrate plane and the electrical characteristics of the transistor might vary. Thus, when the thickness of the semiconductor layer 30 is within the above-described range, the crystallinity of the semiconductor layer 30 can be increased. Increasing the crystallinity of the semiconductor layer 30 enables the semiconductor layer 30 to include a crystal grain.

In the case where a metal oxide contains indium and zinc, the metal oxide sometimes has a c-axis aligned crystalline (CAAC) structure. The CAAC structure has fewer crystal grain boundaries in the a-b plane than a polycrystalline structure. Examples of the metal oxide containing indium and zinc include indium zinc oxide (also referred to as In—Zn oxide or IZO (registered trademark)) and indium gallium zinc oxide (also referred to as In—Ga—Zn oxide or IGZO).

In an oxide semiconductor layer having crystallinity, one or both of hydrogen and oxygen move more easily in an indium oxide film than in an IGZO film, for example. Thus, it can be said that one or both of hydrogen and oxygen are more likely to be supplied to and released from an indium oxide film than to/from an IGZO film, for example. Note that an indium oxide film can be regarded as having a higher property of transmitting one or both of hydrogen and oxygen than an IGZO film, for example. In other words, an indium oxide film can be regarded as having a lower barrier property against one or both of hydrogen and oxygen than an IGZO film, for example.

The indium oxide film preferably has a property of transmitting oxygen at 1×10²⁰ atoms/cm³ or higher and 2×10²¹ atoms/cm³ or lower, preferably 2×10²⁰ atoms/cm³ or higher and 1×10²¹ atoms/cm³ or lower, for example, in heat treatment at a heating temperature of 400° C. for a treatment time of 8 hours. The indium oxide film preferably has a property of diffusing oxygen at 1×10²⁰ atoms/cm³ or higher and 2×10²¹ atoms/cm³ or lower, preferably 2×10²⁰ atoms/cm³ or higher and 1×10²¹ atoms/cm³ or lower, for example, through the crystal grain by heat treatment at a heating temperature of 400° C. for a treatment time of 8 hours.

When oxygen in the indium oxide film diffuses into a crystal grain and a crystal grain boundary, V_{O} present in the crystal grain or the crystal grain boundary can be reduced. Accordingly, electric characteristics and reliability of the transistor can be improved.

The properties of transmitting oxygen and hydrogen in the film can be evaluated by calculation using a nudged elastic band (NEB) method, for example. Specifically, the properties can be evaluated using migration barriers against an oxygen atom and a hydrogen atom obtained by the calculation using the NEB method. As the value of the migration barrier is smaller, the corresponding atom moves (is transmitted) more easily.

Table 1 shows examples of calculation results. In Table 1, In₂O₃ is a crystal model of indium oxide and IGZO is a crystal model of In—Ga—Zn oxide. The term “excess oxygen” in Table 1 refers to oxygen that is not positioned in an oxygen site of a crystal lattice or oxygen that is positioned between lattices.

TABLE 1

| | In₂O₃ | IGZO |
|---|---|---|
| Oxygen migration barrier | 0.85 eV | 1.88 eV |
| Hydrogen migration barrier | 0.34 eV | 1.39 eV |
| Excess oxygen migration barrier | 1.25 eV | 1.43 eV |

According to Table 1, the migration barriers against oxygen, hydrogen, and excess oxygen in the crystal model of indium oxide are lower than those in the crystal model of In—Ga—Zn oxide. This indicates that oxygen and hydrogen move (are transmitted) more easily in the indium oxide than in the In—Ga—Zn oxide. It is also indicated that the indium oxide film has higher properties of transmitting an oxygen atom and a hydrogen atom than the In—Ga—Zn oxide film. It is thus presumed that hydrogen and oxygen are easily supplied to and released from the indium oxide film. Furthermore, an effect of filling V_{O} generated in the +GBT test with oxygen will be produced, probably achieving a highly reliable transistor.

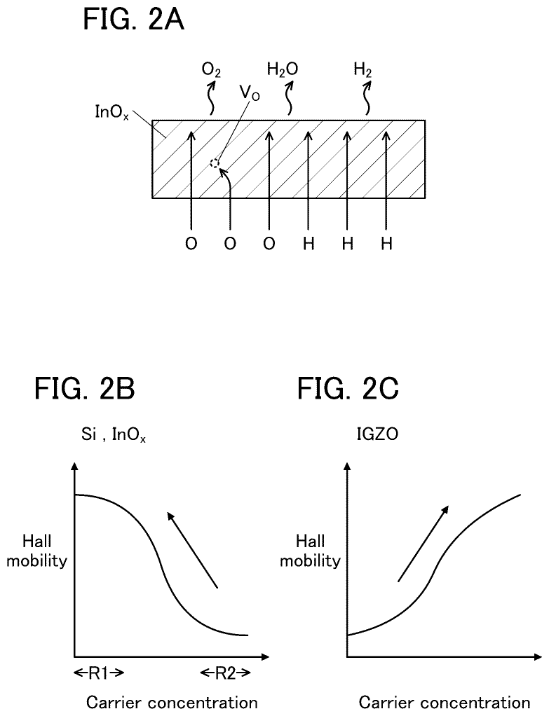

Thus, as shown in FIG. 2A, oxygen (O) diffusing into an indium oxide film (denoted as InO_{X}) is transmitted through the indium oxide film and released as an oxygen molecule (O₂). When reacting with hydrogen contained in the film, oxygen is released as a water molecule (H₂O) in some cases. In the case where the film includes oxygen vacancies (V_{O}), the oxygen vacancies are filled with diffusing oxygen atoms. Since oxygen easily diffuses in the indium oxide film, oxygen vacancies in the indium oxide film are filled with oxygen more easily than those in an IGZO film. As described above, the oxygen vacancies in the indium oxide film are reduced more easily than those in the IGZO film; thus, a transistor including such an indium oxide film can have extremely high reliability.

As shown in FIG. 2A, hydrogen diffuses in the indium oxide film. Hydrogen diffusing into the indium oxide film from the outside is transmitted through the indium oxide film and is released as a hydrogen molecule (H₂). By reacting with oxygen contained in the film as described above, hydrogen is released as a water molecule.

The content percentage of a first element in the semiconductor layer 30 is preferably low. In addition, the concentration of the first element in the semiconductor layer 30 is preferably low. In particular, the concentration of the first element in the channel formation region is preferably low. Here, the first element is at least one of boron, carbon, aluminum, silicon, zinc, and gallium. That is, in the semiconductor layer 30, the concentration of any one of boron, carbon, aluminum, silicon, zinc, and gallium is preferably low, the concentrations of two elements selected from boron, carbon, aluminum, silicon, zinc, and gallium are further preferably low, and the concentrations of all of boron, carbon, aluminum, silicon, zinc, and gallium are still further preferably low. The concentration of the first element in the semiconductor layer 30 is preferably lower than or equal to 1 atomic %, further preferably lower than or equal to 0.1 atomic %, still further preferably lower than or equal to 0.01 atomic % (100 ppm), for example. Note that the preferable concentration of the first element in the semiconductor layer 30 can be rephrased as a preferable concentration of the first element in the channel formation region.

As described later, the concentration of the first element in the semiconductor layer 30 can be lower than or equal to 0.01 atomic % (100 ppm), lower than or equal to 0.0001% (1 ppm), lower than or equal to 0.00001% (0.1 ppm or 100 ppb), or lower than or equal to 0.0000001% (0.001 ppm or 1 ppb) by using a precursor which has been subjected to distillation at least once. That is, the content percentage (purity) of indium excluding oxygen in the semiconductor layer 30 can be higher than or equal to 99.99 atomic % (4N), higher than or equal to 99.9999 atomic % (6N), higher than or equal to 99.99999 atomic % (7N), or higher than or equal to 99.9999999 atomic % (9N), which may enable the semiconductor layer 30 to have a purity substantially the same as the purity of silicon (10N) used for the semiconductor layer.

When the concentrations of boron, carbon, aluminum, and silicon in the semiconductor layer 30 are reduced, the crystallinity of the semiconductor layer 30 can be improved.

In the case where the semiconductor layer 30 contains a gallium atom, the gallium atom is bonded to an excess oxygen atom to form a Ga—O structure. The Ga—O structure functions as an acceptor that traps electrons. Thus, in the transistor including the semiconductor layer 30 containing a gallium atom and an excess oxygen atom, the amount of threshold voltage change in a positive bias temperature stress (PBTS) test is large. Reducing the concentration of gallium in the semiconductor layer 30 can reduce the amount of threshold voltage change in the PBTS test. Accordingly, the transistor can be highly reliable against positive bias application. A phenomenon similar to that in the case where the semiconductor layer 30 contains a gallium atom occurs also in the case where the semiconductor layer 30 contains a zinc atom.

Furthermore, an aluminum atom, a gallium atom, and a zinc atom have higher bonding strength with an oxygen atom than an indium atom does. Therefore, lowering the concentration of aluminum, gallium, and zinc in the indium oxide film can inhibit a reduction in the oxygen-transmitting property.

Furthermore, an impurity, such as the first element, contained in the indium oxide film can serve as a crystal nucleus. By reducing impurities in the indium oxide film as much as possible, the number of crystal nuclei can be small, and an increase in the crystal grain size can be promoted as described later.

In the case where the indium oxide film is a polycrystalline film, the first element is segregated at the crystal grain boundary, so that an oxide containing the first element is formed. The oxide has an insulating property and thus might cause a decrease in the on-state current or field-effect mobility of the transistor. By reducing the first element in the indium oxide film as much as possible, the on-state current or field-effect mobility of the transistor can be increased.

Furthermore, by reducing impurities in the indium oxide film, impurity scattering can be inhibited. Thus, a transistor having high field-effect mobility can be achieved. For example, when the concentration of the first element in the semiconductor layer 30 is within the above-described preferred range, the field-effect mobility of the transistor can be higher than or equal to 100 cm²/(V·s), preferably higher than or equal to 150 cm²/(V·s), further preferably higher than or equal to 200 cm²/(V·s), still further preferably higher than or equal to 250 cm²/(V·s).

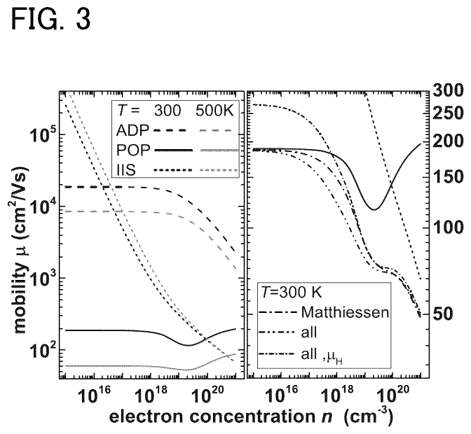

According to the report of Non-Patent Document 2 (see FIG. 3), the upper limit of the Hall mobility calculated assuming that ionized impurities and polar optical phonon are the main factors in scattering in indium oxide is 270 cm²/(V·s).

Here, the dependence of the Hall mobility on the carrier concentration of indium oxide, silicon, and IGZO will be described. FIG. 2B is a schematic view showing the dependence of the Hall mobility on the carrier concentration of silicon (Si) and indium oxide (InO_{X}), and FIG. 2C is a schematic view showing the dependence of the Hall mobility on the carrier concentration of IGZO.

As indicated by an arrow in FIG. 2C, IGZO has a tendency in which the Hall mobility is higher as the carrier concentration is higher. By contrast, as indicated by an arrow in FIG. 2B, indium oxide has a tendency in which the Hall mobility is higher as the carrier concentration is lower (see Non-Patent Document 3). This tendency is similar to that of silicon; as the concentration of a dopant (impurity) in a material is lower, impurity scattering is inhibited more and thus the Hall mobility is higher. That is, indium oxide having higher purity and being more intrinsic has higher Hall mobility. Consequently, the physical properties of indium oxide are different from those of IGZO and similar to those of silicon. Note that the characteristics of indium oxide in FIG. 2B are based on the assumption of single crystal indium oxide; thus, the characteristics of non-single-crystal (e.g., polycrystalline)indium oxide are sometimes different from those in FIG. 2B.

In FIG. 2B, the Hall mobility is extremely high in a range R1 with a low carrier concentration; thus, the range R1 can be regarded as a carrier concentration range suitable for a channel formation region of a transistor, for example. In the case of indium oxide, for example, the range R1 is a range including a carrier concentration of 1×10¹⁵ cm⁻³, e.g., a range with a carrier concentration higher than or equal to 1×10¹⁴ cm⁻³ and lower than or equal to 1×10¹⁸ cm⁻³. The adequately lowered carrier concentration will increase the Hall mobility to approximately 270 cm²/(V·s).

A region of indium oxide where the carrier concentration falls within the range R1 can include an element that reduces the carrier concentration. Examples of the element that reduces the carrier concentration include magnesium, calcium, zinc, cadmium, and copper. When indium is replaced with any of these elements, the carrier concentration can be reduced. Other examples of the element that reduces the carrier concentration include nitrogen, phosphorus, arsenic, and antimony. For example, when oxygen is replaced with nitrogen, phosphorus, arsenic, or antimony, the carrier concentration can be reduced.

A range R2 with a high carrier concentration has low electric resistance and is a carrier concentration range suitable for a source region and a drain region of a transistor, a resistor, or a transparent conductive film, for example. The range R2 is a range including a carrier concentration of 1×10²⁰ cm⁻³, e.g., a range with a carrier concentration higher than or equal to 1×10¹⁹ cm⁻³ and lower than or equal to 1×10²² cm⁻³. The adequately increased carrier concentration will decrease the resistivity to 1×10⁻⁴ Ω-cm or lower.

A region of indium oxide where the carrier concentration falls within the range R2 can include an element that increases the carrier concentration. For example, the region preferably includes the same element as a source electrode and a drain electrode of a transistor. Examples of the element that increases the carrier concentration include titanium, tantalum, tungsten, molybdenum, tin, silicon, germanium, zirconium, hafnium, and boron. It is particularly preferable that an oxide of the element have conductivity or semiconductor properties.

In this manner, the region with a low carrier concentration and the region with a high carrier concentration of indium oxide are used as a channel formation region and source and drain regions, respectively, of a transistor. That is, indium oxide can be regarded as an oxide whose valence electron can be controlled. Although valence electron control in a transistor containing silicon is generally known, valence electron control in a transistor containing indium oxide is a novel technical idea that cannot be conceived usually. With the use of this technical idea, a transistor that has high mobility, has a low off-state current, and can be normally off can be achieved.

The concentration of the first element can be evaluated by, for example, inductively coupled plasma-mass spectrometry (ICP-MS), XPS, secondary ion mass spectrometry (SIMS), time-of-flight secondary ion mass spectrometry (ToF-SIMS), auger electron spectroscopy (AES), energy dispersive X-ray spectroscopy (EDX), inductively coupled plasma-atomic emission spectroscopy (ICP-AES), or the like.

Hydrogen contained in an oxide semiconductor reacts with oxygen bonded to a metal atom to produce water, and thus causes an oxygen vacancy in some cases. Accordingly, the electrical characteristics easily vary, and the reliability is degraded in some cases. Meanwhile, hydrogen at a crystal grain boundary sometimes terminates a dangling bond at the crystal grain boundary to improve the electrical characteristics and reliability of the transistor. Thus, the hydrogen concentration in the indium oxide film is preferably reduced, but may be higher than the concentration of the first element.

The band gap of indium oxide is greater than or equal to 2.5 eV and less than or equal to 3.7 eV. The use of indium oxide having a wider band gap than silicon for the semiconductor layer 30 leads to a low off-state current of the transistor, so that the power consumption of the semiconductor device can be sufficiently reduced.

An OS transistor is an accumulation transistor in which electrons are majority carriers. That is, carriers in an OS transistor are electrons. Assuming that the relaxation time of carriers is constant, the electron (carrier) mobility is higher as the effective mass of electrons (carriers) is smaller. That is, a transistor in which a metal oxide with a small effective mass of electrons is used for a semiconductor layer can have a high on-state current or high field-effect mobility.

Table 2 shows the effective mass in each of single crystal indium oxide (here, In₂O₃) and single crystal silicon (Si). The effective mass of electrons and the effective mass of holes shown in Table 2 are calculated by the first-principles electron state calculation.

TABLE 2
Effective mass in In₂O₃

| Electron | | | |
|---|---|---|---|
| [100] direction | [110] direction | [111] direction | Hole |
| 0.17 | 0.18 | 0.19 | 3.56 |

Effective mass in Si

| Electron | Hole |
|---|---|
| 0.26 | 0.17 |

As shown in Table 2, the effective mass of electrons in indium oxide is small. Thus, the use of indium oxide with a small effective mass of electrons for the semiconductor layer 30 enables a transistor to have a high on-state current, high field-effect mobility, or high frequency characteristics (also referred to as f characteristics). In addition, the effective mass of electrons in indium oxide hardly depends on the crystal orientation. The effective mass of electrons in indium oxide is smaller than that in silicon, for example. Hence, in terms of the effective mass of electrons, the f characteristics of a transistor containing indium oxide in its channel formation region are higher than those of a Si transistor.

As shown in Table 2, the effective mass of holes in indium oxide is large. Thus, the use of indium oxide with a large effective mass of holes for the semiconductor layer 30 enables a transistor to have an extremely low off-state current. The effective mass of holes in indium oxide is larger than that in silicon, for example. Hence, in terms of the effective mass of holes, the off-state current of a transistor containing indium oxide in its channel formation region is sufficiently lower than that of a Si transistor.

The off-state current per micrometer of channel width of the transistor in which indium oxide is used for the semiconductor layer 30 at room temperature (25° C.) can be lower than or equal to 1 aA (1×10⁻¹⁸ A), or lower than or equal to 1 zA (1×10⁻²¹ A). The off-state current per micrometer of channel width at 85° C. can be lower than or equal to 1×10⁻¹⁶ A/μm, preferably lower than or equal to 1×10⁻¹⁷ A/μm, further preferably lower than or equal to 1×10⁻¹⁸ A/μm. The off-state current per micrometer of channel width at 125° C. can be lower than or equal to 1 fA (1×10⁻¹⁵ A), or lower than or equal to 1 aA (1×10⁻¹⁸ A).

Scaling down of an OS transistor can improve the high-frequency characteristics of the transistor. For example, the cutoff frequency (fT) of the transistor can be improved. Specifically, the cutoff frequency of the transistor can be higher than or equal to 50 GHz, preferably higher than or equal to 100 GHz, further preferably higher than or equal to 150 GHz at room temperature (25° C.).

The indium oxide film can contain one or more kinds of metal elements with large period numbers in the periodic table as long as it has crystallinity. The larger the overlap between orbits of metal elements is, the more likely it is that the carrier conductivity will be increased. Thus, when a metal element with a large period number in the periodic table is contained, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, and light rare earth elements (lanthanum, cerium, praseodymium, neodymium, promethium, samarium, and europium).

FIG. 1A illustrates an example where the semiconductor layer 30 has a single-layer structure. The semiconductor layer 30 can have a stacked-layer structure of two or more layers. For example, in the case where the semiconductor layer 30 has a two-layer structure of a first semiconductor layer and a second semiconductor layer over the first semiconductor layer, the above-described metal oxide (typically, indium oxide) that can be used for the semiconductor layer 30 is preferably used for the first semiconductor layer, and a metal oxide whose conduction band minimum is closer to the vacuum level than the conduction band minimum of the first semiconductor layer is preferably used for the second semiconductor layer. In that case, the first semiconductor layer can mainly function as a current path (channel). That is, the first semiconductor layer includes a channel formation region on a surface on the second semiconductor layer side and in the vicinity of the surface.

The above-described structure can reduce the number of carriers trapped at the interface with the first semiconductor layer and its vicinity. Moreover, the channel can be distanced from the surface of the insulating layer 50, so that the influence of surface scattering can be reduced. Thus, the field-effect mobility of the transistor can be increased.

Examples of the metal oxide that can be used for the second semiconductor layer include indium gallium oxide (In—Ga oxide), In—Zn oxide, indium tin oxide (In—Sn oxide, also referred to as ITO), indium titanium oxide (In—Ti oxide), indium aluminum zinc oxide (In—Al—Zn oxide, also referred to as IAZO), In—Ga—Zn oxide, indium tin zinc oxide (also referred to as In—Sn—Zn oxide), indium titanium zinc oxide (In—Ti—Zn oxide), and indium tin oxide containing silicon oxide (also referred to as ITSO). Alternatively, zinc oxide, aluminum zinc oxide (also referred to as Al—Zn oxide or AZO), aluminum tin oxide (Al—Sn oxide), or the like can be used.

Specifically, the In—Zn oxide used for the second semiconductor layer can have an atomic ratio of In:Zn=1:1 or the neighborhood thereof, In:Zn=2:1 or the neighborhood thereof, or In:Zn=4:1 or the neighborhood thereof. Furthermore, specifically, IGZO used for the second semiconductor layer can have an atomic ratio of In:Ga:Zn=1:1:1 or the neighborhood thereof, In:Ga:Zn=1:3:2 or the neighborhood thereof, or In:Ga:Zn=1:3:4 or the neighborhood thereof. Note that the neighborhood of the atomic ratio includes ±30% of an intended atomic ratio.

There is no particular limitation on the crystallinity of the metal oxide included in the second semiconductor layer. The second semiconductor layer sometimes includes, for example, at least one of an amorphous semiconductor (a semiconductor having an amorphous structure), a single crystal semiconductor (a semiconductor having a single crystal structure), and a semiconductor having crystallinity other than single crystal (a microcrystalline semiconductor, a polycrystalline semiconductor, or a semiconductor partly including crystal regions).

In FIGS. 1E and 1F, the island-shaped layer 29 is provided in contact with the top surface of the insulating layer 20, and the semiconductor layer 30 is provided to cover the layer 29.

The layer 29 includes a crystal. The layer 29 functions as a seed or a nucleus in performing treatment for increasing the crystallinity of the semiconductor layer 30. In other words, the layer 29 functions as a seed or a nucleus at the time of crystal growth of the semiconductor layer 30. In this specification and the like, the layer 29 or the crystal included in the layer 29 can be referred to as a seed crystal or a crystal nucleus. Since the layer 29 includes the crystal, the layer 29 can be referred to as a crystal part.

The crystal structure of indium oxide is a cubic crystal structure (bixbyite type). In the case where indium oxide is used for the semiconductor layer 30, the layer 29 preferably includes a hexagonal crystal or a trigonal crystal, for example. In this case, when the layer 29 includes a crystal having a crystal orientation <001> with respect to a surface or a formation surface of the layer 29, the semiconductor layer 30 including a crystal having a crystal orientation <111> can be formed. In the case where the crystal included in the layer 29 has a crystal orientation <001> with respect to the surface or the formation surface of the layer 29, the c-axis of the crystal is perpendicular or substantially perpendicular to the surface or the formation surface of the layer 29. Note that the hexagonal or trigonal crystal can be rephrased as a crystal having a layered structure in some cases; thus, the above-described structure can be regarded as a structure in which the semiconductor layer 30 including a crystal of a cubic crystal system is formed over the layer 29 including a crystal having a layered structure. In other words, the structure can be considered as a stacked-layer structure formed using a heteroepitaxial growth technique or a technique like heteroepitaxial growth.

In this specification and the like, a space group is represented using the short symbol of the international notation (or the Hermann-Mauguin notation). In addition, the Miller index is used for the expression of crystal planes and crystal orientations. In the crystallography, a bar is placed over a number in the expression of space groups, crystal planes, and crystal orientations; in this specification and the like, because of format limitations, space groups, crystal planes, and crystal orientations are sometimes expressed by placing a minus sign (−) in front of a number instead of placing a bar over the number. Furthermore, an individual direction that shows a direction in crystal is expressed with “[ ]”, a set direction that shows all of the equivalent directions is expressed with “< >”, an individual plane that shows a crystal plane is expressed with “( )”, and a set plane having equivalent symmetry is expressed with “{ }”.

In this specification and the like, a crystal orientation of a crystal refers to a direction with respect to a surface of a substrate. Thus, for example, a crystal having a crystal orientation <100>can be regarded as a crystal whose (100) plane is parallel to a surface of a substrate. Note that the crystal orientation of a crystal is not limited to the direction with respect to a surface of a substrate and can also be referred to as a direction with respect to a surface of the insulating layer 20 or a formation surface of the insulating layer 20.

Specifically, zinc oxide, In—Ga oxide, gallium zinc oxide (also referred to as Ga—Zn oxide or GZO), aluminum zinc oxide (also referred to as Al—Zn oxide or AZO), In—Al—Zn oxide, In—Ga—Zn oxide, In—Sn—Zn oxide, or the like can be used for the layer 29. For the layer 29, an In—Ga—Zn oxide is preferably used. Here, the layer 29 contains indium, gallium, zinc, and oxygen. Specifically, it is preferable that the atomic ratio of the In—Ga—Zn oxide be In:Ga:Zn=1:1:1 or in the neighborhood thereof, or In:Ga:Zn=1:3:2 or in the neighborhood thereof. A metal oxide having any of these compositions is suitable for the layer 29 because it easily forms a layered structure.

An In—Ga—Zn oxide, an In—Sn—Zn oxide, and the like tend to have a CAAC structure. In the case where an oxide having a CAAC structure is used for the layer 29, the c-axis of the crystal included in the layer 29 is perpendicular or substantially perpendicular to the surface or the formation surface of the layer 29. That is, the crystal orientation of the crystal included in the layer 29 with respect to the surface or the formation surface of the layer 29 is <001>. Thus, when an oxide that tends to have a CAAC structure is used for the layer 29, the controllability of the crystal orientation of the crystal nucleus can be increased.

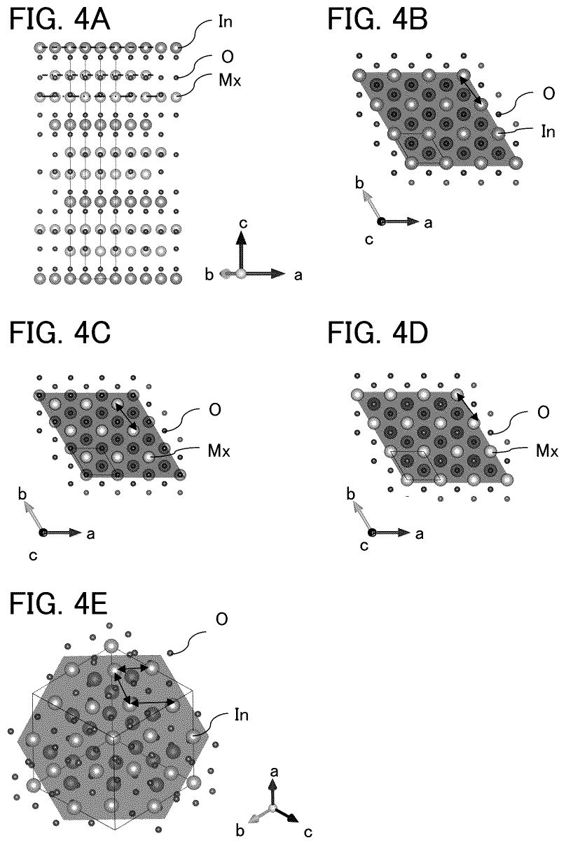

Here, crystal structures of a metal oxide are shown in FIGS. 4A to 4E. FIG. 4A illustrates a crystal structure of an In—Ga—Zn oxide with an atomic ratio of In:Ga:Zn=1:1:1 seen from the direction perpendicular to the c-axis. FIG. 4B illustrates a plane indicated by a dashed line in FIG. 4A, seen from the c-axis direction. FIG. 4C illustrates a plane indicated by a dashed-dotted line in FIG. 4A, seen from the c-axis direction. FIG. 4D illustrates a plane indicated by a dashed double-dotted line in FIG. 4A, seen from the c-axis direction. Mx shown in FIGS. 4A, 4C, and 4D represents a Ga atom or a Zn atom. Note that in FIG. 4A, the plane indicated by the dashed line, the plane indicated by the dashed-dotted line, and the plane indicated by the dashed double-dotted line are collectively referred to as a c-plane in some cases. FIG. 4E illustrates the crystal structure of indium oxide seen from the direction perpendicular to the (111) plane.

The distance between metal atoms on the c-plane (an arrow in each of FIGS. 4B to 4D) is said to be 0.330 nm. The distances between In atoms on the (111) plane (an arrow in FIG. 4E) are said to be 0.334 nm and 0.385 nm. That is, the arrangement of metal atoms seems to be similar between the c-plane of the CAAC structure and the (111) plane of indium oxide. Thus, an oxide that tends to have a CAAC structure can be suitably used for the layer 29.

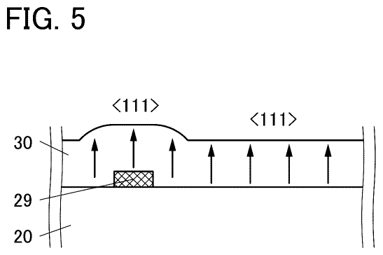

In the case where an oxide that tends to have a CAAC structure is used for the layer 29, the semiconductor layer 30 including a crystal having a crystal orientation <111> can be formed. FIG. 5 is a cross-sectional view of the layer 29 and the insulating layer 20 and the semiconductor layer 30 in the vicinity of the layer 29. In FIG. 5, the <111> direction of the crystal included in the semiconductor layer 30 is indicated by arrows. As illustrated in FIG. 5, the <111> direction of the crystal included in the semiconductor layer 30 is likely to be perpendicular or substantially perpendicular to the substrate surface (not illustrated) in each of a portion above the layer 29, the vicinity of a side surface of the layer 29, and a portion apart from the layer 29. This property can be regarded as being different from the property of the CAAC structure where the c-axis of a crystal is perpendicular or substantially perpendicular to the formation surface or surface of the semiconductor layer 30.

An oxide having a cubic crystal structure can also be used for the layer 29. When the layer 29 has the same crystal structure as the semiconductor layer 30, the semiconductor layer 30 can be epitaxially grown with the layer 29 as a seed or a nucleus, so that the crystallinity of the semiconductor layer 30 can be increased. Note that an oxide containing a Group 3 element in the periodic table is likely to have a cubic crystal structure. The Group 3 element in the crystal mainly exists as trivalent cations. Thus, the layer 29 preferably contains at least one of elements that can be trivalent cations. As the element that can be a trivalent cation contained in the layer 29, scandium, yttrium, cerium, gadolinium, erbium, ytterbium, or the like is preferably used.

As the layer 29, an oxide containing one or both of yttrium and zirconium, erbium oxide, or the like can be used, for example. Examples of the oxide containing one or both of yttrium and zirconium include yttrium oxide, zirconium oxide, and yttrium zirconium oxide.

A difference in the lattice constant or the length of a unit lattice vector between a crystal nucleus and the crystal included in the semiconductor layer 30 (also referred to as a lattice mismatch) is preferably small. The use of an oxide that makes a lattice mismatch small for the layer 29 can increase the crystallinity of the semiconductor layer 30.

One of methods for evaluating the degree of a lattice mismatch is a method using a value of a lattice mismatch degree described below. A lattice mismatch degree Aa [%] of a crystal included in a film to be formed (here, the indium oxide film) with respect to a crystal included in a film on which the film is to be formed is calculated by Formula (1) below. Hereinafter, the lattice mismatch degree Aa of the crystal included in the film to be formed with respect to the crystal included in the film on which the film is to be formed may be simply referred to as the lattice mismatch degree Aa of the film to be formed with respect to the film on which the film is to be formed.

$$\begin{matrix}[ Formula 1 ] & \\ Δ a = ( \frac{{L}_{1}}{{L}_{2}} - 1 ) \times 100 & ( 1 )\end{matrix}$$

In Formula (1), L₁ is the lattice constant or the length of the unit lattice vector of the crystal included in the film to be formed, and L₂ is the lattice constant or the length of the unit lattice vector of the crystal included in the film on which the film is to be formed.

The lattice mismatch degree Aa of the crystal grain included in the semiconductor layer 30 with respect to the crystal nucleus is preferably higher than or equal to −10% and lower than or equal to 10%, further preferably higher than or equal to −5% and lower than or equal to 5%, still further preferably higher than or equal to −3% and lower than or equal to 3%. When a material that makes the lattice mismatch degree with respect to the semiconductor layer 30 low is used for the layer 29, the crystallinity of the semiconductor layer 30 can be increased.

For example, the lattice constant of an indium oxide crystal (bixbyite type) is said to be 1.01194 nm. It is also said that the lattice constant of an yttrium oxide crystal (bixbyite type) is 1.05976 nm. Thus, the lattice mismatch degree of the indium oxide crystal with respect to the yttrium oxide crystal is −4.5%. Therefore, in the case where indium oxide is used for the semiconductor layer 30, yttrium oxide can be used for the layer 29.

For example, the lattice constant of an erbium oxide crystal (bixbyite type) is said to be 1.0582 nm. Thus, the lattice mismatch degree of the indium oxide crystal with respect to the erbium oxide crystal is −4.4%. Therefore, in the case where indium oxide is used for the semiconductor layer 30, erbium oxide can be used for the layer 29.

For example, the lattice constant of a Zr_{0.9}Y_{0.1}O_{1.95} crystal (fluorite type), which is an example of yttrium zirconium oxide, is 0.51481 nm (see ICSD coll. code. 248790). Thus, the lattice mismatch degree of the indium oxide crystal with respect to the Zr_{0.9}Y_{0.1}O_{1.95} crystal is −1.7%. Therefore, in the case where indium oxide is used for the semiconductor layer 30, yttrium zirconium oxide can be suitably used for the layer 29. Note that yttrium zirconium oxide contains yttrium, zirconium, and oxygen.

When the content percentage of yttrium contained in yttrium zirconium oxide, which is formed by adding yttrium or yttrium oxide to zirconium oxide, is higher than 0 atomic %, the crystal structure of zirconium oxide can be stable. However, when the content percentage is high, the crystal structure of yttrium zirconium oxide changes from a cubic crystal system to another crystal system in some cases; thus, the content percentage is preferably not too high. Thus, for example, the content percentage of yttrium contained in yttrium zirconium oxide is preferably higher than or equal to 2 atomic % and lower than or equal to 15 atomic %, further preferably higher than or equal to 5 atomic % and lower than or equal to 10 atomic %.

Furthermore, indium oxide may be used for the layer 29. When indium oxide is used for the layer 29, the semiconductor layer 30 can be homoepitaxially grown with the layer 29 as a seed or a nucleus, so that the crystallinity of the semiconductor layer 30 can be increased. In this case, the crystal orientation of the crystal included in the layer 29 is aligned or substantially aligned with the crystal orientation of the crystal included in the semiconductor layer 30.

There is no particular limitation on a material that can be used for the layer 29. The layer 29 may be formed using an insulating material, a semiconductor material, or a conductive material. In the case where a semiconductor material is used for the layer 29, the layer 29 may be regarded as part of the semiconductor layer 30.

FIG. 1E illustrates an example where the layer 29 is circular in the plan view. The present invention is not limited thereto. The layer 29 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example. In the case where sputtered particles are used for the layer 29, the layer 29 may have a triangular shape or a hexagonal shape in a plan view.

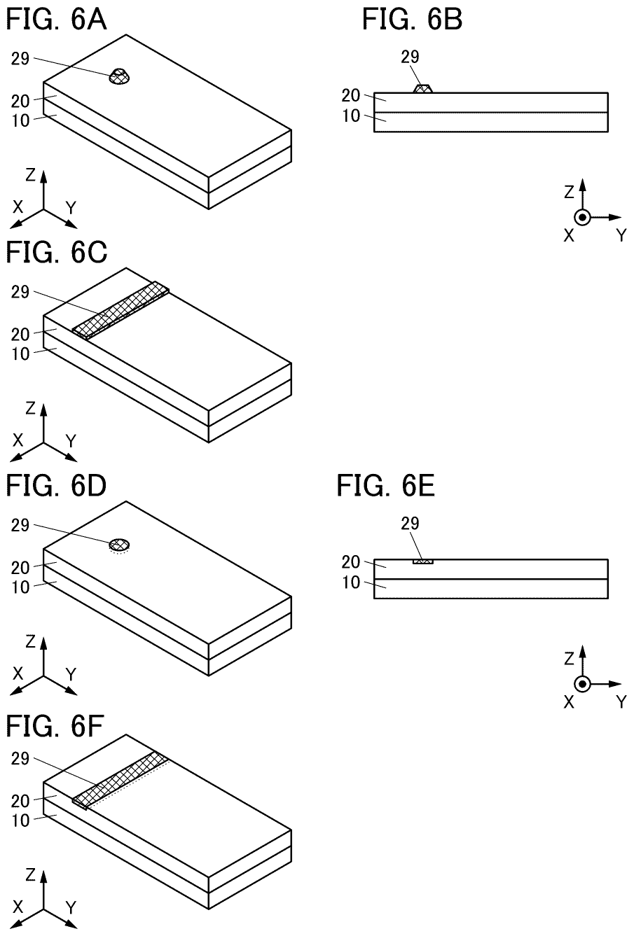

As illustrated in FIGS. 6A and 6B, the layer 29 may have a tapered shape. For example, the angle formed between the top surface of the insulating layer 20 and the side surface of the layer 29 may be less than 90°, preferably greater than or equal to 30° and less than 90°. When the layer 29 has a tapered shape, the coverage with the semiconductor layer 30 can be improved and defects such as voids can be reduced. In addition, crystal growth of the semiconductor layer 30 can be promoted.

FIG. 1A illustrates an example where the island-shaped layer 29 is provided. The present invention is not limited thereto. For example, the layer 29 may include a region extending in a direction perpendicular to the Z direction (the X direction in FIG. 6C).

FIG. 1A illustrates an example where the layer 29 is provided in contact with the top surface of the insulating layer 20. The present invention is not limited thereto. For example, as illustrated in FIGS. 6D and 6E, the layer 29 may be provided so as to be embedded in a depressed portion provided in the insulating layer 20. Thus, the top surface of the insulating layer 20 can be flat, and the crystallinity of the semiconductor layer 30 can be increased. Furthermore, the depressed portion may be an opening portion that penetrates the insulating layer 20. Moreover, the layer 29 embedded in the depressed portion may include an extended region (see FIG. 6F).

The thickness of the layer 29 is preferably small. For example, the thickness of the layer 29 is preferably smaller than that of the semiconductor layer 30. Specifically, the layer 29 preferably includes a region with a thickness greater than or equal to 0.1 nm and less than 2 nm, and further preferably includes a region with a thickness greater than or equal to 0.5 nm and less than 2 nm. When the thickness of the layer 29 is small, a step generated between the layer 29 and the insulating layer 20 is reduced. Thus, the coverage with the semiconductor layer 30 can be improved and defects such as voids can be reduced. In addition, crystal growth of the semiconductor layer 30 can be promoted. Note that the layer 29 may have a layered shape or a particulate shape.

The top surface of the insulating layer 20 is preferably flat. When there is unevenness on the top surface of the insulating layer 20 where the layer 29 is provided, a crystal nucleus might be formed owing to the unevenness and an increase in crystal grain size might be hindered. In view of the above, the top surface of the insulating layer 20 may be made flat, whereby generation of a crystal nucleus can be inhibited and crystallization and crystal growth in the semiconductor layer 30 with the layer 29 as a seed or a nucleus can be promoted.

In this specification and the like, the expression “a top surface of a film or a layer is flat” also includes the case where the top surface of the film or the layer has a minute projecting surface, a minute convex surface, a minute depressed surface, a minute concave surface, a minute uneven shape, or the like.

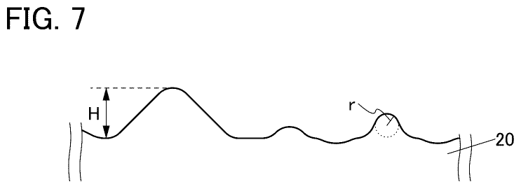

Here, FIG. 7 is a schematic cross-sectional view of the insulating layer 20. FIG. 7 illustrates the top surface shape of the insulating layer 20. In FIG. 7, the height difference H between a projecting portion and a depressed portion adjacent to each other is indicated by a double-headed arrow, and the radius of curvature of a projecting portion is denoted by r. The height difference His preferably greater than or equal to 0 nm and less than 3 nm. When the height difference H is smaller than a preferred thickness of the semiconductor layer 30 described later, crystallization and crystal growth in the semiconductor layer 30 can be prevented from being hindered. The height difference H is further preferably greater than or equal to 0 nm and less than or equal to 2 nm, still further preferably greater than or equal to 0 nm and less than or equal to 1 nm, yet still further preferably greater than or equal to 0 nm and less than or equal to 0.3 nm, further preferably greater than or equal to 0 nm and less than or equal to 0.1 nm. Note that the height difference H of 0 nm means that any projecting or depressed portion cannot be observed on the top surface of the film or the layer. When the height difference H is smaller than the above-described preferred thickness of the layer 29, the coverage with the semiconductor layer 30 can be improved and defects such as voids can be reduced. The radius of curvature r is preferably greater than or equal to 1 nm and less than or equal to 100 nm, further preferably greater than or equal to 10 nm and less than or equal to 100 nm. The top surface where such unevenness exists can be regarded as being flat.

The height difference H and the radius of curvature r can be evaluated by image analysis of a cross-sectional TEM image. In the case where the height difference H and the radius of curvature r of the top surface of a first layer are evaluated by image analysis of a cross-sectional TEM image, a sample including the first layer and a second layer over the first layer is prepared first. Next, a cross-sectional TEM image of the sample is obtained, and the contrast (brightness boundary) observed in the TEM image is assumed to be at the interface between the first layer and the second layer, i.e., the top surface of the first layer. The height difference H and the radius of curvature r can be calculated on the basis of the assumed top surface of the first layer. Note that the height difference H can be calculated as the average value per visual field (e.g., 100 nm). The radius of curvature r can be calculated as the average value per field of view (e.g., 100 nm).

In this specification and the like, even in the case where the average roughness (Ra) of the top surface of a film or a layer is less than 3 nm, the top surface of the film or the layer is regarded as flat. Note that the average roughness (Ra) is obtained by expanding arithmetic mean roughness which is defined by JIS B 0601:2001 (ISO 4287:1997) into three dimensions for application to a curved surface. The average roughness (Ra) can be evaluated using an atomic force microscope (AFM).

Note that the average roughness (Ra) can be calculated from a region of 1 mm square, for example. In the case where the region of 1 mm square is not included in a plan view of an island-shaped layer, the calculation may be performed on the entire region of the layer in the plan view. Note that average roughness (Ra) in this specification and the like may be rephrased as root-mean-square roughness (Rq or RMS) or maximum height roughness (Rz). For example, also in the case where at least one of the average roughness (Ra), root-mean-square roughness (Rq or RMS), and maximum height roughness (Rz) of a top surface of a film or a layer is less than 3 nm, the top surface is regarded as flat.

The flatness of the top surface of a film or a layer may be evaluated by image analysis of the TEM image. For example, the contrast observed in the TEM image is assumed to be at the interface between the first layer and the second layer, and the shape of the interface is assumed to be a roughness curve of the first layer. Then, the arithmetic mean roughness can be calculated from the assumed roughness curve. Note that the reference length may be the length of the top surface of the first layer observed in the TEM image, or may also be the length of the region where the first layer and the second layer overlap with each other. The reference length is 100 nm, for example. In that case, the observed range of the TEM image is preferably longer than or equal to 100 nm in either the vertical direction or the horizontal direction. Even in the case where the arithmetic mean roughness of the top surface of the first layer calculated using this method is less than 3 nm, the top surface of the first layer can be regarded as flat.

The average roughness (Ra) or arithmetic mean roughness of the top surface of the insulating layer 20 is preferably greater than or equal to 0 nm and less than 3 nm. When the average roughness (Ra) or the arithmetic mean roughness of the top surface of the insulating layer 20 is smaller than the preferred thickness of the semiconductor layer 30 described later, crystallization and crystal growth in the semiconductor layer 30 can be prevented from being hindered. The average roughness (Ra) or the arithmetic mean roughness of the top surface of the insulating layer 20 is further preferably greater than or equal to 0 nm and less than or equal to 2 nm, further preferably greater than or equal to 0 nm and less than or equal to 1 nm, still further preferably greater than or equal to 0 nm and less than or equal to 0.5 nm, still further preferably greater than or equal to 0 nm and less than or equal to 0.3 nm, yet still further preferably greater than or equal to 0 nm and less than or equal to 0.2 nm. When the average roughness (Ra) or the arithmetic mean roughness of the top surface of the insulating layer 20 is smaller than the above-described preferred thickness of the layer 29, the coverage with the semiconductor layer 30 can be improved and defects such as voids can be reduced.

The thickness of the semiconductor layer 30 is preferably larger than the average roughness (Ra) or the arithmetic mean roughness of the top surface of the insulating layer 20, and is preferably greater than or equal to 3 nm and less than or equal to 50 nm, for example. Accordingly, crystallization and crystal growth in the semiconductor layer 30 can be prevented from being hindered.

The insulating layer 50 preferably has a function of supplying oxygen to the semiconductor layer 30. The insulating layer 50 preferably includes a region containing oxygen that is released by heating (hereinafter, sometimes referred to as excess oxygen), for example. When the insulating layer including the region containing excess oxygen is in contact with the semiconductor layer 30, oxygen can be supplied to the semiconductor layer 30. Oxygen supplied to the semiconductor layer 30 fills oxygen vacancies, so that the amount of oxygen vacancies in the semiconductor layer 30 can be reduced. Examples of an insulating material that easily forms the region containing excess oxygen include silicon oxide, silicon oxynitride, and porous silicon oxide.

The insulating layer 50 preferably has a function of capturing or fixing (also referred to as gettering) oxygen. As described above, oxygen easily moves in the indium oxide film. Thus, when the insulating layer 50 has a function of capturing or fixing oxygen, excess oxygen in the semiconductor layer 30 can diffuse into the insulating layer 50 and the oxygen can be captured or fixed. Accordingly, the positive drift degradation of the OS transistor in the +GBT stress test due to the excess oxygen can be inhibited. Examples of an insulating material having a function of capturing or fixing oxygen include aluminum oxide, hafnium oxide, hafnium zirconium oxide, and an oxide containing hafnium and silicon (hafnium silicate).

Aluminum oxide, hafnium oxide, hafnium zirconium oxide, and hafnium silicate each have a function of capturing or fixing hydrogen. As described above, hydrogen easily moves in the indium oxide film. Thus, when the insulating layer 50 has a function of capturing or fixing hydrogen, hydrogen in the semiconductor layer 30 can diffuse into the insulating layer 50 and the hydrogen can be captured or fixed. Hence, the hydrogen concentration in the semiconductor layer 30 (in particular, the hydrogen concentration in the channel formation region) can be reduced.

In the example illustrated in FIG. 1A, the insulating layer 50 has a single-layer structure. Note that the insulating layer 50 can have a stacked-layer structure of two or more layers. In the case where the insulating layer 50 has the stacked-layer structure of two or more layers, the layer in contact with the semiconductor layer 30 among the two or more layers included in the insulating layer 50 is preferably formed using the insulating material that can be used for the insulating layer 50 (typically, aluminum oxide). With such a structure, oxygen can be supplied to the semiconductor layer 30 and the amount of oxygen vacancies in the semiconductor layer 30 can be reduced. Moreover, excess oxygen in the semiconductor layer 30 can be released to the insulating layer 50. In addition, hydrogen in the semiconductor layer 30 can be captured or fixed.

The insulating layer 20 preferably has a function of supplying oxygen to the semiconductor layer 30. For example, the insulating layer 20 preferably includes a region containing excess oxygen.

Furthermore, the insulating layer 50 preferably has a function of capturing or fixing oxygen. With this structure, oxygen can be pushed into the semiconductor layer 30 from the insulating layer 20 side, the amount of oxygen vacancies in the semiconductor layer 30 can be reduced, excess oxygen in the semiconductor layer 30 can be pulled from the insulating layer 50 side, and the excessive amount of oxygen in the semiconductor layer 30 can be reduced. Accordingly, a highly reliable semiconductor device can be provided.

Note that the insulating layer 20 may have a function of capturing or fixing oxygen, and the insulating layer 50 may have a function of supplying oxygen to the semiconductor layer 30. With this structure, oxygen can be pushed into the semiconductor layer 30 from the insulating layer 50 side, the amount of oxygen vacancies in the semiconductor layer 30 can be reduced, excess oxygen in the semiconductor layer 30 can be pulled from the insulating layer 20 side, and the excessive amount of oxygen in the semiconductor layer 30 can be reduced. Accordingly, a highly reliable semiconductor device can be provided.

For the insulating layer 20, a material having a lower thermal expansion coefficient than that of a metal oxide used for the semiconductor layer 30 is preferably used. For example, a material having a lower thermal expansion coefficient than indium oxide can be used for the insulating layer 20. Specifically, the thermal expansion coefficient of the insulating layer 20 is preferably higher than or equal to 0.01×10⁻⁶ K⁻¹ and lower than or equal to 5.5×10⁻⁶ K⁻¹, further preferably higher than or equal to 0.01×10⁻⁶ K⁻¹ and lower than or equal to 5.0×10⁻⁶ K⁻¹, still further preferably higher than or equal to 0.01×10⁻⁶ K⁻¹ and lower than or equal to 3.0×10⁻⁶ K⁻¹, yet still further preferably higher than or equal to 0.01×10⁻⁶ K⁻¹ and lower than or equal to 1.0×10⁻⁶ K⁻¹. With such a structure, when the semiconductor layer 30 containing indium oxide is in contact with or in the vicinity of the insulating layer 20 with a low thermal expansion coefficient, tensile stress is applied to the indium oxide at the time of temperature decrease, so that the indium oxide becomes unstable in terms of energy. As a result, the indium oxide comes to have a cubic crystal structure that is more stable in terms of energy. Then, crystal growth is promoted, so that a cubic crystal having an increased grain size can be formed. Silicon oxide has a lower thermal expansion coefficient than indium oxide and thus is suitable for the insulating layer 20.

Here, Table 3 shows the thermal expansion coefficients of oxide semiconductors and insulators. Table 3 shows the thermal expansion coefficients of IGZO and indium oxide (In₂O₃) as the oxide semiconductor, and those of silicon oxide (SiO₂), silicon nitride (Si₃N₄), and yttria-stabilized zirconia (YSZ) as the insulator. According to the value in Table 3, silicon nitride can also be used for the insulating layer 20.

TABLE 3

| | | Thermal expansion coefficient |
|---|---|---|
| Material | | [×10⁻⁶ K⁻¹] |
| Oxide semiconductor | IGZO | 5.23 |
| | In₂O₃ | 6.15 |
| Insulator | SiO₂ | 0.54 |
| | Si₃N₄ | 2.3 |
| | YSZ | 7.7 |

In the example illustrated in FIG. 1F, the insulating layer 20 has a single-layer structure. Note that the insulating layer 20 can have a stacked-layer structure of two or more layers. In the case where the insulating layer 20 has the stacked-layer structure of two or more layers, the layer in contact with the semiconductor layer 30 among the two or more layers included in the insulating layer 20 is preferably formed using the insulating material that can be used for the insulating layer 20 (typically, silicon oxide). With such a structure, the crystallinity of the semiconductor layer 30 can be improved.

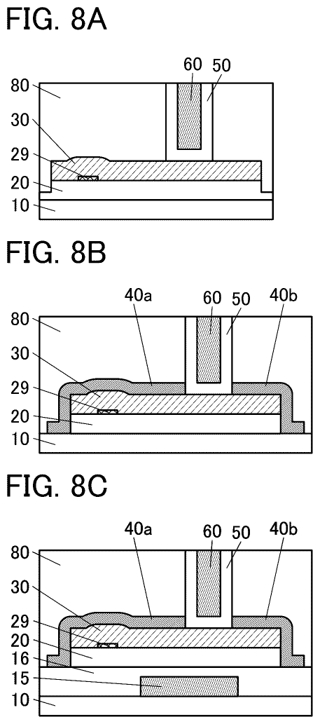

FIG. 1F illustrates an example in which the insulating layer 20 has an island shape like the semiconductor layer 30. The present invention is not limited thereto. For example, as illustrated in FIG. 8A, the insulating layer 20 may have a shape that is not an island shape and may have a protruding portion in a portion overlapping with the semiconductor layer 30.

The conductive layer 60 is preferably formed using a material having high conductivity such as tungsten. For the conductive layer 60, a conductive material that is not easily oxidized, a conductive material having a function of inhibiting diffusion of oxygen, or the like is preferably used. Examples of the conductive material include a conductive material containing nitrogen (e.g., titanium nitride or tantalum nitride) and a conductive material containing oxygen (e.g., ruthenium oxide). Thus, a decrease in conductivity of the conductive layer 60 can be inhibited.

It is preferable to use, for the conductive layer 60, a conductive material containing oxygen and a metal element contained in the metal oxide where a channel is formed. One or more of ITO, indium oxide containing tungsten oxide, indium zinc oxide containing tungsten oxide, indium oxide containing titanium oxide, indium tin oxide containing titanium oxide, In—Zn oxide, and ITSO may be used, for example. Indium gallium zinc oxide containing nitrogen may also be used. With the use of such a material, hydrogen contained in the metal oxide where a channel is formed can be captured in some cases. Hydrogen entering from an insulating layer or the like outside the transistor can also be captured in some cases.

The insulating layer 80 functions as an interlayer film. The insulating layer 50 and the conductive layer 60 are provided to fill the opening portion 89 provided in the insulating layer 80. The opening portion 89 is preferably provided at a position not overlapping with the layer 29. A portion of the semiconductor layer 30 that does not overlap with the layer 29 is flatter than a portion of the semiconductor layer 30 that overlaps with the layer 29. Thus, the opening portion 89 is provided at a position not overlapping with the layer 29, whereby a channel can be formed in the flat region of the semiconductor layer 30, and the electrical characteristics of the transistor can be improved.

As illustrated in FIG. 8B, the semiconductor device of one embodiment of the present invention can include a conductive layer 40a and a conductive layer 40b that are placed apart from each other over the semiconductor layer 30. The conductive layer 40a and the conductive layer 40b function as a source electrode and a drain electrode of the transistor. In FIG. 8B, each of the conductive layer 40a and the conductive layer 40b is in contact with at least part of the top surface of the semiconductor layer 30 and at least part of the side surface of the semiconductor layer 30. With this structure, the contact area between the conductive layer 40a or 40b and the semiconductor layer 30 is increased, so that the contact resistance between the conductive layer 40a and the semiconductor layer 30 and the contact resistance between the conductive layer 40b and the semiconductor layer 30 can be reduced.

As illustrated in FIG. 8C, the semiconductor device of one embodiment of the present invention can include a conductive layer 15 at a position overlapping with the conductive layer 60 with the semiconductor layer 30 therebetween. The semiconductor device illustrated in FIG. 8C includes an insulating layer 16. The conductive layer 15 is covered with the insulating layer 16 and includes a portion overlapping with the semiconductor layer 30 with the insulating layer 20 therebetween.

In the structure illustrated in FIG. 8C, the conductive layer 60 functions as a first gate electrode of the transistor, the insulating layer 50 functions as a first gate insulating layer of the transistor, the conductive layer 15 functions as a second gate electrode of the transistor, and the insulating layer 16 and the insulating layer 20 function as a second gate insulating layer of the transistor.

Note that the semiconductor device illustrated in FIG. 8C does not necessarily include the insulating layer 50 and the conductive layer 60. In that case, the conductive layer 15 functions as a gate electrode of the transistor, and the insulating layer 16 and the insulating layer 20 function as a gate insulating layer of the transistor. In this case, the structure of the transistor can be regarded as a bottom-gate structure.

### Example 1 of Method for Manufacturing Semiconductor Device

An example of a method for manufacturing a semiconductor device of one embodiment of the present is described below. The example of the method for manufacturing a semiconductor device described here includes a method for forming a semiconductor layer.

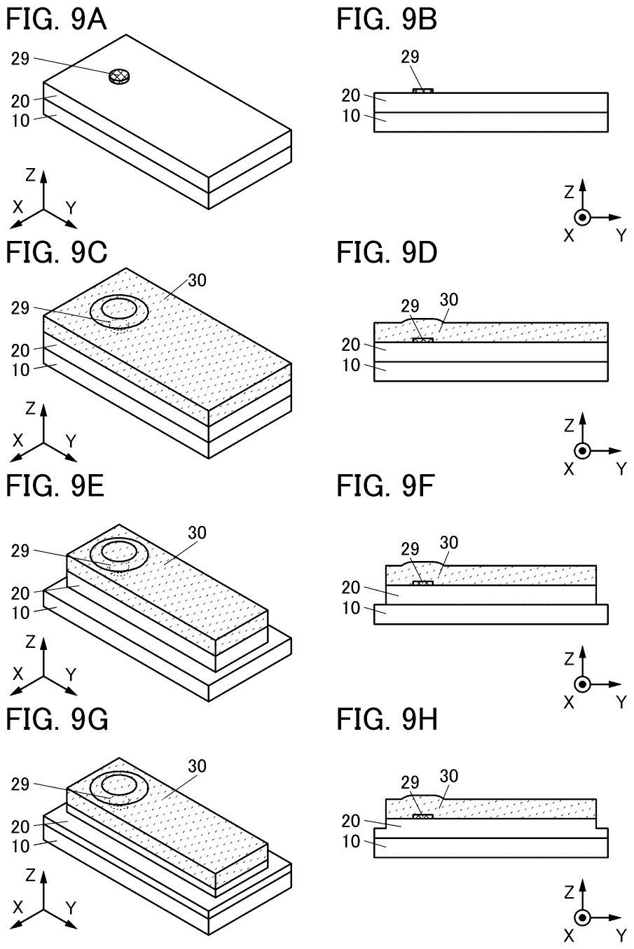

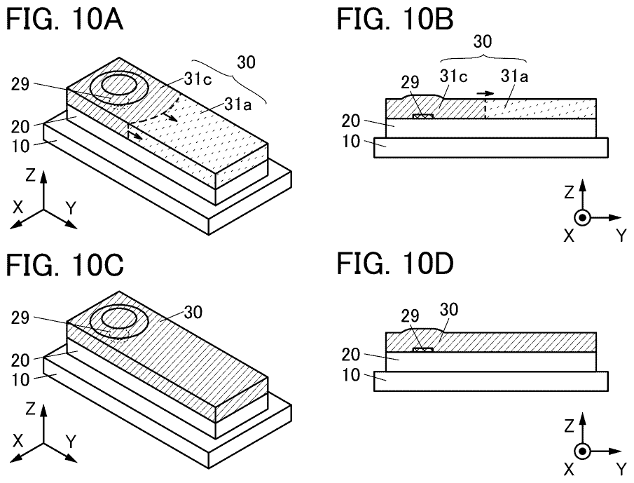

FIG. 9A, FIG. 9C, FIG. 9E, FIG. 9G, FIG. 10A, and FIG. 10C are schematic perspective views of a semiconductor device, and FIG. 9B, FIG. 9D, FIG. 9F, FIG. 9H, FIG. 10B, and FIG. 10D are cross-sectional views of the semiconductor device seen from the X direction.

Layers constituting the semiconductor device (e.g., the insulating layer 20, the layer 29, the semiconductor layer 30, the conductive layer 40a, the conductive layer 40b, the insulating layer 80, the insulating layer 50, and the conductive layer 60) can be formed by a sputtering method, a chemical vapor deposition (CVD) method, a vacuum evaporation method, a molecular beam epitaxy (MBE) method, a pulsed laser deposition (PLD) method, an ALD method, or the like.

Unlike in a film formation method in which particles ejected from a target or the like are deposited, a film is formed by reaction at a surface of an object to be processed in an ALD method. Thus, an ALD method can provide good step coverage, almost regardless of the shape of an object to be processed. In particular, the ALD method allows excellent step coverage and excellent thickness uniformity and thus can be suitably used to cover a surface of an opening portion or a groove portion with a high aspect ratio, for example.

Moreover, some precursors used in the ALD method contain an element such as carbon or chlorine. Thus, a film formed by the ALD method sometimes contains an element such as carbon or chlorine in a larger quantity than a film formed by another film formation method. Note that these elements can be quantified by XPS or SIMS. An ALD method employing one or both of a film formation condition with a high substrate temperature and impurity removal treatment can sometimes form a film with smaller amounts of carbon and chlorine than an ALD method without the film formation condition with a high substrate temperature or the impurity removal treatment.

Examples of the ALD method include a thermal ALD method, in which a precursor and a reactant react with each other only by a thermal energy, and a plasma-enhanced ALD (PEALD) method, in which a reactant excited by plasma is used.

In a deposition apparatus employing an ALD method, deposition is performed in such a manner that a first source gas (also referred to as a precursor or a metal precursor in some cases) and a second source gas (also referred to as a reactant, an oxidizer, or a nonmetallic precursor in some cases) are alternately introduced into a chamber for reaction, and then the introduction of these source gases is repeated. Note that the source gases to be introduced can be switched by switching the respective switching valves (also referred to as high-speed valves in some cases), for example. When the source gases are introduced, an inert gas such as nitrogen (N₂), argon (Ar), or helium (He) may be introduced as a carrier gas with the source gases into the chamber. With the use of a carrier gas, the source gases can be inhibited from being adsorbed onto an inner side of a pipe and an inner side of a valve and can be introduced into the chamber, even in the case where the volatility of the source gases is low or the vapor pressure is low. Moreover, uniformity of the formed film is improved, which is preferable.

An ALD method in which a plurality of kinds of precursors are introduced at the same time enables formation of a film with a desired composition. In the case where a plurality of different kinds of precursors are introduced, the number of cycles for each precursor is controlled, whereby a film with a desired composition can be formed.

First, as illustrated in FIGS. 9A and 9B, the substrate 10 is prepared, and the insulating layer 20 is formed over the substrate 10. The top surface of the insulating layer 20 is preferably flat. For example, the top surface of the insulating layer 20 is preferably planarized by planarization treatment using a chemical mechanical polishing (CMP) method or the like to improve flatness. In the case where the top surface of the insulating layer 20 is flat, the crystallinity of the semiconductor layer 30 to be formed later can be increased. For example, lateral growth of the crystal included in the semiconductor layer 30 can be promoted in the later-described first heat treatment.

The insulating layer 20 can be formed by a sputtering method in an atmosphere containing oxygen, for example. Since a molecule containing hydrogen is not used as a film formation gas in the sputtering method, the concentration of hydrogen in the insulating layer 20 can be reduced. When the insulating layer 20 is formed by a sputtering method in an atmosphere containing oxygen, oxygen can be added to the insulating layer 20. By heat applied after the formation of the semiconductor layer 30 or the like, oxygen can be supplied from the insulating layer 20 to the semiconductor layer 30 to reduce oxygen vacancies. For example, when a silicon oxide film is formed by a sputtering method as the insulating layer 20, the top surface of the insulating layer 20 can be flat.

Before the layer 29 is formed, heat treatment is preferably performed. The heat treatment is performed, for example, at higher than or equal to 250° C. and lower than or equal to 650° C., preferably higher than or equal to 300° C. and lower than or equal to 500° C., further preferably higher than or equal to 320° C. and lower than or equal to 450° C. Even in the case where the heat treatment is performed, by setting the temperature within the above-described range, deformation (distortion or warpage) of the substrate can be significantly inhibited.

The heat treatment is performed in a nitrogen gas atmosphere, an inert gas atmosphere, or an atmosphere containing an oxidizing gas at 10 ppm (0.001%) or more, 1% or more, or 10% or more. For example, in the case where the heat treatment is performed in a mixed atmosphere of a nitrogen gas and an oxygen gas, the proportion of the oxygen gas is preferably approximately 20%. The heat treatment may be performed under a reduced pressure. Alternatively, heat treatment may be performed in an atmosphere of a nitrogen gas or an inert gas, and then another heat treatment may be performed in an atmosphere containing an oxidizing gas at 10 ppm or more, 1% or more, or 10% or more in order to compensate for released oxygen. By the above-described heat treatment, impurities such as hydrogen and water contained in the insulating layer 20 or the like can be reduced before the semiconductor layer 30 is formed.

The gas used in the above-described heat treatment is preferably highly purified. For example, the amount of moisture contained in the gas used in the above-described heat treatment is preferably less than 1 ppb (1×10⁻³ ppm), further preferably less than 0.1 ppb (1×10⁻⁴ ppm), still further preferably less than 0.05 ppb (5×10⁻⁵ ppm). The heat treatment using a highly purified gas can prevent the entry of moisture or the like into the insulating layer 20 or the like as much as possible.

The heating apparatus used for the heat treatment is not limited to a particular apparatus, and may be an apparatus for heating an object to be processed by heat conduction or heat radiation from a heating element such as a resistance heating element. For example, an electric furnace, or a rapid thermal annealing (RTA) apparatus such as a lamp rapid thermal annealing (LRTA) apparatus or a gas rapid thermal annealing (GRTA) apparatus can be used. An LRTA apparatus is an apparatus for heating an object to be processed by radiation of light (an electromagnetic wave) emitted from a lamp such as a halogen lamp, a metal halide lamp, a xenon arc lamp, a carbon arc lamp, a high pressure sodium lamp, or a high pressure mercury lamp. A GRTA apparatus is an apparatus for heat treatment using a high-temperature gas.

Treatment for supplying oxygen is preferably performed before the layer 29 is formed. Accordingly, oxygen can be supplied to the insulating layer 20, and the oxygen can be supplied from the insulating layer 20 to the semiconductor layer 30 by heat applied after formation of the semiconductor layer 30, for example.

Examples of the treatment for supplying oxygen include heat treatment in an oxygen-containing atmosphere and plasma treatment in an oxygen-containing atmosphere. Note that the plasma treatment in this specification and the like includes microwave plasma treatment described later. Alternatively, for example, an oxide film (preferably a metal oxide film) may be formed by a sputtering method in an oxygen-containing atmosphere to supply oxygen to the insulating layer 20. The formed oxide film may be removed immediately or left as it is. In the case where the formed oxide film is left as it is, the oxide film can be used as part of the semiconductor layer 30. An oxygen-containing atmosphere can include not only an oxygen gas (O₂) but also a gas of an oxygen-containing compound such as ozone (O₃) or dinitrogen monoxide (N₂O). The substrate temperature in the plasma treatment is higher than or equal to room temperature (25° C.) and lower than or equal to 450° C.

Next, the layer 29 is formed over the insulating layer 20 (FIGS. 9A and 9B). The layer 29 functions as a seed or a nucleus for crystal growth of the semiconductor layer 30. Thus, the layer 29 can be referred to as a seed layer, a seed crystal, or the like.

There is no particular limitation on the method for forming the layer 29. For example, a film to be the insulating layer 29 is formed and then processed, whereby the layer 29 can be formed. The insulating film can be formed by a sputtering method, a CVD method, a vacuum evaporation method, an MBE method, a PLD method, an ALD method, or the like.

The layer 29 can be formed by a sputtering method. When the layer 29 is formed by a sputtering method, the crystallinity of the layer 29 can be increased. When the layer 29 is formed by a sputtering method in an oxygen-containing atmosphere, oxygen can be added to the insulating layer 20.

In the case where a sputtering target contains a plurality of crystal grains each of which has a layered structure and an interface at which the crystal grain is easily cleaved, ion collision with the sputtering target might cleave crystal grains to make a plate-like or pellet-like sputtering particle. The plate-like or pellet-like sputtering particle deposited over the insulating layer 20 may be used as the layer 29.

In the case where a film to be the layer 29 is formed and processed into the layer 29, one or both of a wet etching method and a dry etching method can be used for the processing of the film. The film is preferably processed by a wet etching method. The wet etching method is less likely to cause damage than the dry etching method in some cases. Thus, damage to the insulating layer 20 can be reduced, and the flatness of the top surface of the insulating layer 20 can be maintained.

Alternatively, a depressed portion is formed in the insulating layer 20, a film to be the layer 29 is embedded in the depressed portion, and the film is polished by CMP treatment or the like until the surface of the insulating layer 20 is exposed, whereby the layer 29 illustrated in FIGS. 6D and 6E or the layer 29 illustrated in FIG. 6F can be formed. Thus, a formation surface of the semiconductor layer 30 can be formed flat.

As described above, forming the layer 29 before the formation of the semiconductor layer 30 can reduce the influence of heat on the semiconductor layer 30, thereby inhibiting a reduction in the crystal grain size in the semiconductor layer 30 and an increase in the number of crystal grain boundaries.

Next, as illustrated in FIGS. 9C and 9D, the semiconductor layer 30 is formed to cover the layer 29. The semiconductor layer 30 is preferably formed by a sputtering method. As a sputtering gas, a single gas of a noble gas (typically argon), a single gas of oxygen, a mixed gas of a noble gas and oxygen, or the like can be used. The proportion of a noble gas (typically, argon) in the whole sputtering gas is, for example, higher than or equal to 50% and lower than or equal to 100%, preferably higher than or equal to 70% and lower than or equal to 100%, further preferably higher than or equal to 90% and lower than or equal to 100%. By increasing the proportion of a noble gas (typically, argon) in the whole sputtering gas, the semiconductor layer 30 with low crystallinity can be formed. In addition, the semiconductor layer 30 having many dangling bonds can be formed. Thus, the etching rate of the semiconductor layer 30 can be increased. Thus, the semiconductor layer 30 can be easily processed and the productivity of the semiconductor device can be increased. Note that the semiconductor layer 30 having low crystallinity has an amorphous structure, for example.

Note that the sputtering gas can also contain hydrogen (H₂). Hydrogen is introduced when the semiconductor layer 30 is formed by a sputtering method, whereby the semiconductor layer 30 with low crystallinity can be formed. In addition, generation of a crystal nucleus can be inhibited or disappearance of a crystal nucleus can be promoted at the time of forming the semiconductor layer 30. In the case where the number of crystal nuclei is large, grown crystals collide with each other, which inhibits an increase in grain size. That is, a crystal with a small grain size is formed. In contrast, when generation of a crystal nucleus is inhibited and some crystal nuclei in the film are eliminated to reduce the number of crystal nuclei and first heat treatment described later is performed, crystal growth can be promoted from a smaller number of crystal nuclei, which can increase the crystal grain size in the semiconductor layer 30.

The semiconductor layer 30 can also be formed by a sputtering method in an oxygen-containing atmosphere. At this time, the use of a sputtering method that does not use a molecule containing hydrogen as a film formation gas can reduce the concentration of hydrogen in the semiconductor layer 30. For example, oxygen or a mixed gas of oxygen and a noble gas is preferably used as the sputtering gas.

The semiconductor layer 30 may be formed by an ALD method. The semiconductor layer 30 can be formed using a first precursor and a first oxidizer. The first precursor preferably contains indium. In that case, an indium oxide film is formed as the semiconductor layer 30. That is, an oxide film containing a single element besides oxygen is formed. In the case where the first precursor contains indium, a thermal ALD method can be used as the ALD method.

As the precursor containing indium, it is possible to use trimethylindium, triethylindium, ethyldimethylindium, tris(1-methylethyl)indium, tris(2,2,6,6-tetramethyl-3,5-heptanedionato)indium, cyclopentadienylindium, indium(III) acetylacetonate, (3-(dimethylamino)propyl)dimethylindium, (diethylphosphino)dimethylindium, chlorodimethylindium, bromodimethylindium, dimethyl(2-propanolato)indium, or the like.

As the precursor containing indium, an inorganic precursor not containing hydrocarbon may be used. As the inorganic precursor containing indium, it is possible to use a halogen-based indium compound such as trifluoroindium (indium(III) fluoride), indium trichloride (indium(III) chloride), indium tribromide (indium(III) bromide), or indium triiodide (indium(III) iodide). The decomposition temperature of indium trichloride is approximately higher than or equal to 500° C. and lower than or equal to 700° C. Thus, with the use of indium trichloride, film formation can be performed by an ALD method while a substrate is being heated at approximately higher than or equal to 400° C. and lower than or equal to 600° C., e.g., at 500° C.

In the method for forming the semiconductor layer 30, it is preferable to use a precursor with a low impurity concentration, i.e., a high-purity precursor. For example, the use of a precursor having a purity higher than or equal to 3N (99.9%), preferably higher than or equal to 4N (99.99%), further preferably higher than or equal to 5N (99.999%), still further preferably higher than or equal to 6N (99.9999%) can reduce impurities in the semiconductor layer 30.

The gallium content and the aluminum content in the precursor containing indium are each preferably less than or equal to 1000 ppm, further preferably less than or equal to 500 ppm, still further preferably less than or equal to 100 ppm, yet further preferably less than or equal to 50 ppm, yet still further preferably less than or equal to 10 ppm, yet still further preferably less than or equal to 1 ppm. With the use of a precursor having a small gallium content, the concentration of gallium in the semiconductor layer 30 can be reduced and the reliability of the transistor can be increased. Furthermore, the use of a precursor containing a small amount of aluminum can reduce the concentration of aluminum in the semiconductor layer 30, so that the crystallinity of the semiconductor layer 30 can be improved.

As the precursor used in this embodiment, a precursor purified by two or more times of distillation (also referred to as “rectification” or “precision distillation”) is preferably used. The use of such a precursor is preferable to facilitate deposition of a metal oxide containing few impurities. Distillation is preferably performed a plurality of times to further inhibit impurities due to a starting material used to produce the precursor from remaining in the precursor. Note that the present invention is not limited to the above, and a precursor subjected to distillation once, i.e., single distillation, may be used. The single distillation is preferable in terms of a reduction in manufacturing cost.

By performing one or more times of distillation, the aluminum content in the precursor containing indium can be lower than or equal to 100 ppm, lower than or equal to 1 ppm, or lower than or equal to 1 ppm (0.001 ppm). With the use of the precursor containing indium, an indium oxide film having a purity substantially equal to the purity of silicon (10N) used for the semiconductor layer can be formed.

Ozone (O₃), oxygen (O₂), water (H₂O), hydrogen peroxide (H₂O₂), or the like can be used as the first oxidizer. The first oxidizer preferably contains at least one of ozone and oxygen. When ozone, oxygen, or the like not containing hydrogen is used as the first oxidizer, the amount of hydrogen mixed into the insulating layer 20 can be reduced. The first oxidizer can contain at least one of water and hydrogen peroxide. Thus, the semiconductor layer 30 with low crystallinity can be formed.

In this specification and the like, unless otherwise specified, ozone, oxygen, and water that can be used as an oxidizer include not only those in gas or molecular states but also those in plasma, radical, and ion states.

The pulse time for introducing the first oxidizer is preferably longer than or equal to 0.1 seconds and shorter than or equal to 30 seconds, further preferably longer than or equal to 0.3 seconds and shorter than or equal to 15 seconds, still further preferably longer than or equal to 0.3 seconds and shorter than or equal to 10 seconds. The pulse time of introducing the first oxidizer is shortened to reduce the amount of introduced first oxidizer, so that a larger amount of hydrogen contained in the first precursor remains in the film. When a larger amount of hydrogen remains in the film, generation of crystal nuclei can be inhibited and some crystal nuclei in the film can be eliminated; accordingly, the number of crystal nuclei in the film can be reduced.

Here, the substrate heating temperature at the time of introducing the first precursor into a reaction chamber is preferably a temperature corresponding to the decomposition temperature of the first precursor. Here, in the case of a thermal ALD method in which triethylindium is used as the precursor containing indium, the substrate heating temperature can be higher than or equal to 100° C. and lower than or equal to 350° C., preferably higher than or equal to 150° C. and lower than or equal to 300° C., for example. Note that in the case where the layer 29 is provided, the substrate heating temperature can be higher than or equal to room temperature (25° C.) and lower than or equal to 300° C., preferably higher than or equal to room temperature and lower than or equal to 200° C., further preferably higher than or equal to room temperature and lower than or equal to 150° C. When the substrate heating temperature is lowered, the crystallinity of the semiconductor layer 30 at the time of deposition can be lowered.

In the case where the semiconductor layer 30 has a stacked-layer structure, the semiconductor layer 30 can also be formed by a sputtering method and an ALD method, for example. In the case where the semiconductor layer 30 has a two-layer structure of a first semiconductor layer and a second semiconductor layer over the first semiconductor layer, for example, the first semiconductor layer can be formed by an ALD method and the second semiconductor layer can be formed by a sputtering method. Since an ALD method is a deposition method that provides higher coverage than a sputtering method, forming the first semiconductor layer by an ALD method can improve the coverage with the semiconductor layer 30. Furthermore, damage to a base (here, the insulating layer 20) can be reduced, and a mixed layer at the interface between the base and the semiconductor layer 30 can be inhibited, so that higher crystallinity can be achieved. When the second semiconductor layer is formed by a sputtering method, the productivity can be increased.

Alternatively, the first semiconductor layer may be formed by a sputtering method and the second semiconductor layer may be formed by an ALD method. Even when a pin hole, disconnection, or the like is in the first semiconductor layer formed by a sputtering method, the second semiconductor layer formed by an ALD method with favorable coverage can fill the portion.

Then, the semiconductor layer 30 is processed into a desired shape. In FIGS. 9E and 9F, the semiconductor layer 30 and the insulating layer 20 are processed into island shapes to form a structure body including the semiconductor layer 30 and the insulating layer 20. Specifically, the semiconductor layer 30 and the insulating layer 20 are processed so that a plurality of structure bodies are provided to be apart from each other in the X direction and the Y direction.

Note that as illustrated in FIGS. 9G and 9H, processing may be performed so that a portion that is of the insulating layer 20 and does not overlap with the semiconductor layer 30 is left. In this case, it can be said that the insulating layer 20 includes a projecting portion in a portion overlapping with the semiconductor layer 30.

Note that the second element is preferably supplied (can also be referred to as “added” or “injected”) to the semiconductor layer 30 before the semiconductor layer 30 is processed. Thus, the second element is supplied to the semiconductor layer 30. The supply of the second element to the semiconductor layer 30 can lower the crystallinity of the semiconductor layer 30. Thus, the semiconductor layer 30 can be easily processed and the productivity of the semiconductor device can be increased.

As the second element, one or more kinds selected from hydrogen and a noble gas (helium, neon, argon, krypton, xenon, and the like) are preferably used.

Plasma treatment can be suitably employed for supplying the second element. The second element can be supplied in such a manner that plasma is generated in a gas atmosphere containing the second element to be supplied and plasma treatment is performed. A dry etching apparatus, an ashing apparatus, a plasma CVD apparatus, a high-density plasma CVD apparatus, or the like can be used to generate the plasma. The second element is preferably accelerated and supplied to increase the collision energy at the time of supplying the second element to the semiconductor layer 30 and further efficiently lower the crystallinity of the semiconductor layer 30.

Note that the supply of the second element is not limited to the above-described method, and an ion implantation method can be used, for example. In the ion implantation method, the concentration profile in the depth direction can be highly accurately controlled by the acceleration energy and the dosage of ions. With the use of an ion implantation method in which a source gas is ionized and the ion is subjected to mass separation and then supplied, ions having a certain mass can be supplied and the purity of the second element to be supplied can be increased. Alternatively, an ion implantation method in which ions are supplied without mass separation may be used, in which case the productivity can be increased. In this specification and the like, there is no limitation on whether mass separation is performed unless otherwise specified. Note that a method in which ions are subjected to mass separation and then supplied is referred to as an ion implantation method, and a method in which ions are supplied without mass separation is referred to as an ion doping method in some cases.

As the source gas, a gas containing the second element can be used. In the case where argon is used as the second element, an argon gas can be used as the source gas. In the case where argon and hydrogen are used as the second element, a mixed gas of an argon gas and a hydrogen gas can be used as the source gas. Alternatively, a mixed gas of a gas containing the second element and another gas can be used. Note that the source material used for supplying the second element is not limited to a gas, and a solid or a liquid can also be employed by being vaporized by heating.

Then, first heat treatment is performed. The first heat treatment is preferably performed in an atmosphere containing at least one of hydrogen (H₂) and nitrogen (N₂), for example, and further preferably performed in an atmosphere containing hydrogen (H₂) and nitrogen (N₂). In that case, the hydrogen flow rate ratio is preferably higher than or equal to 3% and lower than or equal to 15%, further preferably higher than or equal to 5% and lower than or equal to 10%. Note that the hydrogen flow rate ratio refers to the proportion of the flow rate of a hydrogen gas with respect to the flow rate of the total gas. The temperature of the first heat treatment is preferably higher than or equal to 120° C. and lower than or equal to 300° C., further preferably higher than or equal to 120° C. and lower than or equal to 250° C., still further preferably higher than or equal to 120° C. and lower than or equal to 200° C. The time of the first heat treatment is preferably longer than or equal to one hour and shorter than or equal to 8 hours.

By performing the first heat treatment, epitaxial growth of the semiconductor layer 30 and lateral growth of a crystal grain can progress using the layer 29 as a seed or a nucleus, so that the crystallinity of the semiconductor layer 30 can be increased. In particular, when a material with a low thermal expansion coefficient is used for the insulating layer 20, crystal growth can be promoted. For example, when a crystal grain is formed in a portion of the semiconductor layer 30 that overlaps with the layer 29 and the crystal grain is laterally grown, crystal growth of the semiconductor layer 30 can be performed along the formation surface. That is, as illustrated in FIGS. 10A and 10B, the crystal is laterally grown with the layer 29 as a seed or a nucleus, and a region 31c spreads. The region 31c has higher crystallinity than a region 31a. As the processing time goes on, the region 31c further spreads along the formation surface. At the end of the first heat treatment, the region 31c spreads to the whole semiconductor layer 30 (FIGS. 10C and 10D). In this manner, the crystallinity of the semiconductor layer 30 can be increased. Indium oxide whose crystallinity is increased by crystal growth in the lateral direction with a crystal nucleus as a starting point can be referred to as lateral growth indium oxide (LGIO).

When silicon oxide with a low thermal expansion coefficient is used for the insulating layer 20 and tensile stress is applied to the indium oxide from the top surface of the insulating layer 20 at the time of temperature decrease, crystal growth of the semiconductor layer 30 can be promoted.

Then, second heat treatment is performed. The second heat treatment is preferably performed in an atmosphere containing nitrogen and oxygen (with a typical volume ratio of nitrogen to oxygen of 4:1). The temperature of the second heat treatment is preferably higher than or equal to that of the first heat treatment. For example, the temperature of the second heat treatment is preferably higher than or equal to 300° C. and lower than or equal to 400° C., further preferably higher than or equal to 300° C. and lower than or equal to 350° C. The time of the second heat treatment is preferably longer than or equal to one hour and shorter than or equal to 4 hours.

A gas used in the second heat treatment preferably has high purity. The heat treatment using a highly purified gas can prevent entry of moisture or the like into the semiconductor layer 30 as much as possible.

There is no particular limitation on the heat treatment used for the second heat treatment, and an electric furnace, an RTA apparatus, or the like can be used, for example.

By performing the first heat treatment at a temperature lower than that of the second heat treatment, generation of a crystal nucleus can be inhibited and an increase in crystal grain size can be promoted. Since the first heat treatment is performed in a reducing atmosphere, the amount of oxygen vacancies contained in the semiconductor layer 30 is increased. Then, the second heat treatment can supply oxygen to the semiconductor layer 30 and fill (nullify) oxygen vacancies with the supplied oxygen. When the first heat treatment is performed at a temperature lower than that of the second heat treatment, impurities remain in the semiconductor layer 30 in some cases. Thus, the second heat treatment is performed at a temperature higher than that of the first heat treatment, whereby the impurity concentration in the semiconductor layer 30 can be reduced. In addition, the hydrogen concentration in the semiconductor layer 30 can be reduced. Furthermore, the second heat treatment can further increase the crystal grain size in the semiconductor layer 30.

The first heat treatment and the second heat treatment performed in this order as described above enable crystal growth of the semiconductor layer 30 and a reduction in the amount of oxygen vacancies and impurities in the semiconductor layer 30.

After the formation of the semiconductor layer 30, microwave plasma treatment may be performed. The microwave plasma treatment can reduce the concentration of impurities such as hydrogen or water contained in the semiconductor layer 30. In addition, the crystal region of the semiconductor layer 30 grows in some cases.

In this specification and the like, a microwave refers to an electromagnetic wave having a frequency greater than or equal to 300 MHz and less than or equal to 300 GHz. Microwave plasma treatment refers to, for example, treatment using an apparatus including a power source for generating high-density plasma using microwaves. Microwave plasma treatment can also be referred to as microwave-excited high-density plasma treatment.

By performing microwave plasma treatment in an oxygen-containing atmosphere, the impurity concentration in the semiconductor layer 30 can be reduced. Examples of impurities include carbon. Although the microwave plasma treatment in an oxygen-containing atmosphere is performed on the semiconductor layer 30 in the above-described example, one embodiment of the present invention is not limited thereto. For example, microwave plasma treatment in an oxygen-containing atmosphere may be performed on an insulating film, specifically a silicon oxide film, which is provided in the vicinity of the semiconductor layer 30. Furthermore, the crystallinity of the semiconductor layer 30 is sometimes increased by heat in the microwave plasma treatment.

The microwave plasma treatment is preferably performed under a reduced pressure, and the pressure is preferably higher than or equal to 10 Pa and lower than or equal to 1000 Pa, further preferably higher than or equal to 50 Pa and lower than or equal to 700 Pa, still further preferably higher than or equal to 100 Pa and lower than or equal to 400 Pa. The treatment temperature is preferably higher than or equal to room temperature (25° C.) and lower than or equal to 750° C., further preferably higher than or equal to 300° C. and lower than or equal to 500° C., and can be higher than or equal to 400° C. and lower than or equal to 450° C.

In the microwave plasma treatment, substrate heating may be performed. The substrate heating temperature is preferably higher than or equal to room temperature (e.g., 25° C.), higher than or equal to 100° C., higher than or equal to 200° C., higher than or equal to 300° C., or higher than or equal to 400° C., and lower than or equal to 500° C. or lower than or equal to 450° C. For example, the substrate heating temperature is preferably higher than or equal to room temperature and lower than or equal to 500° C., further preferably higher than or equal to 100° C. and lower than or equal to 450° C., still further preferably higher than or equal to 200° C. and lower than or equal to 450° C., yet still further preferably higher than or equal to 300° C. and lower than or equal to 450° C., yet still further preferably higher than or equal to 400° C. and lower than or equal to 450° C.

The microwave plasma treatment can be performed using an oxygen gas and an argon gas, for example. Note that when the oxygen flow rate ratio (O₂/(O₂+Ar)) in the microwave plasma treatment is too high, discharging tends to be unstable. In view of this, the oxygen flow rate ratio (O₂/(O₂+Ar)) is, for example, preferably higher than 0% and lower than or equal to 50%, further preferably higher than 0% and lower than or equal to 40%, still further preferably higher than 0% and lower than or equal to 30%.

In the microwave plasma treatment using an oxygen gas and an argon gas, oxygen radicals can be mainly in three states: triplet oxygen (O(³Pⱼ)), singlet oxygen (O(¹D₂)), and an oxygen ion (O₂⁺). The oxygen ion effectively acts for reducing the hydrogen concentration in an oxide film by the microwave plasma treatment. The amount of oxygen radicals in each state changes depending on the oxygen flow rate ratio or a pressure in the microwave plasma treatment. For example, the amount of oxygen ions tends to increase under a condition with a low oxygen flow rate ratio and a low pressure. Meanwhile, an excessively low oxygen flow rate ratio or pressure might destabilize the control of the oxygen flow rate, thereby making stable discharging difficult or causing etching of an oxide film, for example. Therefore, for example, the oxygen flow rate ratio (O₂/(O₂+Ar)) in the microwave plasma treatment is preferably higher than 0% and lower than or equal to 10%, further preferably higher than or equal to 0.5% and lower than or equal to 5%, still further preferably higher than or equal to 0.5% and lower than or equal to 3%, and is typically preferably 1%.

As the microwave plasma treatment time is shorter, the productivity becomes higher. In view of this, the microwave plasma treatment time is preferably longer than or equal to 1 minute and shorter than or equal to 60 minutes, further preferably longer than or equal to 1 minute and shorter than or equal to 30 minutes, still further preferably longer than or equal to 1 minute and shorter than or equal to 10 minutes.

The microwave plasma treatment in an oxygen-containing atmosphere can convert an oxygen gas into plasma by using a high-frequency wave such as a microwave or an RF, and apply, to the oxide semiconductor layer, oxygen radicals that are generated by conversion of the oxygen gas into plasma. By the effects of plasma, a microwave, oxygen radicals, and the like, hydrogen can be removed from the oxide semiconductor layer. In this manner, the concentration of hydrogen in the oxide semiconductor layer can be reduced. At this time, carbon bonded to oxygen, hydrogen, or the like can also be removed in some cases. Performing the microwave plasma treatment in such a manner can reduce impurities. Supplying the oxygen radicals to oxygen vacancies formed in the oxide semiconductor layer can further reduce oxygen vacancies in the oxide semiconductor layer.

Meanwhile, when part of oxygen that has been present in the oxide semiconductor before the microwave plasma treatment reacts with hydrogen in the oxide semiconductor, i.e., a reaction “2H +O→H₂O↑” occurs, the hydrogen can be removed in the form of H₂O (i.e., dehydration or dehydrogenation can be performed). H₂O is a limiting factor in improving crystallinity and thus is preferably removed from the oxide semiconductor. Hydrogen in the oxide semiconductor is removed in the form of H₂O to reduce the hydrogen concentration in the oxide semiconductor, whereby an improvement in crystallinity can be promoted. When the temperature of the microwave plasma treatment is increased, the hydrogen concentration in the oxide semiconductor can be further reduced.

In addition, the microwave plasma treatment may be followed successively by heat treatment without exposure to the air. The heat treatment temperature is preferably higher than or equal to 100° C. and lower than or equal to 750° C., further preferably higher than or equal to 300° C. and lower than or equal to 500° C., still further preferably higher than or equal to 400° C. and lower than or equal to 450° C., for example. Even in the case where the heat treatment is performed, by setting the temperature within the above-described range, deformation (distortion or warpage) of the substrate can be significantly inhibited.

Note that the crystallinity can also be improved by performing plasma treatment using an oxygen gas, instead of the microwave plasma treatment.

Oxygen supplied to the oxide semiconductor layer is in any of a variety of forms such as an oxygen atom, an oxygen molecule, an oxygen ion (a charged oxygen atom or a charged oxygen molecule), and an oxygen radical (an oxygen atom, an oxygen molecule, or an oxygen ion having an unpaired electron). Oxygen injected into the oxide semiconductor layer preferably has one or more of the above forms. An oxygen radical is particularly preferable.

Note that treatment for supplying hydrogen to the semiconductor layer 30 (also referred to as hydrogenation treatment) may be performed before the formation of the insulating layer 50. By supplying hydrogen to the semiconductor layer 30, a dangling bond existing at the crystal grain boundary or the like is terminated, whereby the electrical characteristics and reliability of the transistor are improved in some cases. Examples of the treatment for supplying hydrogen include heat treatment and plasma treatment in an atmosphere containing hydrogen.

Next, the insulating layer 80 is formed to cover the semiconductor layer 30, and the opening portion 89 overlapping with part of the semiconductor layer 30 is formed in the insulating layer 80. As described above, the opening portion 89 is preferably formed at a position not overlapping with the layer 29.

Then, the insulating layer 50 is formed so as to cover the opening portion 89. The insulating layer 50 is preferably formed by an ALD method. The insulating layer 50 can be formed using a second precursor and a second oxidizer. The second precursor preferably contains one of aluminum and hafnium. In that case, an aluminum oxide film or a hafnium oxide film is formed as the insulating layer 50. That is, an oxide film containing a single element besides oxygen is formed. In the case where the second precursor contains one of aluminum and hafnium, a thermal ALD method can be used as an ALD method.

As the precursor containing aluminum, aluminum chloride, trimethylaluminum, or the like can be used, for example. As the precursor containing hafnium, hafnium tetrachloride, tetrakis(ethylmethylamide)hafnium (TEMAHf), or the like can be used, for example.

As the second oxidizer, any of the above-described materials that can be used as the first oxidizer can be used. Note that the first oxidizer and the second oxidizer may be formed using the same oxidizer or different oxidizers.

In an ALD process, a step in which a precursor is introduced into a chamber and adsorbed onto a substrate surface is performed. Here, the precursor is adsorbed onto the substrate surface, whereby a self-limiting mechanism of surface chemical reaction works and no more precursor is adsorbed onto a layer of the precursor over the substrate. Note that the proper range of substrate temperatures at which the self-limiting mechanism of surface chemical reaction works is also referred to as an ALD window. The ALD window depends on the temperature characteristics, vapor pressure, decomposition temperature, and the like of a precursor. That is, the ALD window differs between precursors. Thus, in the case where an oxide film containing a plurality of kinds of elements besides oxygen is formed, the film formation conditions need to be adjusted in consideration of the ALD windows of precursors. Meanwhile, in the case where an oxide film containing a single element besides oxygen, such as an indium oxide film or an aluminum oxide film, is formed, the film formation conditions can be adjusted in consideration of the ALD window of only one kind of precursor, which facilitates the adjustment of the film formation conditions and enables a high-quality oxide film to be formed.

After the formation of the insulating layer 50, microwave plasma treatment is preferably performed. The microwave plasma treatment can reduce the concentration of impurities such as hydrogen and water contained in the semiconductor layer 30. The above description can be referred to for the details of the microwave plasma treatment.

Next, the conductive layer 60 is formed over the insulating layer 50 to fill the opening portion 89. Through the above-described steps, the semiconductor device illustrated in FIGS. 1A to 1F can be manufactured.

Note that in the case where the conductive layer 40a and the conductive layer 40b are provided over the semiconductor layer 30 as illustrated in FIG. 8B, after the semiconductor layer 30 having crystallinity is formed, a conductive layer to be the conductive layer 40a and the conductive layer 40b is formed over the semiconductor layer 30, the insulating layer 80 is formed over the conductive layer, the opening portion 89 is formed in the insulating layer 80, and a portion of the conductive layer that overlaps with the opening portion 89 is removed. Thus, the conductive layer 40a and the conductive layer 40b are formed from the conductive layer.

In FIGS. 1A to 1F, the layer 29 and the semiconductor layer 30 in the vicinity of the layer 29 remain without being removed. This can reduce the number of manufacturing steps of the semiconductor device. The present invention is not limited thereto. For example, the layer 29 and the semiconductor layer 30 in the vicinity of the layer 29 may be removed.

Note that in the case where the semiconductor layer 30 is formed by an ALD method, the semiconductor layer 30 having crystallinity can sometimes be formed using the layer 29 as a seed or a nucleus in the process of forming the semiconductor layer 30. For example, when the substrate heating temperature in deposition by an ALD method is higher than or equal to 100° C. and lower than or equal to 300° C., or higher than or equal to 150° C. and lower than or equal to 250° C., the semiconductor layer 30 having crystallinity can be formed at the time of deposition. In that case, heat treatment for crystal growth of the semiconductor layer 30 is not necessarily performed. When the substrate heating temperature is excessively high, a crystal nucleus might be formed and an increase in crystal grain size might be hindered. By contrast, when the substrate heating temperature is excessively low, crystal growth might not occur in the process of forming the semiconductor layer 30.

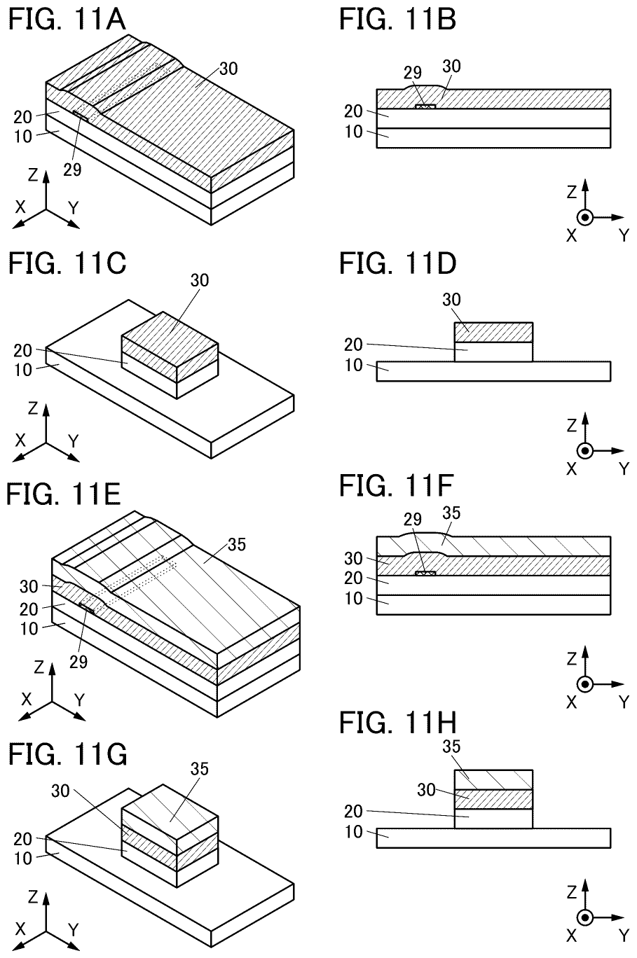

FIGS. 11A and 11B each illustrate a structure in which the semiconductor layer 30 having crystallinity, which is illustrated in FIGS. 10C and 10D, is formed in the step of forming the semiconductor layer 30 described with reference to FIGS. 9C and 9D. Note that FIGS. 11A and 11B illustrate a case where the layer 29 including a region extending in the X direction is used.

Note that in the case where the semiconductor layer 30 having crystallinity can be formed in the process of forming the semiconductor layer 30, at least one of the above-described first heat treatment, second heat treatment, microwave plasma treatment, and hydrogenation treatment may be performed. This might further increase the crystallinity of the semiconductor layer 30. In the case where the semiconductor layer 30 having crystallinity can be formed in the process of forming the semiconductor layer 30, the layer 29 may be removed in a later step. For example, as illustrated in FIGS. 11C and 11D, the semiconductor layer 30 and the insulating layer 20 can be processed into island shapes and the layer 29 can be removed. In this way, the semiconductor layer 30 with a flat top surface can be formed.

In the case where the semiconductor layer 30 having crystallinity can be formed in the process of forming the semiconductor layer 30, the semiconductor layer 30 can be processed into a desired shape after a layer is formed over the semiconductor layer 30. For example, as illustrated in FIGS. 11E to 11H, a layer 35 is formed over the semiconductor layer 30, and the layer 35, the semiconductor layer 30, and the insulating layer 20 can be processed into island shapes and the layer 29 can be removed. Note that the layer 35 may have a single-layer structure or a stacked-layer structure of two or more layers. In the case where the layer 35 is formed to have a stacked-layer structure, layers in the stacked-layer structure may be formed using the same material or may be formed using different materials. Note that “different materials” may refer to two or more kinds selected from a semiconductor material, an insulating material, and a conductive material.

### Example 2 of Method for Manufacturing Semiconductor Device

An example of a method for manufacturing a semiconductor device including a method for forming a semiconductor layer partly different from the above-described method is described below. Note that in order to avoid repeated description, description of the same portions as the portions described above is omitted and different portions are described in detail. Unless otherwise specified, the above description in Example 1 of method for manufacturing semiconductor device can be referred to for portions that are not described below.

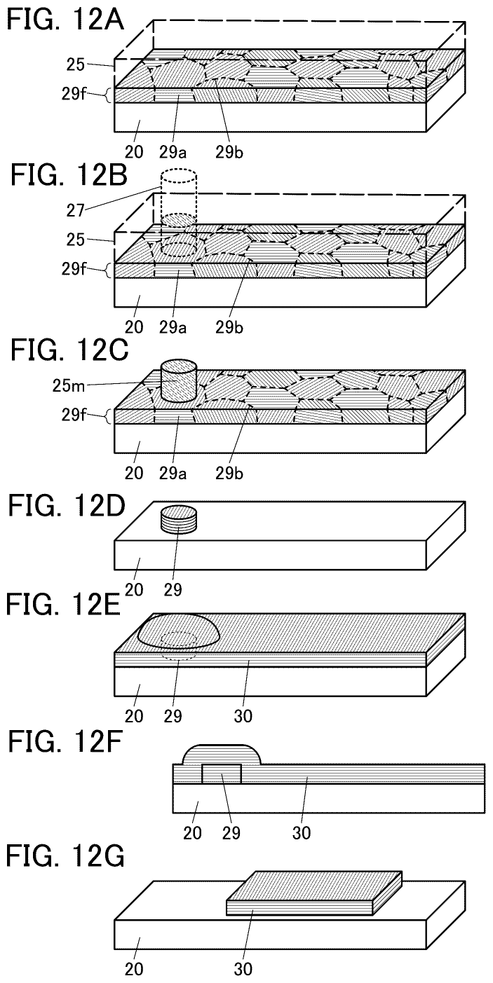

In the example of the method for manufacturing a semiconductor device described below, the layer 29 serving as a crystal nucleus can be formed of one grain included in a polycrystalline film. Specifically, the layer 29 is formed in such a manner that one of a plurality of grains included in a polycrystalline film is selected and the other grains that are not used are removed by etching. FIGS. 12A to 12E and FIG. 12G are schematic perspective views of steps in the example of the manufacturing method described below as an example.

First, the insulating layer 20 is formed over the substrate 10 (not illustrated), and a film 29f is formed over the insulating layer 20. After that, a resist mask 25 is formed to cover the film 29f (FIG. 12A).

The film 29f is a film part of which is to be the layer 29 later. The film 29f has a polycrystalline crystal structure. The film 29f includes a plurality of grains 29a and a grain boundary 29b between two of the grains 29a. In FIG. 12A and the like, different hatching patterns are shown to express different grains 29a. The grain boundary 29b is denoted by a dashed line.

For the resist mask 25, what is called a negative photosensitive resin, which has a lowered solubility by being exposed to light, is preferably used. The resist mask 25 preferably does not have sensitivity to a specific wavelength range. The resist mask 25 particularly preferably does not have sensitivity to visible light or the X-ray wavelength range.

Next, the film 29f is observed through the resist mask 25, one that meets the requirement is extracted from the plurality of grains 29a included in a predetermined range of the film 29f, and coordinates of the one grain 29a are determined. Examples of the requirement include the size, shape, and position. The one grain preferably has a shape such that at least the minimum irradiation region of a light-exposure apparatus used in a later light exposure step fits. In that case, if the resist mask 25 does not have sensitivity to the visible light wavelength range (i.e., has a light-transmitting property), an observation method using visible light can be employed.

An optical microscope using visible light is preferably used for the extraction of the grain 29a and the determination of the coordinates of the grain 29a. Using an image captured by a camera mounted in an optical microscope is preferable to visual observation, because of enabling the grain 29a that meets the requirement to be automatically extracted by image analysis. An analysis method utilizing artificial intelligence (AI) as well as a pattern matching method can be used for the image analysis.

In order to clarify the shape of the grain 29a, wet etching may be performed to etch part of the grain boundary. By making the heights of the plurality of grains 29a different by utilizing a difference in etching rate due to a difference in crystal orientation, the shape of the grains 29a can be clarified. For example, in the case of using a metal oxide film of indium oxide, IGZO, or the like as the film 29f, it is preferable to use a developer, a tetramethylammonium hydroxide (TMAH) aqueous solution, dilute hydrofluoric acid, oxalic acid, phosphoric acid, acetic acid, nitric acid, or a mixed solution containing two or more of these acids, for example. As a chemical solution used for the etching, either an acidic chemical solution or an alkaline chemical solution can be used. When an aqueous solution in which these chemical solutions are diluted is used, the etching rate can be lowered, so that the target grain can be prevented from being eliminated.

In addition to the above optical microscope, XRD analysis using X-rays may be performed to identify the crystal orientation of the grain 29a. In the case where a plurality of island-shaped semiconductor layers 30 are formed in the substrate, the crystal orientations of the semiconductor layers 30 can be made close to each other by setting the crystal orientations of the grains 29a used as their respective seed crystals to be close to each other, whereby variations in electrical characteristics of transistors due to variations in crystal orientations can be reduced in some cases. In the case where the crystal orientation can be estimated using the AI described above, XRD analysis is not necessarily used.

Subsequently, light exposure treatment and development treatment are performed. The determined region that fits in the grain 29a is irradiated with light 27, and a portion of the resist mask 25 positioned above the region is exposed to light (FIG. 12B). Then, development treatment is performed, so that a resist mask 25m is formed over the specific grain 29a (FIG. 12C). The light 27 is light having a wavelength range to which the resist mask 25 has sensitivity, and may be visible light or ultraviolet light, for example. In that case, the region irradiated with the light 27 preferably does not include the grain boundary 29b. Since the grain boundary 29b is a region with many defects, by avoiding the grain boundary 29b, the layer 29 formed later can be prevented from containing defects.

Next, the portion of the film 29f that is not covered with the resist mask 25m is removed by etching, so that the island-shaped layer 29 can be formed (FIG. 12D). The layer 29 thus formed is part of the one grain 29a and thus has a single crystal structure. The etching may be performed by dry etching or wet etching.

After that, the semiconductor layer 30 is formed to cover the layer 29 in a manner similar to the above, whereby the single crystal semiconductor layer 30 can be formed (FIG. 12E). FIG. 12F is a schematic cross-sectional view of a region including the layer 29 in FIG. 12E.

Here, the semiconductor layer 30 and the layer 29 are preferably formed using the same metal oxide. In this case, the semiconductor layer 30 can be homoepitaxially grown with the layer 29 as a seed or a nucleus, and the crystal orientation of the layer 29 and the crystal orientation of the semiconductor layer 30 are aligned with each other.

Then, part of the semiconductor layer 30 may be removed by etching to form the semiconductor layer 30 having an island shape (FIG. 12G). FIG. 12G illustrates a case where the layer 29 is also removed by etching.

In this way, the single crystal semiconductor layer 30 can be formed. With the use of the semiconductor layer 30 formed in this manner, a transistor having both a high on-state current and high reliability can be manufactured.

Note that the single crystal semiconductor layer 30 formed in this manner may be used as a seed crystal and a semiconductor film covering the semiconductor layer 30 may be further formed to form a single crystal semiconductor film. For example, in the case where the layer 29 contains an element different from that in the semiconductor layer 30, the element might be diffused into the semiconductor layer 30 as an impurity. Thus, a region of the semiconductor layer 30 that is apart from the layer 29 may be partly used as a seed crystal and a semiconductor film having the same composition as the semiconductor layer 30 may be crystallized, whereby a single crystal semiconductor film with a low impurity concentration and high purity can be obtained.

### Example 3 of Method for Manufacturing Semiconductor Device

Although the method in which the semiconductor layer 30 having crystallinity is formed by forming the semiconductor layer 30 over the layer 29 serving as a nucleus is described above, one embodiment of the present invention is not limited thereto. An example of the case where the layer 29 serving as a nucleus is formed over the semiconductor layer 30 is described below.

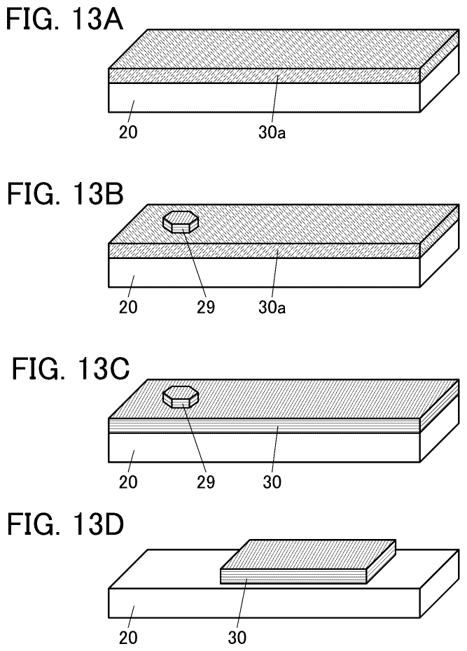

First, a semiconductor layer 30a is formed over the insulating layer 20 (FIG. 13A). The semiconductor layer 30a is a film with low crystallinity, such as an amorphous film or a microcrystalline film. When the semiconductor layer 30a is formed under a low substrate temperature condition at the time of deposition (e.g., lower than 150° C., lower than or equal to 100° C., lower than or equal to 50° C., or room temperature), for example, a film with low crystallinity can be formed. In the case where the semiconductor layer 30a is formed by a sputtering method, using a gas with a low proportion of oxygen (e.g., lower than or equal to 5%, preferably 0%) as a deposition gas can inhibit crystallization at the time of deposition and enables the semiconductor layer 30a having low crystallinity to be deposited.

Next, the island-shaped layer 29 is formed over the semiconductor layer 30a (FIG. 13B). The layer 29 has a single crystal structure. FIG. 13B illustrates the layer 29 with the shape of the outline in the plan view being hexagonal; however, one embodiment of the present invention is not limited thereto, and the outline of the layer 29 can have any shape such as a polygon other than a hexagon, a circular shape, or an elliptical shape.

For example, the layer 29 can be formed by the method described in Example 2 of method for manufacturing semiconductor device, that is, by forming a polycrystalline film and then removing, with part of a certain grain left, the other part.

In the case where a polycrystalline film is formed as the layer 29, the polycrystalline film is preferably deposited under the lowest possible substrate temperature condition (e.g., lower than 150° C., preferably lower than 100° C.). This can prevent crystallization of the semiconductor layer 30a and generation of a polycrystal at the time of depositing the layer 29. In the case where the layer 29 is formed by a sputtering method, using a gas with a high proportion of oxygen (e.g., higher than or equal to 10%, preferably higher than or equal to 20%, further preferably higher than or equal to 30%) as a deposition gas enables the layer 29 having higher crystallinity than the semiconductor layer 30a to be formed.

Etching is preferably performed by a method that applies as little heat as possible. For example, by etching a film by a wet etching method, the film can be processed at a low temperature and can be less damaged by etching, so that the layer 29 with few defects can be formed.

Alternatively, the layer 29 may be formed by a sputtering method using a shielding mask such as a metal mask, for example. Thus, the island-shaped layer 29 can be formed at a desired position. With such a method, a step of processing a film can be omitted, resulting in simplification of the process. In that case, with the use of a polycrystalline sputtering target, a minute particle having a single crystal structure that reflects the crystal structure of the sputtering target (the particle is also referred to as a pellet) can be attached to a specific position over the semiconductor layer 30a, and can be used as the layer 29.

Next, by performing heat treatment, the semiconductor layer 30a is crystallized using the layer 29 as a seed crystal, so that the single crystal semiconductor layer 30 can be obtained (FIG. 13C). For the heat treatment method, the above description of the first heat treatment can be referred to.

Then, an unnecessary portion of the semiconductor layer 30 and the layer 29 are removed by etching, so that the island-shaped semiconductor layer 30 is obtained (FIG. 13D). Note that a structure in which the layer 29 is not removed may be employed as well.

In this way, the single crystal semiconductor layer 30 can be formed. With the use of the semiconductor layer 30 formed in this manner, a transistor having both a high on-state current and high reliability can be manufactured.

### Application Example

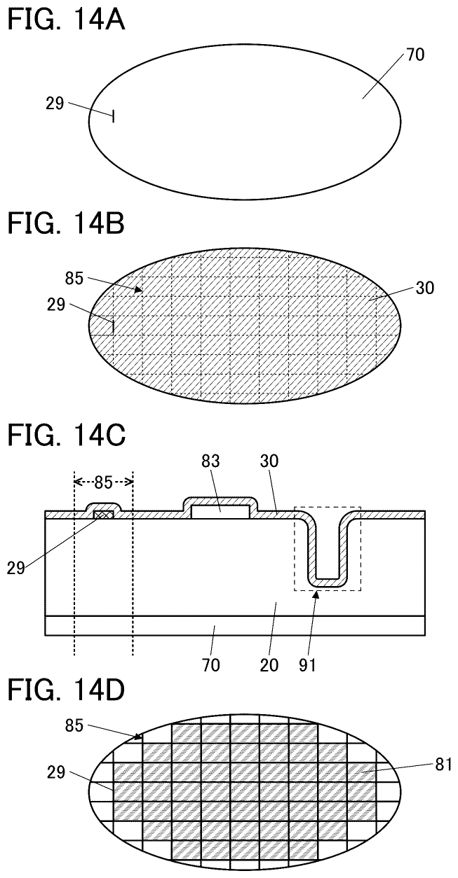

With the use of the method for forming a metal oxide layer of one embodiment of the present invention, the semiconductor layer 30 can have a large area. Accordingly, a transistor including the semiconductor layer 30 and a semiconductor chip including the transistor can be mass-produced with high yield. A method for manufacturing a semiconductor chip 81 will be described below with reference to FIGS. 14A to 14D.

FIG. 14A is a schematic perspective view of a substrate 70. As illustrated in FIG. 14A, the layer 29 is formed at a position close to the perimeter of the substrate 70, and then the semiconductor layer 30 is formed over the entire surface of the substrate 70 so as to cover the layer 29. Thus, as illustrated in FIG. 14B, crystal growth proceeds with the layer 29 as a seed crystal, so that the single crystal or polycrystalline semiconductor layer 30 having uniform crystal orientation over the entire surface of the substrate 70 can be formed. More specifically, in the case where the crystal orientation of the layer 29 is <001>, the semiconductor layer 30 including a crystal whose crystal orientation <111> is perpendicular to the top surface of the substrate 70 can be formed. In FIG. 14B, a scribe line 85 is denoted by a dashed line. The layer 29 is preferably provided at a position overlapping with the scribe line 85.

As the substrate 70, a silicon wafer can be typically used. Alternatively, it is possible to use an insulating substrate such as a glass substrate, a quartz substrate, a sapphire substrate, or a stabilized zirconia substrate (yttria-stabilized zirconia substrate), or a semiconductor substrate such as a germanium substrate, a silicon carbide substrate, a silicon germanium substrate, a gallium arsenide substrate, an indium phosphide substrate, a zinc oxide substrate, or a gallium oxide substrate. As the substrate 70, a substrate with a diameter of 3 inches, 5 inches, 8 inches, or 12 inches can be used, for example. In particular, even in the case where a large substrate such as a 12-inch substrate is used, the semiconductor layer 30 with favorable crystallinity can be obtained and the productivity can be improved.

Subsequently, a transistor including the semiconductor layer 30, a wiring, an electrode, and the like are formed, whereby a plurality of the semiconductor chips 81 can be formed. Next, as illustrated in FIG. 14D, the substrate 70 over which the semiconductor chips 81 are formed is divided along the scribe line 85, whereby the plurality of semiconductor chips 81 separated from each other can be obtained. At this time, in the case where the layer 29 is placed at a position overlapping with the scribe line 85, the layer 29 does not remain in the semiconductor chips 81.

The layer 29 may be provided outside the scribe line 85. The number of layers 29 is not limited to one, and two or more layers 29 can be provided. For example, a plurality of layers 29 can be provided at regular intervals, and the plurality of layers 29 can be provided to overlap with the scribe line 85.

FIG. 14C is a schematic cross-sectional view in the stage of forming the semiconductor layer 30 illustrated in FIG. 14B. The layer 29 is provided at a position overlapping with the scribe line 85, and the semiconductor layer 30 is formed to cover the layer 29. The semiconductor layer 30 is formed along a side surface and a bottom surface of an opening portion 91 provided in the insulating layer 20. The semiconductor layer 30 is provided to also cover a structure body 83 formed over the insulating layer 20. Even in the case where the semiconductor layer 30 is provided to cover an uneven shape over the substrate 70 like this, as described above, the semiconductor layer 30 can be a single crystal or polycrystalline film having uniform crystal orientation.

Examples of the structure body 83 include a wiring, an electrode, and a projecting portion of the insulating layer 20. The structure body 83 may be a component of a transistor having a structure different from that of a transistor provided in the opening portion 91.

This embodiment can be combined with any of the other embodiments or Example as appropriate. In this specification, in the case where a plurality of structure examples are shown in one embodiment, the structure examples can be combined as appropriate.

### Embodiment 2

In this embodiment, semiconductor devices having any of the structures described in Embodiment 1 will be described.

### Structure Example 1 of Semiconductor Device

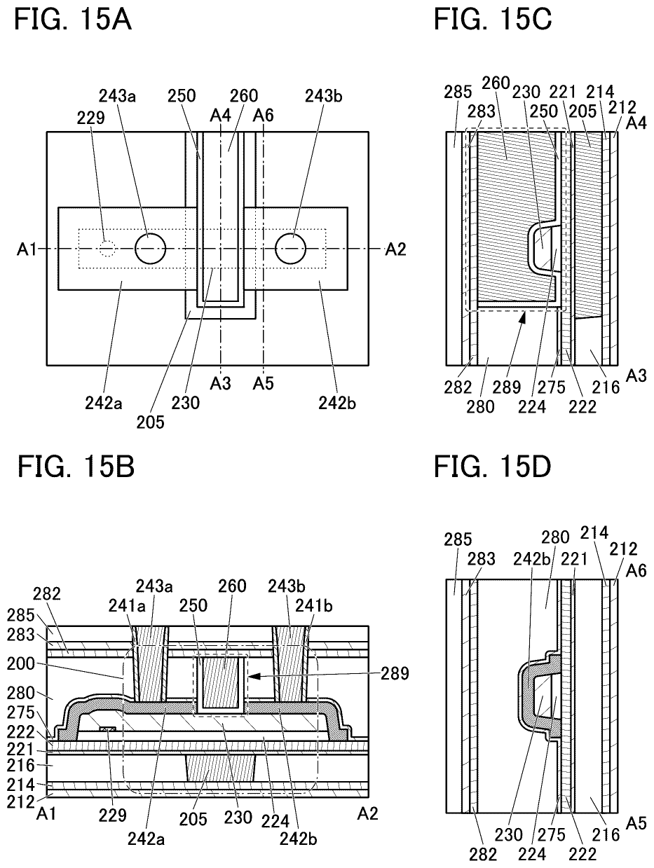

Structure examples of semiconductor devices of one embodiment of the present invention will be described with reference to FIG. 15A to FIG. 26D.

FIG. 15A is a plan view of a semiconductor device including a transistor 200. FIG. 15B is a cross-sectional view of a portion indicated by a dashed-dotted line A1-A2 in FIG. 15A, and is also a cross-sectional view of the transistor 200 in the channel length direction. FIG. 15C is a cross-sectional view of a portion indicated by a dashed-dotted line A3-A4 in FIG. 15A, and is also a cross-sectional view of the transistor 200 in the channel width direction. FIG. 15D is a cross-sectional view of a portion indicated by a dashed-dotted line A5-A6 in FIG. 15A. Note that for simplification, some components are not illustrated in the plan view in FIG. 15A. Some components may be omitted also in plan views mentioned below.

The transistor 200 includes a conductive layer 205, an insulating layer 221 over the conductive layer 205, an insulating layer 222 over the insulating layer 221, an insulating layer 224 over the insulating layer 222, a layer 229 over the insulating layer 224, a semiconductor layer 230 covering the layer 229, a conductive layer 242a and a conductive layer 242b over the semiconductor layer 230, an insulating layer 250 over the semiconductor layer 230, and a conductive layer 260 over the insulating layer 250.

The insulating layer 224, the semiconductor layer 230, the layer 229, the insulating layer 250, and the conductive layer 260 respectively correspond to the insulating layer 20, the semiconductor layer 30, the layer 29, the insulating layer 50, and the conductive layer 60 described in Embodiment 1. Thus, the structures (e.g., material and thickness), formation methods, and the like of the insulating layer 20, the semiconductor layer 30, the layer 29, the insulating layer 50, and the conductive layer 60 described in Embodiment 1 can be referred to for those of the insulating layer 224, the semiconductor layer 230, the layer 229, the insulating layer 250, and the conductive layer 260. Furthermore, the conductive layer 205 corresponds to the conductive layer 15 described in Embodiment 1. The conductive layer 242a and the conductive layer 242b respectively correspond to the conductive layer 40a and the conductive layer 40b described in Embodiment 1.

In the transistor 200, the conductive layer 260 functions as a first gate electrode (also can be referred to as an upper gate electrode or a top gate electrode), and the insulating layer 250 functions as a first gate insulating layer. The conductive layer 205 functions as a second gate electrode (also can be referred to as a lower gate electrode or a bottom gate electrode), and the insulating layers 224, 222, and 221 each function as a second gate insulating layer. The conductive layer 242a functions as one of a source electrode and a drain electrode, and the conductive layer 242b functions as the other of the source electrode and the drain electrode.

An insulating layer 275 is provided over the conductive layer 242a and the conductive layer 242b, and an insulating layer 280 is provided over the insulating layer 275. An opening portion 289 reaching the insulating layer 222 and the semiconductor layer 230 is formed in the insulating layer 280 and the insulating layer 275, and the opening portion 289 overlaps with a region between the conductive layer 242a and the conductive layer 242b. In a plan view, the side surface of the insulating layer 280 in the opening portion 289 is aligned or substantially aligned with the side surfaces of the conductive layers 242a and 242b. Note that the insulating layer 280 corresponds to the insulating layer 80 described in Embodiment 1.

The insulating layer 250 and the conductive layer 260 are provided in the opening portion 289. An insulating layer 282 is provided in contact with the top surface of the insulating layer 280, the upper end portion of the insulating layer 250, and the top surface of the conductive layer 260. The insulating layer 283 is provided over the insulating layer 282. An insulating layer 216 is provided below the insulating layer 221, an insulating layer 214 is provided below the insulating layer 216 and the conductive layer 205, and an insulating layer 212 is provided below the insulating layer 214. The insulating layer 212 is provided over a substrate (not illustrated). The substrate corresponds to the substrate 10 described in Embodiment 1. The insulating layers 212, 214, 280, 282, 283, and 285 function as interlayer films.

An opening reaching the conductive layer 242a is formed in the insulating layers 285, 283, 282, 280, and 275, and a conductive layer 243a and an insulating layer 241a are provided in the opening. The insulating layer 241a is provided in contact with the sidewall of the opening, and the conductive layer 243a is located inward from the insulating layer 241a. An opening reaching the conductive layer 242b is formed in the insulating layers 285, 283, 282, 280, and 275, and a conductive layer 243b and an insulating layer 241b are provided in the opening. The insulating layer 241b is provided in contact with the sidewall of the opening, and the conductive layer 243b is located inward from the insulating layer 241b. The conductive layers 243a and 243b function as vias that connect a wiring or the like provided over the transistor 200 to the source or the drain of the transistor 200.

In the semiconductor layer 230, a channel formation region and source and drain regions of the transistor 200 are formed. The channel formation region is sandwiched between the source and drain regions. That is, the semiconductor layer 230 includes the channel formation region, the source region, and the drain region. At least part of the channel formation region overlaps with the conductive layer 260. The source region overlaps with the conductive layer 242a, and the drain region overlaps with the conductive layer 242b. Note that the source region and the drain region can be interchanged with each other. The source region and the drain region are n-type regions (low-resistance regions) having a higher carrier concentration than the channel formation region. The semiconductor layer 230 may have a single-layer structure or a stacked-layer structure of two or more layers.

The semiconductor layer 230 is physically separated between the transistors 200 adjacent in the channel length direction. With this structure, the row hammer and passing gate effects can be prevented in the case where the transistors 200 are used in memory cells. Note that the row hammer effect refers to a phenomenon in which accumulated charges leak to an adjacent word line and cause a malfunction in a structure where word lines (the conductive layer 260) of two transistors are adjacent to each other and channel formation regions of the two transistors are connected, and the passing gate effect refers to a phenomenon in which electric charges are transferred to a gate or a gate insulating layer in a floating state to form an unintended current path or cause a change in characteristics such as a threshold.

In the semiconductor device illustrated in FIGS. 15A to 15D, the opening in which the conductive layer 243a is provided is provided at a position not overlapping with the layer 229. The conductive layer 243a is provided to be positioned between the layer 229 and the conductive layer 260 in the plan view. With such a structure, the opening can have a favorable shape. Thus, a contact defect can be inhibited and a highly reliable semiconductor device can be provided.

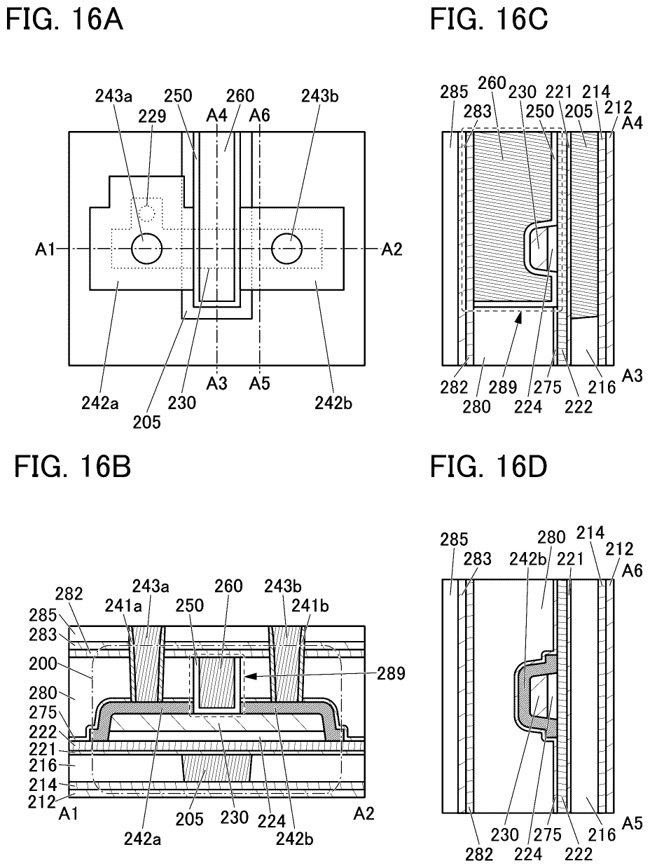

Although FIGS. 15A and 15B illustrate an example where the layer 229 is positioned on a straight line connecting the conductive layer 243a and the conductive layer 243b, the present invention is not limited to this structure. For example, as illustrated in FIGS. 16A to 16D, the layer 229 may be positioned off the straight line connecting the conductive layer 243a and the conductive layer 243b. This structure can also inhibit a contact defect, so that a highly reliable semiconductor device can be provided. FIGS. 16A to 16D are a plan view and cross-sectional views of a semiconductor device including the transistor 200 and correspond to the plan view and cross-sectional views in FIGS. 15A to 15D.

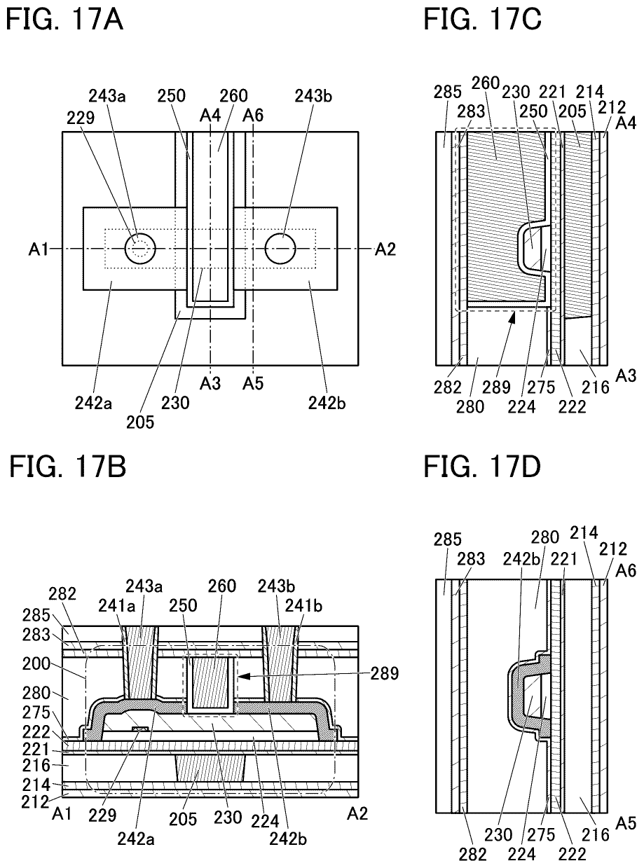

Although FIGS. 15A and 15B illustrate an example where the opening in which the conductive layer 243a is provided is provided at a position not overlapping with the layer 229, the present invention is not limited to this structure. For example, as illustrated in FIGS. 17A to 17D, the opening in which the conductive layer 243a is provided may be provided to include a portion overlapping with the layer 229. This structure enables miniaturization and higher integration of the semiconductor device. FIGS. 17A to 17D are a plan view and cross-sectional views of a semiconductor device including the transistor 200 and correspond to the plan view and cross-sectional views in FIGS. 15A to 15D.

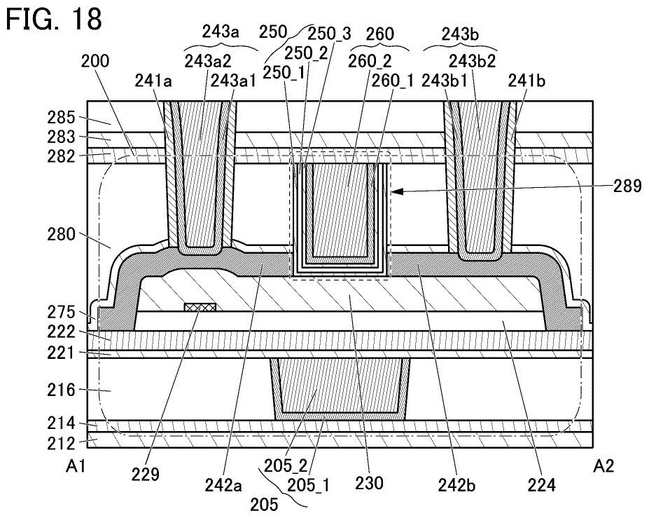

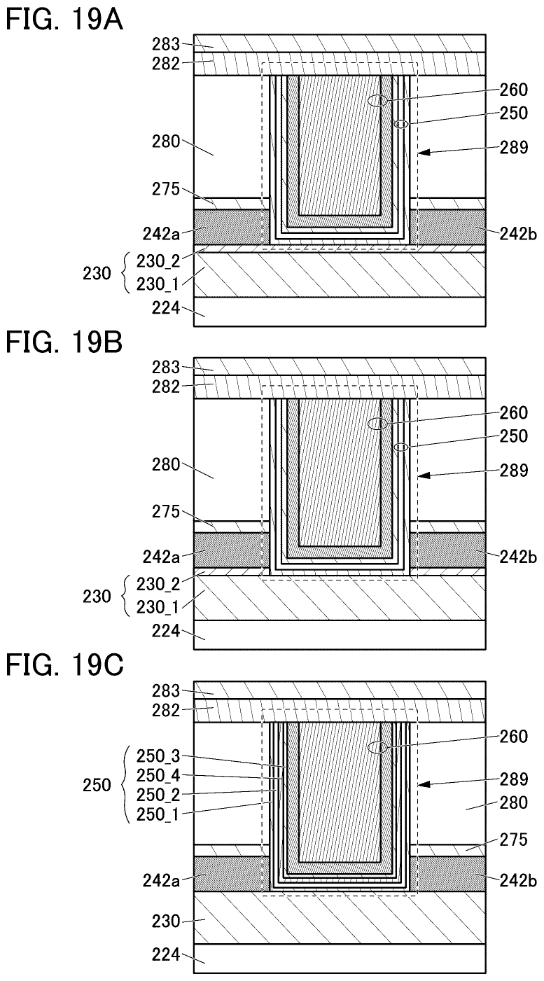

FIG. 18 and FIGS. 19A to 19C are enlarged cross-sectional views of the transistor 200 illustrated in FIGS. 17A to 17D in the channel length direction.

When an insulating layer containing excess oxygen is provided in the vicinity of the oxide semiconductor layer and heat treatment is performed, oxygen can be supplied from the insulating layer to the oxide semiconductor layer to reduce oxygen vacancies. However, supply of an excessive amount of oxygen to the source region or the drain region might cause a decrease in the on-state current or field-effect mobility of the transistor 200. Furthermore, a variation in the amount of oxygen supplied to the source region or the drain region in the substrate plane leads to a variation in the characteristics of the semiconductor device including the transistor. An excessive amount of oxygen supplied from the insulating layer to the oxide semiconductor layer adversely affects the electrical characteristics and reliability of the transistor in some cases. Moreover, oxygen diffuses into a conductive layer such as a gate electrode, a source electrode, or a drain electrode to oxidize the conductive layer, which might impair the conductivity.

It is preferable that at least one of an insulating layer having a barrier property against hydrogen and an insulating layer having a function of capturing or fixing hydrogen be formed in the vicinity of the semiconductor layer 230 to reduce the hydrogen concentration in the channel formation region and its vicinity in the semiconductor layer 230.

At least one of the insulating layers 212, 214, 221, 222, 275, 282, and 283 preferably functions as a barrier insulating layer against hydrogen. At least one of the insulating layers 212, 214, 221, 222, 275, 282, and 283 preferably functions as a barrier insulating layer against impurities. At least one of the insulating layers 212, 214, 221, 222, 275, 282, and 283 preferably functions as a barrier insulating layer against oxygen. Note that not all of the insulating layers 212, 214, 221, 222, 275, 282, and 283 need to be provided. When the barrier properties against hydrogen, impurities, oxygen, and the like are sufficient, any of the insulating layers 212, 214, 221, 222, 275, 282, and 283 can be formed selectively as appropriate. For example, the insulating layer 216 and the conductive layer 205 can be formed in contact with the top surface of the insulating layer 212, without providing the insulating layer 214.

The insulating layers 212, 221, 275, and 283 each preferably have a function of inhibiting diffusion of hydrogen. For example, silicon nitride, which has a higher hydrogen barrier property, is used for the insulating layers 212, 221, 275, and 283.

The insulating layers 214, 222, and 282 each preferably have a function of capturing or fixing hydrogen. For example, aluminum oxide is used for the insulating layers 214 and 282. For example, for the insulating layer 222 functioning as the second gate insulating layer, hafnium oxide, which is a high relative-permittivity (high-k) material, is preferably used.

When the insulating layer 212 having a function of inhibiting diffusion of hydrogen is provided below the transistor 200 as illustrated in FIG. 18, diffusion of hydrogen from a layer below the transistor 200 can be inhibited. When the insulating layer 214 having a function of capturing or fixing hydrogen is provided, hydrogen contained in the insulating layer 216 or the like can be captured or fixed by the insulating layer 214. This can reduce the hydrogen concentration in the semiconductor layer 230 and its vicinity.

When the insulating layer 221 having a function of inhibiting diffusion of hydrogen is provided below the semiconductor layer 230, diffusion of hydrogen from below the semiconductor layer 230 can be inhibited. When the insulating layer 222 having a function of capturing or fixing hydrogen is provided, hydrogen contained in the insulating layer 224 or the like can be captured or fixed by the insulating layer 222. This can reduce the hydrogen concentration in the semiconductor layer 230 and its vicinity.

Providing the insulating layer 275 having a function of inhibiting diffusion of hydrogen to cover the semiconductor layer 230, the conductive layer 242a, the conductive layer 242b, and the like can inhibit diffusion of hydrogen from the insulating layer 280 into the semiconductor layer 230, the conductive layer 242a, the conductive layer 242b, and the like.

When the insulating layer 283 having a function of inhibiting diffusion of hydrogen is provided over the transistor 200, diffusion of hydrogen from above the transistor 200 can be inhibited. When the insulating layer 282 having a function of capturing or fixing hydrogen is provided, hydrogen contained in the insulating layer 280 or the like can be captured or fixed by the insulating layer 282. This can reduce the hydrogen concentration in the semiconductor layer 230 and its vicinity.

When the top and bottom of the transistor 200 are surrounded by barrier insulating layers against hydrogen in this manner, diffusion of hydrogen into the oxide semiconductor can be reduced and the hydrogen concentration in the channel formation region can be reduced. Thus, the electrical characteristics and reliability of the transistor 200 can be improved.

The insulating layer 280 preferably contains excess oxygen. Supply of the oxygen to the semiconductor layer 230 through the insulating layer 250 by heat treatment can reduce oxygen vacancies in the channel formation region.

The insulating layer 282 is preferably formed in an atmosphere containing an oxygen gas by a sputtering method. Thus, oxygen can be added to the insulating layer 280. The insulating layer 282 may have a single-layer structure or a stacked-layer structure of two or more layers.

As described above, heat treatment is performed on the insulating layer 280 containing excess oxygen, whereby an appropriate amount of oxygen can be supplied to the semiconductor layer 230 through the insulating layer 250. Since the insulating layers 282 and 283 each having a barrier property against oxygen are placed over the insulating layer 280 in the heat treatment, oxygen contained in the insulating layer 280 can be prevented from excessively diffusing from the insulating layer 280. Since the insulating layer 275 having a barrier property against oxygen is formed between the insulating layer 280 and each of the semiconductor layer 230 and the conductive layers 242a and 242b, oxygen contained in the insulating layer 280 can be prevented from excessively diffusing from the insulating layer 280. The heat treatment is performed in a state where the opening is formed in part of the insulating layers 280, 282, and 283, whereby part of oxygen contained in the insulating layer 280 can diffuse outwardly and the amount of oxygen supplied from the insulating layer 280 to the semiconductor layer 230 can be adjusted.

FIG. 18 illustrates an example in which the semiconductor layer 230 has a single-layer structure. The semiconductor layer 230 can have a stacked-layer structure of two or more layers. As illustrated in FIG. 19A, the semiconductor layer 230 can have a two-layer structure of a semiconductor layer 230_1 and a semiconductor layer 230_2 over the semiconductor layer 230_1.

The semiconductor layer 230_1 and the semiconductor layer 230_2 respectively correspond to the first semiconductor layer and the second semiconductor layer described in Embodiment 1. Thus, the structures (e.g., materials and thicknesses), formation methods, and the like of the first semiconductor layer and the second semiconductor layer described in Embodiment 1 can be referred to for those of the semiconductor layer 230_1 and the semiconductor layer 230_2.

In the example illustrated in FIG. 19A, the insulating layer 250 is in contact with the top surface of the semiconductor layer 230_2; however, the present invention is not limited thereto. For example, as illustrated in FIG. 19B, the semiconductor layer 230_2 in a region overlapping with the opening portion 289 can be removed so that the insulating layer 250 can be in contact with the side surface of the semiconductor layer 230_2 and the top surface of the semiconductor layer 230_1. With such a structure, the distance between the conductive layer 260 and the semiconductor layer 230_1 can be shortened. Accordingly, an electric field from the gate electrode can be suitably applied to the semiconductor layer 230_1.

Preferably, the insulating layer 250 enables oxygen diffusion from the insulating layer 280 into the semiconductor layer 230 and inhibition of oxidation of the conductive layers 242a, 242b, and 260.

The insulating layer 250 is formed in contact with the top surface of the insulating layer 222, the side surface of the insulating layer 224, the top and side surfaces of the semiconductor layer 230, the side surface of the conductive layer 242a, the side surface of the conductive layer 242b, the side surface of the insulating layer 275, and the side surface of the insulating layer 280 in the opening portion 289.

In the example illustrated in FIG. 17B, the insulating layer 250 has a single-layer structure. Note that the insulating layer 250 can have a stacked-layer structure of two or more layers. In that case, the insulating layer 250 is preferably formed of two or more kinds of films. When the insulating layer 250 is formed of two or more kinds of films, the insulating layer 250 can have a plurality of functions. Examples of the functions of the insulating layer 250 include a function of extracting excess oxygen from the semiconductor layer 230, a function of extracting hydrogen from the semiconductor layer 230, and a function of inhibiting diffusion of hydrogen into the semiconductor layer 230.

For example, as illustrated in FIG. 18, the insulating layer 250 preferably has a stacked-layer structure of the insulating layer 250_1 in contact with the semiconductor layer 230, the insulating layer 250_2 over the insulating layer 250_1, and the insulating layer 250_3 over the insulating layer 250_2.

Any of the above-described materials that can be used for the insulating layer 50 can be used for the insulating layer 250_1. For example, the insulating layer 250_1 including a region in contact with the side surface of the conductive layer 242a and a region in contact with the side surface of the conductive layer 242b has a function of capturing or fixing oxygen, so that oxidation of the side surfaces of the conductive layers 242a and 242b can be inhibited and accordingly formation of oxide films on the side surfaces can be inhibited. This can inhibit a reduction in on-state current or field-effect mobility of the transistor 200. This structure can also inhibit oxygen in the insulating layer 250_2 from being absorbed into the conductive layers 242a and 242b. Thus, an appropriate amount of oxygen can be supplied from the insulating layer 250_2 to the semiconductor layer 230, so that oxygen vacancies in the channel formation region in the semiconductor layer 230 can be reduced.

When the insulating layer 250_1 is provided between the insulating layer 280 and the insulating layer 250_2 and between the insulating layer 250_2 and the semiconductor layer 230, oxygen can be inhibited from being excessively supplied from the insulating layer 280 to the semiconductor layer 230, and an appropriate amount of oxygen can be supplied to the semiconductor layer 230. Thus, the amount of oxygen in the channel formation region and its vicinity in the semiconductor layer 230 can be controlled to be an appropriate amount; hence, the transistor 200 can be prevented from having excessively normally-off characteristics and can have high reliability. In addition, excessive oxidation of the source and drain regions can be inhibited, and a reduction in on-state current or field-effect mobility of the transistor 200 can be inhibited.

With the above structure, the i-type or substantially i-type channel formation region and the n-type source and drain regions can be formed; thus, a semiconductor device having excellent electrical characteristics can be provided. The semiconductor device with the above structure can have excellent electrical characteristics even when being scaled down or highly integrated. Furthermore, scaling down of the transistor 200 can improve the high-frequency characteristics. Specifically, the cutoff frequency can be improved.

The insulating layer 250_1 is preferably formed using a high-k material. An example of the high-k material is an oxide containing one or both of aluminum and hafnium. With the use of the high-k material for the insulating layer 250_1, a gate potential applied during the operation of the transistor can be reduced while the physical thickness of a gate insulator is maintained. Furthermore, the equivalent oxide thickness (EOT) of the insulator functioning as the gate insulator can be reduced.

As described above, for the insulating layer 250_1, it is preferable to use an oxide that contains aluminum and/or hafnium and it is further preferable to use an oxide that contains aluminum and/or hafnium and has an amorphous structure. Since aluminum oxide can be formed as an amorphous film relatively easily by an ALD method, the use of aluminum oxide having an amorphous structure is further preferred. Aluminum oxide is suitable for the insulating layer 250_1 because of having a function of capturing or fixing oxygen and hydrogen. Alternatively, hafnium oxide is suitable for the insulating layer 250_1 because of having a high function of capturing or fixing oxygen and hydrogen.

The insulating layer 250_2 is preferably formed using a material with a low relative permittivity, for example. The insulating layer 250_2 preferably includes a silicon oxide film or a silicon oxynitride film, for example.

Silicon oxide or silicon nitride is an insulating material having a high withstand voltage. Thus, a leakage current of the transistor can be reduced. A silicon oxide film or a silicon oxynitride film has a high hydrogen-transmitting property. Hence, the insulating layer 250 may have a three-layer structure of the insulating layer 250_2, the insulating layer 250_1 over the insulating layer 250_2, and the insulating layer 250_3 over the insulating layer 250_1. With such a structure, hydrogen in the semiconductor layer 230 can diffuse into the insulating layer 250_1 through the insulating layer 250_2, and the hydrogen can be captured or fixed. Accordingly, the hydrogen concentration in the semiconductor layer 230 can be reduced.

The insulating layer 250_3 preferably has a barrier property against hydrogen. Such a structure can inhibit diffusion of hydrogen into the semiconductor layer 230. The insulating layer 250_3 preferably also has a barrier property against oxygen. The insulating layer 250_3 is provided between the channel formation region in the semiconductor layer 230 and the conductive layer 260. Such a structure can inhibit oxygen contained in the channel formation region in the semiconductor layer 230 from diffusing into the conductive layer 260 and thus can inhibit formation of oxygen vacancies in the channel formation region in the semiconductor layer 230. Oxygen contained in the semiconductor layer 230 can be inhibited from diffusing into the conductive layer 260 and oxidizing the conductive layer 260. The insulating layer 250_3 preferably has a lower oxygen-transmitting property than at least the insulating layer 250_2. The insulating layer 250_3 preferably has a function of inhibiting diffusion of hydrogen. This can prevent diffusion of impurities such as hydrogen contained in the conductive layer 260 into the semiconductor layer 230. Silicon nitride is preferably used for the insulating layer 250_3, for example.

The insulating layer 250 can have a three-layer structure in which a hafnium oxide film, a silicon oxide film, and a silicon nitride film are stacked in this order from the semiconductor layer 230 side, for example. The hafnium oxide film, the silicon oxide film, and the silicon nitride film have thicknesses of 2 nm, 2 nm, and 1 nm, respectively. With such a structure, an excess amount of oxygen in the semiconductor layer 230 can be released to the insulating layer 250, so that the amount of excess oxygen in the semiconductor layer 230 can be reduced. Furthermore, hydrogen in the semiconductor layer 230 can be captured or fixed. Accordingly, the electrical characteristics and reliability of the transistor 200 can be improved. The insulating layer 250 can also have a three-layer structure in which a silicon oxide film, a hafnium oxide film, and a silicon nitride film are stacked in this order from the semiconductor layer 230 side, for example.

As illustrated in FIG. 19C, an insulating layer 250_4 may be provided over the insulating layer 250_2. The insulating layer 250_4 can be formed using any of the insulating materials that can be used for the insulating layer 250_1. When the insulating layer 250_4 having a function of capturing or fixing hydrogen is provided between the insulating layer 250_3 and the insulating layer 250_2, hydrogen contained in the insulating layer 250_2 and the like can be captured or fixed.

Specifically, the insulating layer 250 preferably has a four-layer structure in which an aluminum oxide film, a silicon oxide film, a hafnium oxide film, and a silicon nitride film are stacked in this order from the semiconductor layer 230 side. With such a structure, hydrogen in the semiconductor layer 230 can diffuse into the insulating layer 250_1 or the insulating layer 250_4, and the hydrogen can be captured or fixed. Accordingly, the hydrogen concentration in the semiconductor layer 230 can be reduced.

The insulating layer 250 is preferably thin. For example, when the thickness of the insulating layer 250 is greater than or equal to 1 nm and less than or equal to 20 nm, preferably greater than or equal to 3 nm and less than or equal to 10 nm, the subthreshold swing value (also referred to as S value) can be reduced. Note that the S value means the amount of change in gate voltage in a subthreshold region when the drain voltage is constant and the drain current is changed by one order of magnitude.

The thickness of each layer included in the insulating layer 250 is preferably greater than or equal to 0.1 nm and less than or equal to 20 nm, preferably greater than or equal to 0.1 nm and less than or equal to 10 nm, further preferably greater than or equal to 0.1 nm and less than or equal to 5.0 nm, further preferably greater than or equal to 0.5 nm and less than or equal to 5.0 nm, further preferably greater than or equal to 1.0 nm and less than 5.0 nm, still further preferably greater than or equal to 1.0 nm and less than or equal to 3.0 nm. Note that each layer included in the insulating layer 250 at least partly includes a region with the above-described thickness.

The insulating layer 250_3 in the insulating layer 250 having the four-layer structure is not necessarily provided. For example, an insulating layer having a function of capturing or fixing oxygen can be used as the insulating layer 250_1, an insulating layer containing a material with a low relative permittivity can be used as the insulating layer 250_2, and an insulating layer having a function of capturing or fixing hydrogen can be used as the insulating layer 250_4. Specifically, the insulating layer 250 can have a three-layer structure in which an aluminum oxide film, a silicon oxide film, and a hafnium oxide film are stacked in this order from the semiconductor layer 230 side.

In order that the insulating layers 250_1 to 250_4 have small thicknesses as described above, an ALD method is preferably employed. In order that the insulating layers 250_1 to 250_4 with good coverage are formed in the opening portion 289, an ALD method is preferably employed.

Note that in formation of the insulating layer 250 having a stacked-layer structure of a plurality of insulating films, an ALD process is preferably performed twice or more. For example, two or more kinds of the insulating films in the insulating layer 250 are preferably formed through an ALD process. When at least two kinds of insulating films are formed through an ALD process, the coverage with the insulating layer 250 and the thickness uniformity of the insulating layer 250 can be improved. When two or more kinds of insulating films are successively formed through an ALD process, for example, the productivity can be increased.

Although the insulating layer 250 has the three-layer structure or the four-layer structure in the above description, the present invention is not limited thereto. The insulating layer 250 can have a structure including at least one of the insulating layers 250_1 to 250_4. When the insulating layer 250 is formed of one, two, or three of the insulating layers 250_1 to 250_4, the fabrication process of the semiconductor device can be simplified and the productivity can be improved.

The conductive layer 205 is provided to overlap with the semiconductor layer 230 and the conductive layer 260. For the conductive layer 205, any of conductive materials described later in [Conductive layer] can be used. Here, the conductive layer 205 is provided to fill an opening formed in the insulating layer 216. The conductive layer 205 is preferably provided to extend in the channel width direction as illustrated in FIGS. 17A and 17C. With such a structure, the conductive layer 205 functions as a wiring when a plurality of transistors are provided.

As illustrated in FIG. 18, the conductive layer 205 preferably includes a conductive layer 205_1 and a conductive layer 205_2. The conductive layer 205_1 is provided in contact with the bottom surface and the sidewall of the opening. The conductive layer 205_2 is provided to fill a depression of the conductive layer 205_1 formed along the opening. Here, the top surface of the conductive layer 205 is level or substantially level with the top surface of the insulating layer 216.

The conductive layer 205_1 preferably contains a conductive material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom. Alternatively, the conductive layer 205_1 preferably contains a conductive material having a function of inhibiting diffusion of oxygen (e.g., at least one of an oxygen atom and an oxygen molecule).

When the conductive layer 205_1 is formed using a conductive material having a function of inhibiting diffusion of hydrogen, impurities such as hydrogen contained in the conductive layer 205_2 can be prevented from diffusing into the semiconductor layer 230 through the insulating layer 216 and the like. When a conductive material having a function of inhibiting diffusion of oxygen is used for the conductive layer 205_1, a reduction in conductivity of the conductive layer 205_2 due to oxidation of the conductive layer 205_2 can be inhibited. Examples of the conductive material having a function of inhibiting diffusion of oxygen include titanium, titanium nitride, tantalum, tantalum nitride, ruthenium, and ruthenium oxide. The conductive layer 205_1 can have a single-layer structure or a stacked-layer structure of the above conductive material. For example, the conductive layer 205_1 preferably contains titanium nitride.

The conductive layer 205_2 is preferably formed using a conductor having high conductivity. For example, a conductive material containing tungsten, copper, or aluminum as its main component is preferably used for the conductive layer 205_2. For example, the conductive layer 205_2 preferably contains tungsten.

The conductive layer 205 can function as the second gate electrode. In that case, by changing a potential applied to the conductive layer 205 not in conjunction with but independently of a potential applied to the conductive layer 260, the threshold voltage (Vth) of the transistor 200 can be controlled. Specifically, when a negative potential is applied to the conductive layer 205, the Vth of the transistor 200 can be further increased and the off-state current can be reduced. Thus, the drain current at the time when a potential applied to the conductive layer 260 is 0 V can be lower in the case where a negative potential is applied to the conductive layer 205 than in the case where the negative potential is not applied to the conductive layer 205.

Although FIG. 18 illustrates the stacked-layer structure of the conductive layers 205_1 and 205_2, the present invention is not limited to this structure. The conductive layer 205 may have a single-layer structure or a stacked-layer structure of three or more layers. For example, the conductive layer 205_1 may have a two-layer structure of a tantalum nitride film and a titanium nitride film over the tantalum nitride film, and the conductive layer 205_2 including a tungsten film may be provided over the conductive layer 205_1. With such a structure, impurities such as hydrogen and metal impurities such as copper contained in the layer below the transistor 200 can be inhibited from diffusing into the conductive layer 205.

The insulating layers 224, 221, and 222 function as the second gate insulating layer.

The insulating layer 224 preferably includes, for example, a silicon oxide film or a silicon oxynitride film. Thus, oxygen can be supplied from the insulating layer 224 to the semiconductor layer 230, so that oxygen vacancies can be reduced. Note that the insulating layer 224 may have a stacked-layer structure of two or more layers. In that case, without limitation to a stacked-layer structure formed of the same material, a stacked-layer structure formed of different materials may be employed.

The insulating layer 224 is preferably processed into an island shape like the semiconductor layer 230. Thus, in the case where a plurality of the transistors 200 are provided, the transistors 200 include the insulating layers 224 having substantially the same sizes. Accordingly, the amounts of oxygen supplied from the insulating layers 224 to the semiconductor layers 230 are substantially the same in the transistors 200. As a result, variations in electrical characteristics of the transistors 200 in the substrate plane can be reduced.

When the insulating layer 224 is provided to have an island shape, the level of at least part of the bottom surface of the conductive layer 260 can be lower than that of the bottom surface of the semiconductor layer 230 (see FIG. 17C). Thus, the conductive layer 260 can be provided to face the top and side surfaces of the semiconductor layer 230, so that an electric field of the conductive layer 260 can act on the top and side surfaces of the semiconductor layer 230.

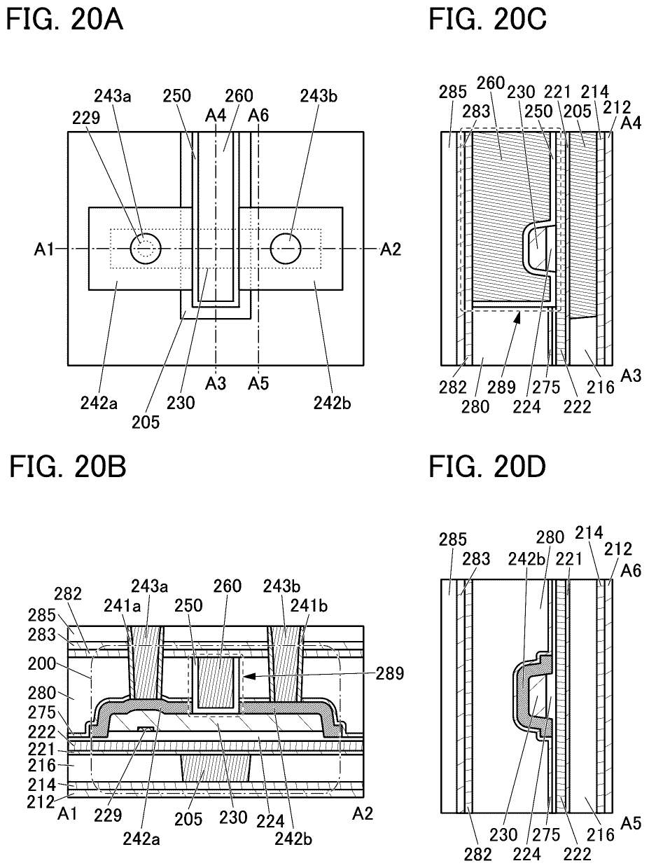

Note that the insulating layer 224 is not necessarily processed into an island shape. For example, as illustrated in FIGS. 20A to 20D, the insulating layer 224 may have a shape in which an opening is partly formed, instead of having an island shape. Here, FIGS. 20A to 20D correspond to FIGS. 17A to 17D, respectively, and are the same as FIGS. 17A to 17D except for the shape of the insulating layer 224.

The insulating layer 224 illustrated in FIGS. 20A to 20D has a smaller thickness in a region not overlapping with the semiconductor layer 230 than in a region overlapping with the semiconductor layer 230. An opening is formed in a region not overlapping with the semiconductor layer 230 but overlapping with the insulating layer 250. In the case where a plurality of transistors are provided over one substrate, forming the insulating layer 224 in this manner results in formation of the semiconductor layers 230 of the transistors over the same insulating layer 224. Thus, a variation in the amount of oxygen supplied from the insulating layer 224 to the semiconductor layers 230 of the transistors can be reduced. Accordingly, variations in electrical characteristics of the transistors can be reduced.

In the insulating layer 224 illustrated in FIGS. 20A to 20D, the opening is formed in the region not overlapping with the semiconductor layer 230 but overlapping with the insulating layer 250; however, a structure without the opening may be employed.

For the conductive layers 242a and 242b, any of the conductive materials described later in [Conductive layer] can be used. Specifically, a conductive material that is not easily oxidized or a conductive material having a function of inhibiting diffusion of oxygen is preferably used for the conductive layers 242a and 242b. Examples of the conductive material include a conductive material containing nitrogen and a conductive material containing oxygen. The use of such conductive materials can inhibit a reduction in the conductivity of the conductive layers 242a and 242b.

For each of the conductive layers 242a and 242b, a metal nitride is preferably used; for example, a nitride containing tantalum, a nitride containing titanium, a nitride containing molybdenum, a nitride containing tungsten, a nitride containing tantalum and aluminum, or a nitride containing titanium and aluminum is preferably used. For example, tantalum nitride can be used for the conductive layers 242a and 242b. For another example, ruthenium, ruthenium oxide, ruthenium nitride, an oxide containing strontium and ruthenium, an oxide containing lanthanum and nickel, ITO, ITSO, or an In—Zn oxide may be used. These materials are preferable because they are conductive materials that are not easily oxidized or materials that maintain their conductivity even after absorbing oxygen.

The conductive layer 242a and the conductive layer 242b may each have a stacked-layer structure. In this case, any of the above-described conductive materials is used for lower layers (layers having large contact areas with the semiconductor layer 230) of the conductive layers 242a and 242b, and a conductive material having higher conductivity is used for upper layers of the conductive layers 242a and 242b. For example, tantalum nitride can be used for the lower layers and tungsten can be used for the upper layers. For another example, ITO or ITSO can be used for the lower layers and tungsten can be used for the upper layers.

The conductive layer 260 is provided in the opening portion 289 to cover the top surface of the insulating layer 222, the side surface of the insulating layer 224, and the top and side surfaces of the semiconductor layer 230 with the insulating layer 250 therebetween. The top surface of the conductive layer 260 is level or substantially level with the upper end portion of the insulating layer 250 and the top surface of the insulating layer 280.

Note that the sidewall of the opening portion 289 may be perpendicular or substantially perpendicular to the top surface of the insulating layer 222 or may have a tapered shape. The sidewall with a tapered shape can improve the coverage with the insulating layer 250 formed in the opening portion 289, so that the number of defects such as voids can be reduced.

The conductive layer 260 is preferably provided to extend in the channel width direction as illustrated in FIGS. 17A and 17C. With such a structure, the conductive layer 260 functions as a wiring when a plurality of transistors are provided.

As illustrated in FIG. 17C, a curved surface may be provided between the top and side surfaces of the semiconductor layer 230 in the cross-sectional view of the transistor 200 in the channel width direction. That is, the end portion of the side surface and the end portion of the top surface may be curved.

As illustrated in FIG. 18, the conductive layer 260 preferably has a two-layer structure. Here, the conductive layer 260 preferably includes the conductive layer 260_1 and the conductive layer 260_2 over the conductive layer 260_1. For example, the conductive layer 260_1 is preferably positioned to cover the bottom and side surfaces of the conductive layer 260_2.

For example, it is preferable that titanium nitride be used for the conductive layer 260_1, and tungsten be used for the conductive layer 260_2. Alternatively, it is preferable that tantalum nitride be used for the conductive layer 260_1, and copper be used for the conductive layer 260_2. Such a structure can increase the conductivity of the conductive layer 260.

Alternatively, the conductive layer 260 may have a stacked-layer structure of three or more layers. For example, the conductive layer 260 may have a three-layer structure of a tantalum nitride film, a titanium nitride film over the tantalum nitride film, and a tungsten film over the titanium nitride film.

The insulating layers 216, 280, and 285 each preferably have a lower relative permittivity than the insulating layer 222. In the case where a material with a low relative permittivity is used for an interlayer film, the parasitic capacitance generated between wirings can be reduced.

For example, the insulating layers 216, 280, and 285 can each be formed using any of materials with a low relative permittivity described later in [Insulating layer]. Silicon oxide and silicon oxynitride are particularly preferable because of their thermal stability. Materials such as silicon oxide, silicon oxynitride, and porous silicon oxide are preferably used, in which case a region containing excess oxygen can be easily formed.

The top surfaces of the insulating layers 216 and 280 may be planarized.

The concentration of impurities such as water and hydrogen in the insulating layer 280 is preferably reduced. For example, the insulating layer 280 preferably includes an oxide containing silicon, such as silicon oxide or silicon oxynitride.

For the conductive layers 243a and 243b, any of the conductive materials described later in [Conductive layer] can be used. The conductive layers 243a and 243b are preferably formed using a conductive material containing tungsten, copper, or aluminum as its main component, for example. The conductive layers 243a and 243b may each have a stacked-layer structure.

For example, as illustrated in FIG. 18, the conductive layers 243a and 243b may each have a two-layer structure. The conductive layer 243a includes a conductive layer 243al formed along the opening and a conductive layer 243a2 located inward from the conductive layer 243al. The conductive layer 243b includes a conductive layer 243b1 formed along the opening and a conductive layer 243b2 located inward from the conductive layer 243b1.

The conductive layers 243a1 and 243b1 can each be formed to have a single-layer structure or a stacked-layer structure using any of the conductive materials that can be used for the conductive layer 205_1. Providing the conductive layers 243al and 243b1 can inhibit entry of impurities such as water and hydrogen into the semiconductor layer 230 through the conductive layers 243a2 and 243b2. Note that the conductive layers 243a2 and 243b2 can be formed using any of the conductive materials that can be used for the conductive layers 243a and 243b.

As illustrated in FIG. 17B, the top surfaces of the conductive layers 243a and 243b are level or substantially level with the top surface of the insulating layer 285. As illustrated in FIG. 18, the conductive layer 243a may be formed such that its lower portion is embedded in the conductive layer 242a. Similarly, the conductive layer 243b may be formed such that its lower portion is embedded in the conductive layer 242b.

A barrier insulating layer that can be used for the insulating layer 275 and the like is used as the insulating layers 241a and 241b. For example, silicon nitride is used for the insulating layers 241a and 241b. The insulating layers 241a and 241b are provided in contact with the insulating layers 285, 283, 282, and 275. Thus, impurities such as water and hydrogen contained in the insulating layer 280 or the like can be inhibited from entering the semiconductor layer 230 through the conductive layers 243a and 243b. Silicon nitride is particularly preferable because of its high barrier property against hydrogen. Furthermore, oxygen contained in the insulating layer 280 can be prevented from being absorbed by the conductive layers 243a and 243b.

The insulating layers 241a and 241b may each have a stacked-layer structure. In that case, a combination of a barrier insulating layer against oxygen and a barrier insulating layer against hydrogen is preferably used for a first insulating layer in contact with the sidewall of the opening formed in the insulating layer 280 and the like and a second insulating layer located inward from the first insulating layer.

### Modification Example 1

In FIG. 17B and the like, the insulating layer 250 is in contact with the side surface of the insulating layer 280 in the opening portion 289; however, the present invention is not limited to this structure. For example, an insulating layer may be provided between the insulating layer 250 and the insulating layer 280 in the opening portion 289.

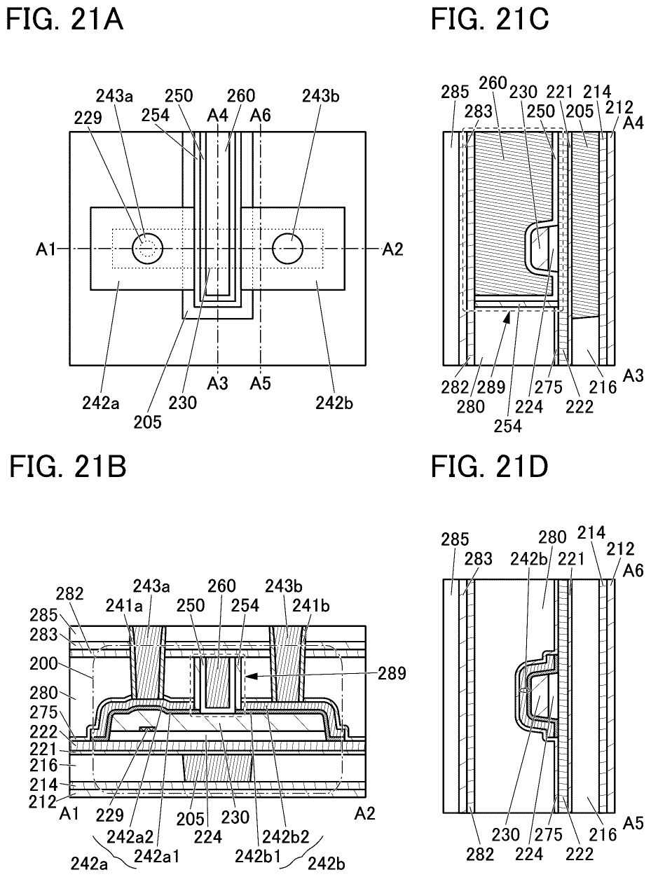

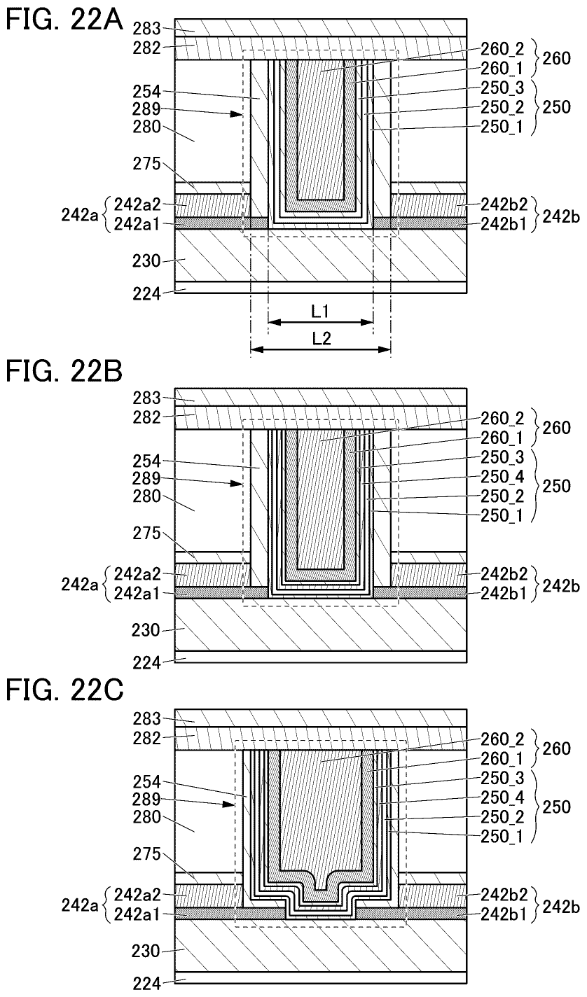

A modification example of the semiconductor device described with reference to FIGS. 17A to 17D will be described with reference to FIGS. 21A to 21D and FIGS. 22A to 22C. FIGS. 21A to 21D are a plan view and cross-sectional views of the semiconductor device including the transistor 200 and correspond to the plan view and cross-sectional views in FIGS. 17A to 17D. FIGS. 22A to 22C are enlarged cross-sectional views of the transistor 200 in the channel length direction.

The transistor 200 illustrated in FIGS. 21A to 21D is different from the transistor 200 illustrated in FIGS. 17A to 17D mainly in including an insulating layer 254. Differences from the above description are mainly described below. The above description is referred to for the same portions, and the description of the same portions is omitted in some cases.

In FIGS. 21A to 21D, the conductive layers 242a and 242b each have a two-layer structure. The conductive layer 242a has a stacked-layer structure of a conductive layer 242al and a conductive layer 242a2 over the conductive layer 242a1. The conductive layer 242b has a stacked-layer structure of a conductive layer 242b1 and a conductive layer 242b2 over the conductive layer 242b1. The conductive layers 242a1 and 242b1 correspond to the lower layers of the conductive layers 242a and 242b, and the conductive layers 242a2 and 242b2 correspond to the upper layers of the conductive layers 242a and 242b.

As illustrated in FIGS. 21B and 21C, the insulating layer 254 is provided in the opening portion 289 and is in contact with the side surface of the insulating layer 280, the side surface of the conductive layer 242a2, the side surface of the conductive layer 242b2, the top surface of the conductive layer 242a1, the top surface of the conductive layer 242b1, and the top surface of the insulating layer 222 in the opening portion 289. In other words, the insulating layer 254 is formed in a sidewall shape to be in contact with the sidewall of the opening portion 289. Here, the sidewall of the opening portion 289 corresponds to, for example, the side surface of the insulating layer 280 and the like in the opening portion 289.

The insulating layer 254 preferably has a barrier property against oxygen. When the insulating layer 254 has a barrier property against oxygen, oxidation of the side surfaces of the conductive layers 242a and 242b can be inhibited and accordingly formation of oxide films on the side surfaces can be inhibited. It is thus possible to inhibit a reduction in the on-state current or field-effect mobility of the transistor 200. As the insulating layer 254, a barrier insulating layer against oxygen can be used. For example, silicon nitride is used for the insulating layer 254.

The opening portion 289 overlaps with a region between the conductive layers 242a2 and 242b2. In the plan view, the side surface of the insulating layer 280 is aligned or substantially aligned with the side surfaces of the conductive layers 242a2 and 242b2 in the opening portion 289. Parts of the conductive layers 242a1 and 242b1 are formed to extend to the inside of the opening portion 289. In other words, part of the conductive layer 242al having a top surface on which the insulating layer 254 is formed (hereinafter, sometimes referred to as an extending portion of the conductive layer 242a1) is formed to extend beyond the conductive layer 242a2 toward the conductive layer 260. Similarly, part of the conductive layer 242b1 having a top surface on which the insulating layer 254 is formed (hereinafter, sometimes referred to as an extending portion of the conductive layer 242b1) is formed to extend beyond the conductive layer 242b2 toward the conductive layer 260.

Part of the top surface of the conductive layer 242al is in contact with the conductive layer 242a2, and part of the top surface of the conductive layer 242b1 is in contact with the conductive layer 242b2. Accordingly, the insulating layer 254 is in contact with another part of the top surface of the conductive layer 242a1, another part of the top surface of the conductive layer 242b1, the side surface of the conductive layer 242a2, and the side surface of the conductive layer 242b2 in the opening portion 289. The insulating layer 250 is in contact with the top surface of the semiconductor layer 230, the side surface of the conductive layer 242a1, the side surface of the conductive layer 242b1, and the side surface of the insulating layer 254.

By anisotropic etching, the insulating layer 254 is formed in a sidewall shape to be in contact with the sidewall of the opening portion 289. The insulating layer 254 is formed in contact with the side surfaces of the conductive layers 242a2 and 242b2, and thus has a function of protecting the conductive layers 242a2 and 242b2.

The insulating layer 254 functions as a mask at the time of dividing the conductive layer into the conductive layers 242al and 242b1. Thus, as illustrated in FIG. 22A, in the cross-sectional view of the transistor 200, the side end portion of the insulating layer 254 is aligned or substantially aligned with the side end portions of the conductive layers 242a1 and 242b1.

Note that heat treatment in an oxygen-containing atmosphere is preferably performed after the division of the conductive layer into the conductive layers 242al and 242b1 but before the formation of the insulating layer 250. At this time, since the insulating layer 254 is formed in contact with the side surfaces of the conductive layers 242a2 and 242b2, excessive oxidation of the conductive layers 242a2 and 242b2 can be prevented. Even in the case where microwave plasma treatment is performed after the division of the conductive layer into the conductive layers 242al and 242b1, formation of oxide films on the side surfaces of the conductive layers 242a and 242b can be inhibited.

The insulating layer 254, the insulating layer 250, and the conductive layer 260 are provided to reflect the shape of the opening portion 289. Thus, the insulating layer 254 is provided to cover the sidewall of the opening portion 289, the insulating layer 250 is provided to cover the bottom portion of the opening portion 289 and the insulating layer 254, and the conductive layer 260 is provided to fill the depression of the insulating layer 250.

As described above, the insulating layer 250 may have a stacked-layer structure. For example, as illustrated in FIG. 22A, the insulating layer 250 may have a three-layer structure of the insulating layers 250_1 to 250_3. For another example, as illustrated in FIG. 22B, the insulating layer 250 may have a four-layer structure of the insulating layers 250_1 to 250_4.

The thickness of the insulating layer 254 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulating layer 254 has a thickness in the above range, excessive oxidation of the conductive layers 242a2 and 242b2 can be inhibited. Note that the insulating layer 254 at least partly has a region with the above thickness. The insulating layer 254 is provided in contact with the sidewall of the opening portion 289, and thus is preferably formed by, for example, an ALD method that provides excellent coverage. When the thickness of the insulating layer 254 is excessively large, the time for forming the insulating layer 254 by an ALD method is long, which decreases the productivity. For this reason, the thickness of the insulating layer 254 is preferably in the above range. Moreover, the insulating layer 254 preferably has a thickness that does not excessively inhibit diffusion of excess oxygen from the insulating layer 280 to the insulating layer 250_2 and diffusion of excess oxygen from the insulating layer 250_2 to the semiconductor layer 230.

As illustrated in FIG. 22A, in the cross-sectional view of the transistor 200 in the channel length direction, a distance L1 between the conductive layers 242a1 and 242b1 is smaller than a distance L2 between the conductive layers 242a2 and 242b2. Here, the distance L1 refers to the shortest distance between the conductive layers 242al and 242b1, and the distance L2 refers to the shortest distance between the conductive layers 242a2 and 242b2. With such a structure, the distance between the source and the drain can be shortened, and the channel length can be accordingly shortened. This can improve the frequency characteristics of the transistor 200. In this manner, scaling down of the semiconductor device enables the semiconductor device to have a higher operating speed.

In the structure illustrated in FIG. 22A, the difference between the distance L2 and the distance L1 is twice the thickness of the insulating layer 254. In other words, the distance L2 is equal or substantially equal to the sum of the distance L1 and the double of the thickness of the insulating layer 254. Here, the thickness of the insulating layer 254 refers to the width in the A1-A2 direction of at least part of the insulating layer 254.

The insulating layer 254 may have a stacked-layer structure of two or more layers. In that case, at least one of the stacked layers can be the above-described inorganic insulating layer that is not easily oxidized. For example, the inorganic insulating layer that is not easily oxidized is used as a first insulating layer of the insulating layer 254, and an insulating material (e.g., silicon oxide) that can be used for the insulating layer 250_2 is used for a second insulating layer over the first insulating layer of the insulating layer 254. The second insulating layer of the insulating layer 254 preferably has a lower relative permittivity than the first insulating layer of the insulating layer 254. When the insulating layer 254 has a two-layer structure to have a large thickness in the above manner, the distance between the conductive layer 260 and the conductive layer 242a or 242b can be increased and thus the parasitic capacitance can be reduced.

Although an example in which the insulating layer 254 is formed in a sidewall shape by anisotropic etching is described above, the present invention is not limited thereto. As illustrated in FIG. 22C, the insulating layer 254 can have an opening inside the opening portion 289. In that case, the opening of the insulating layer 254 can be formed by removing part of an insulating film to be the insulating layer 254 by a lithography method. The opening of the insulating layer 254 preferably overlaps with a region between the conductive layers 242a1 and 242b1.

As illustrated in FIG. 22C, extending portions are formed in a lower portion of the insulating layer 254 in the cross-sectional view. The extending portions of the insulating layer 254 overlap with the extending portions of the conductive layers 242a1 and 242b1.

### Modification Example 2

Although the modification example 1 describes the structure in which the insulating layer 254 is provided in contact with the sidewall of the opening portion 289, the present invention is not limited to this structure. For example, a structure in which the insulating layer 254 is not provided in the opening portion 289 may be employed.

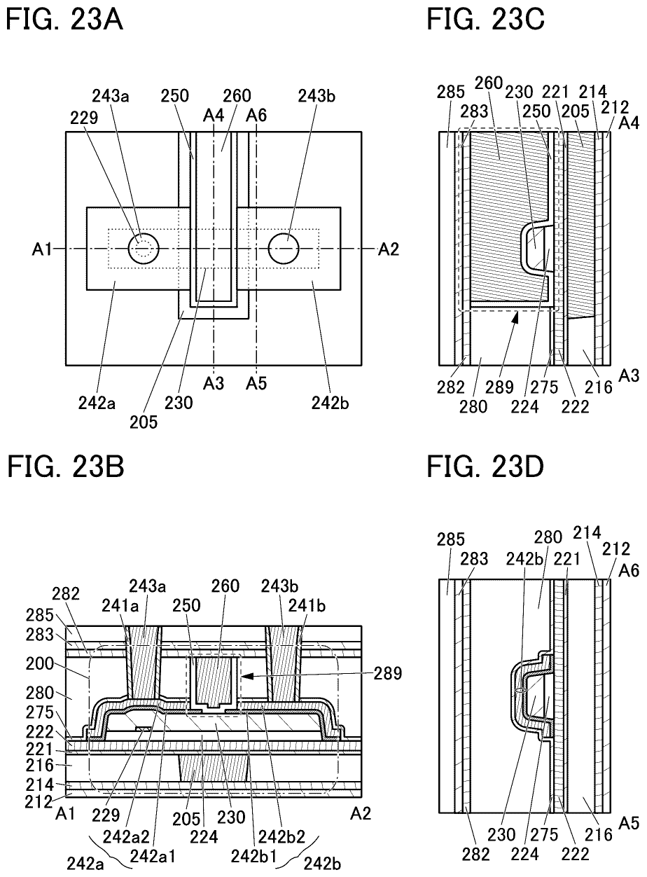

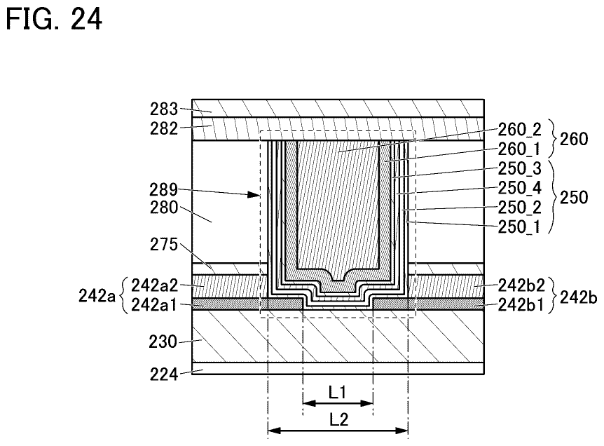

A modification example of the semiconductor device described in the modification example 1 will be described with reference to FIGS. 23A to 23D and FIG. 24. FIGS. 23A to 23D are a plan view and cross-sectional views of the semiconductor device including the transistor 200 and correspond to the plan view and cross-sectional views in FIGS. 21A to 21D. FIG. 24 is an enlarged cross-sectional view of the transistor 200 in the channel length direction and corresponds to the enlarged cross-sectional view in FIG. 22C.

The transistor 200 illustrated in FIGS. 23A to 23D is different from the transistor 200 illustrated in FIGS. 21A to 21D mainly in not including the insulating layer 254. Differences from the above description are mainly described below. The above description is referred to for the same portions, and the description of the same portions is omitted in some cases.

As illustrated in FIG. 24, in the case where the insulating layer 254 is not provided, part of the insulating layer 250 is positioned to overlap with the extending portions of the conductive layers 242a1 and 242b1. In some cases, part of the conductive layer 260 is positioned to overlap with the extending portions of the conductive layers 242al and 242b1. Here, the extending portions of the conductive layers 242a1 and 242b1 are in contact with the insulating layer 250. The side surface of the insulating layer 250 is in contact with the side surfaces of the insulating layers 280 and 275 and the side surfaces of the conductive layers 242a2 and 242b2.

The insulating layer 250 is formed to reflect the shape of the opening portion 289. Accordingly, the insulating layer 250 is formed to reflect the shapes of the conductive layers 242a1 and 242b1 that extend in the opening portion 289.

As illustrated in FIG. 24, in the cross-sectional view of the transistor 200 in the channel length direction, the distance L1 between the conductive layers 242a1 and 242b1 is smaller than the distance L2 between the conductive layers 242a2 and 242b2. With such a structure, the distance between the source and the drain can be shortened, and the channel length can be accordingly shortened. This can improve the frequency characteristics of the transistor 200. In this manner, scaling down of the semiconductor device enables the semiconductor device to have a higher operating speed.

Furthermore, with the structure illustrated in FIG. 24, the width of the upper portion of the conductive layer 260 can be larger than the distance L1. This can reduce the wiring resistance of the conductive layer 260. Consequently, the power consumption of the semiconductor device can be reduced.

### Structure Example 2 of Semiconductor Device

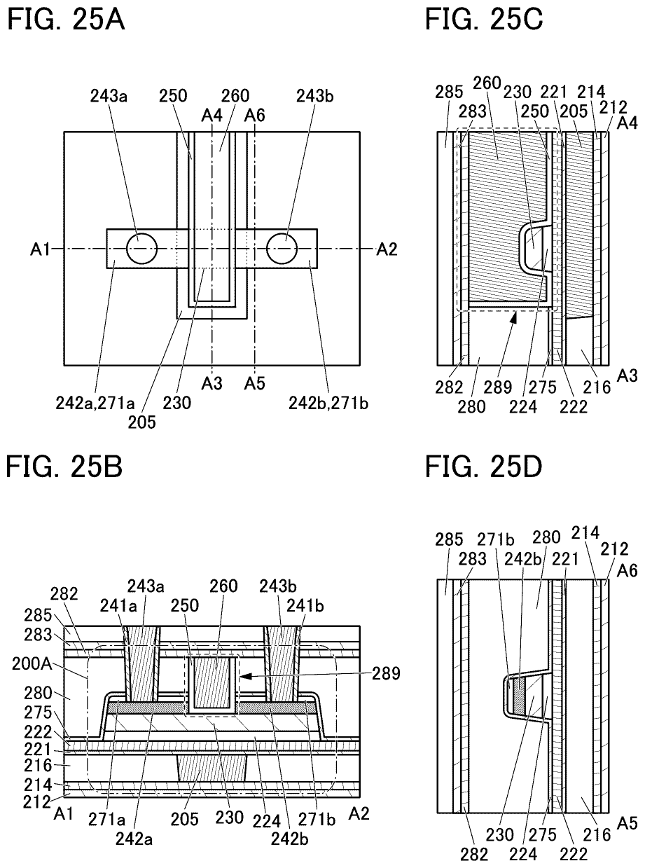

A structure example of the semiconductor device of one embodiment of the present invention will be described with reference to FIGS. 25A to 25D.

FIG. 25A is a plan view of a semiconductor device including a transistor 200A. FIG. 25B is a cross-sectional view of a portion indicated by a dashed-dotted line A1-A2 in FIG. 25A, and is also a cross-sectional view of the transistor 200A in the channel length direction. FIG. 25C is a cross-sectional view of a portion indicated by a dashed-dotted line A3-A4 in FIG. 25A, and is also a cross-sectional view of the transistor 200A in the channel width direction. FIG. 25D is a cross-sectional view of a portion indicated by a dashed-dotted line A5-A6 in FIG. 25A.

The transistor 200A is different from the transistor 200 illustrated in FIGS. 17A to 17D mainly in that a side end portion of the conductive layer 242a and a side end portion of the semiconductor layer 230 are aligned or substantially aligned with each other, a side end portion of the conductive layer 242b and a side end portion of the semiconductor layer 230 are aligned or substantially aligned with each other, an insulating layer 271a and an insulating layer 271b are included, and the layer 229 is not included. Differences from the above description are mainly described below. The above description is referred to for the same portions, and the description of the same portions is omitted in some cases.

The insulating layer 271a is provided over the conductive layer 242a, and the insulating layer 271b is provided over the conductive layer 242b.

The transistor 200A can be manufactured by the manufacturing method described with reference to FIGS. 11E to 11H, for example. Specifically, the semiconductor layer 30 having crystallinity is formed, a conductive film to be the conductive layer 242a and the conductive layer 242b is formed over the semiconductor layer 30, an insulating layer to be the insulating layer 271a and the insulating layer 271b is formed over the conductive film, the conductive film is processed using the insulating layer as a mask to form a conductive layer overlapping with the insulating layer, and the semiconductor layer 30 is further processed. Thus, an island-shaped structure body including the insulating layer, the conductive layer, and the semiconductor layer 30 can be formed. In this case, the two-layer structure of the island-shaped insulating layer and the island-shaped conductive layer corresponds to the island-shaped layer 35 described in Embodiment 1.

Furthermore, the insulating layer 271a and the insulating layer 271b can be formed by removing a portion of the island-shaped insulating layer that overlaps with the opening portion 289. The conductive layer 242a and the conductive layer 242b can be formed by removing a portion of the island-shaped conductive layer that overlaps with the opening portion 289. Accordingly, the side end portion of the conductive layer 242a and the side end portion of the semiconductor layer 230 are aligned or substantially aligned with each other, and the side end portion of the conductive layer 242b and the side end portion of the semiconductor layer 230 are aligned or substantially aligned with each other. Thus, miniaturization and higher integration of the semiconductor device can be achieved.

The above-described insulating layer functions as a mask for the above-described conductive layer, and thus each of the conductive layers 242a and 242b does not have a curved surface between the side surface and the top surface. Accordingly, the end portion at the intersection of the side surface and the top surface of each of the conductive layers 242a and 242b is angular. The cross-sectional area of each of the conductive layers 242a and 242b is larger in the case where the end portion at the intersection of the side surface and the top surface of each of the conductive layers 242a and 242b is angular than in the case where the end portion is rounded. Accordingly, the resistances of the conductive layers 242a and 242b are reduced, so that the on-state current of the transistor can be increased.

Note that at least one of the structures described above in <Structure example 1 of semiconductor device> can also be employed for the transistor 200A.

### Structure Example 3 of Semiconductor Device

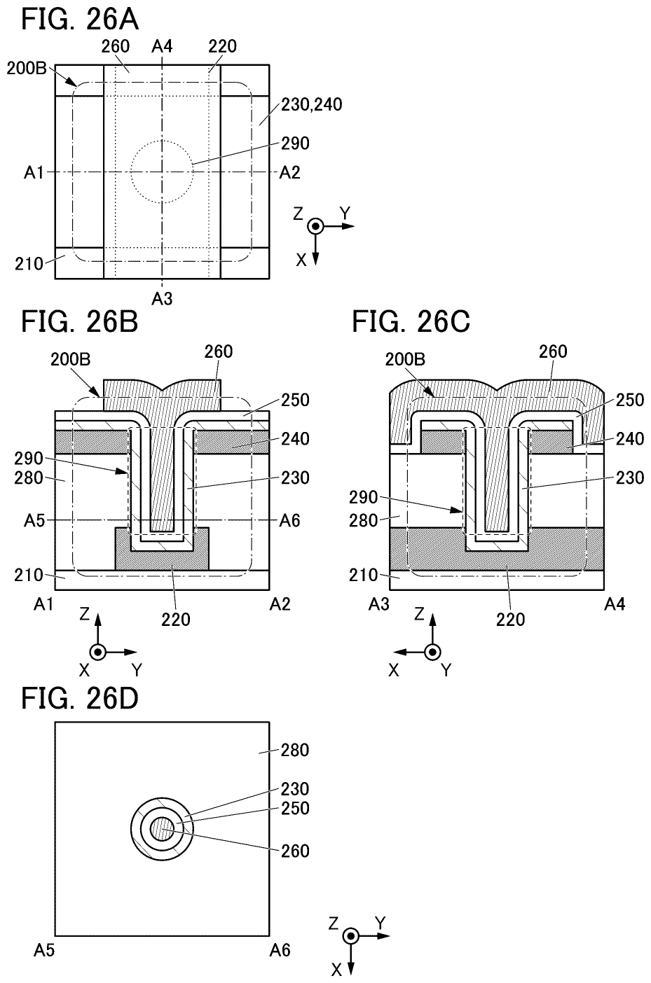

A structure example of a semiconductor device of one embodiment of the present invention will be described with reference to FIG. 26A to FIG. 26D.

FIG. 26A is a plan view of a semiconductor device including a transistor 200B. FIG. 26B is a cross-sectional view taken along the dashed-dotted line A1-A2 in FIG. 26A. FIG. 26C is a cross-sectional view taken along the dashed-dotted line A3-A4 in FIG. 26A. FIG. 26D is a cross-sectional view taken along the dashed-dotted line A5-A6 in FIG. 26B.

The transistor 200B includes a conductive layer 220, a conductive layer 240, the semiconductor layer 230, the insulating layer 250 over the semiconductor layer 230, and the conductive layer 260 over the insulating layer 250.

The conductive layer 220 is provided over an insulating layer 210, the insulating layer 280 is provided over the conductive layer 220, and the conductive layer 240 is provided over the insulating layer 280. An opening portion 290 reaching the conductive layer 220 is formed in the conductive layer 240 and the insulating layer 280, and the semiconductor layer 230 is provided along a bottom portion and a sidewall of the opening portion 290. The semiconductor layer 230 includes a portion in contact with the conductive layer 240 and a portion in contact with the conductive layer 220.

In the transistor 200B, the conductive layer 260 functions as a gate electrode, and the insulating layer 250 functions as a gate insulating layer. The conductive layer 220 functions as one of a source electrode and a drain electrode, and the conductive layer 240 function as the other of the source electrode and the drain electrode.

The semiconductor layer 230 includes a region overlapping with the conductive layer 260 with the insulating layer 250 therebetween. At least part of the region functions as a channel formation region of the transistor 200B. One of a region of the semiconductor layer 230 which is in the vicinity of the conductive layer 220 and a region of the semiconductor layer 230 which is in the vicinity of the conductive layer 240 functions as a source region, and the other functions as a drain region. That is, the channel formation region is sandwiched between the source region and the drain region.

The semiconductor layer 230 is provided in the opening portion 290. The transistor 200B has a structure in which a current flows in the vertical direction since one of the source electrode and the drain electrode (here, the conductive layer 220) is positioned on the lower side and the other of the source electrode and the drain electrode (here, the conductive layer 240) is positioned on the upper side. That is, a channel is formed along the side surface of the opening portion 290. Thus, the area occupied by the transistor 200B can be smaller than the area occupied by a planar transistor in which a channel formation region, a source region, and a drain region are provided separately on the XY plane. Accordingly, the semiconductor device can be highly integrated. In the case where the transistor 200B is used for a memory device, the memory capacity per unit area can be increased. The channel length direction of the transistor 200B includes a height (vertical) component; thus, the transistor 200B can be referred to as a vertical field-effect transistor (VFET), a vertical transistor, a vertical-channel transistor, or the like.

The transistor 200B corresponds to the transistor provided in the opening portion 91 described in Embodiment 1.

In the case where the opening portion 290 is formed to be circular in a top view as illustrated in FIG. 26D, the semiconductor layer 230, the insulating layer 250, and the conductive layer 260 are formed concentrically. This makes the distance between the conductive layer 260 and the semiconductor layer 230 substantially uniform, so that a gate electric field can be substantially uniformly applied to the semiconductor layer 230.

This embodiment describes the example in which the opening portion 290 is circular in the plan view. When the opening portion is circular, the processing accuracy in forming the opening portion can be increased; thus, the opening portion can be formed to have a minute size. Note that the present invention is not limited thereto. The opening portion 290 in the plan view can have a circular shape, a substantially circular shape such as an elliptical shape, a polygonal shape such as a triangular shape, a quadrangular shape (including a rectangular shape, a rhombic shape, and a square), a pentagonal shape, or a star polygonal shape, or any of these polygonal shapes whose corners are rounded, for example.

For the structures (e.g., materials and thicknesses) of the semiconductor layer 230, the insulating layer 250, the conductive layer 260, and the insulating layer 280, the structures of the semiconductor layer 230, the insulating layer 250, the conductive layer 260, and the insulating layer 280 described above in <Structure example 1 of semiconductor device> or the like can be referred to.

For the conductive layer 220 and the conductive layer 240, any of the conductive materials described later in [Conductive layer] can be used. Any of the above-described materials that can be used for the conductive layer 242a and the conductive layer 242b can also be used.

### <Materials for Semiconductor Device>

Materials that can be used for the semiconductor device of this embodiment will be described below. Note that the layers included in the semiconductor device of this embodiment may each have a single-layer structure or a stacked-layer structure.

### [Oxide Semiconductor Layer]

For the oxide semiconductor layer that can be used as the semiconductor layer of the transistor of one embodiment of the present invention, description in <Structure of semiconductor device> can be referred to.

The carrier concentration in the channel formation region is preferably lower than 1×10¹⁹ cm⁻³, lower than 1×10¹⁸ cm⁻³, lower than 5×10¹⁷ cm⁻³, lower than 1×10¹⁷ cm⁻³, lower than 1×10¹⁶ cm⁻³, lower than 1×10¹⁵ cm⁻³, lower than 1×10¹⁴ cm⁻³, lower than 1×10¹³ cm⁻³, lower than 1×10¹² cm⁻³, lower than 1×10¹¹ cm⁻³, or lower than 1×10¹⁰ cm⁻³. The lower limit of the carrier concentration in the channel formation region is not particularly limited and can be, for example, 1×10⁻⁷ cm⁻³.

As described above, the electrical characteristics of the OS transistor may vary easily and the reliability of the OS transistor may be decreased when oxygen vacancies (V_{O}) and impurities are present in the channel formation region in the oxide semiconductor. Accordingly, in order to obtain stable electrical characteristics of the OS transistor, reducing the impurity concentration in the oxide semiconductor is effective. In order to reduce the impurity concentration in the oxide semiconductor, it is preferable that the impurity concentration in an adjacent film be also reduced. Examples of impurities include hydrogen, carbon, and nitrogen.

When the oxide semiconductor contains nitrogen, a trap state is sometimes formed. This may make the electrical characteristics of the transistor unstable. Accordingly, the nitrogen concentration in the channel formation region in the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

When the oxide semiconductor contains an alkali metal or an alkaline earth metal, defect states are formed and the transistor has unstable electrical characteristics in some cases. Thus, the concentration of an alkali metal or an alkaline earth metal in the channel formation region in the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region of a transistor, the transistor can have stable electrical characteristics.

### [Insulating Layer]

An inorganic insulating film is preferably used as each of the insulating layers included in the semiconductor device (e.g., the insulating layers 210, 212, 214, 216, 221, 222, 224, 241a, 241b, 250, 254, 271a, 271b, 275, 280, 283, and 285). Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used for the insulating layer included in the semiconductor device.

With scaling down and high integration of a transistor, for example, a problem such as generation of a leakage current may arise because of a thin gate insulating layer. When a high-k material is used for the gate insulating layer, the voltage at the time of operation of the transistor can be reduced while the physical thickness is maintained. Furthermore, the equivalent oxide thickness (EOT) of the gate insulating layer can be reduced. By contrast, when a material with a low relative permittivity is used for the insulating layer functioning as an interlayer film, the parasitic capacitance generated between wirings can be reduced. Thus, a material is preferably selected depending on the function of an insulating layer. Note that a material with a low relative permittivity is a material with high dielectric strength.

Examples of the material with a high relative permittivity include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of the inorganic insulating material with a low relative permittivity include silicon oxide containing fluorine, silicon oxide containing carbon, and silicon oxide containing carbon and nitrogen. Another example is porous silicon oxide. Note that these silicon oxides can contain nitrogen.

A material that can have ferroelectricity may be used for the insulating layer included in the semiconductor device. As the material that can have ferroelectricity, an oxide containing one or both of hafnium and zirconium is preferably used. Examples of the oxide include metal oxides such as hafnium oxide, zirconium oxide, and hafnium zirconium oxide. As the material that can have ferroelectricity, a material in which an element J1 (the element J1 here is one or more selected from one of hafnium and zirconium, silicon, aluminum, gadolinium, yttrium, lanthanum, strontium, and the like) is added to a metal oxide containing the other of hafnium and zirconium may also be used.

Addition of a Group 3 element in the periodic table to an oxide containing one or both of hafnium and zirconium increases the oxygen vacancy concentration in the oxide and facilitates formation of a crystal having an orthorhombic crystal structure. This is preferable because the proportion of the crystal having an orthorhombic crystal structure is increased and the amount of remanent polarization can be increased. On the other hand, too much addition of the Group 3 element might decrease the crystallinity of the oxide and hinder the exhibition of ferroelectricity. Thus, the content percentage of the Group 3 element in the oxide containing one or both of hafnium and zirconium is preferably higher than or equal to 0.1 atomic % and lower than or equal to 10 atomic %, further preferably higher than or equal to 0.1 atomic % and lower than or equal to 5 atomic %, still further preferably higher than or equal to 0.1 atomic % and lower than or equal to 3 atomic %. Here, the content percentage of the Group 3 element refers to the proportion of the number of the Group 3 element atoms in the number of all metal element atoms contained in the layer. The Group 3 element is preferably one or more selected from scandium, lanthanum, and yttrium, further preferably one or both of lanthanum and yttrium.

Examples of the material that can have ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Examples of the material that can have ferroelectricity also include the above metal nitride to which an element M3 is added. Note that the element M3 is one or more of magnesium, calcium, strontium, zinc, cadmium, and the like.

Examples of the material that can have ferroelectricity include perovskite-type oxynitrides such as SrTaO₂N and BaTaO₂N, and GaFeO₃ with a K-alumina-type structure. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Since the above-listed materials and the like may change their crystal structures (characteristics) according to a variety of processes and the like as well as film formation conditions, a material that exhibits ferroelectricity is referred to not only as a ferroelectric but also as a material that can have ferroelectricity in this specification and the like.

In this specification and the like, the material that can have ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

The ferroelectric layer preferably includes a crystal having an orthorhombic crystal structure, in which case ferroelectricity is exhibited. A crystal included in the ferroelectric layer may have one or more of crystal structures selected from tetragonal, orthorhombic, monoclinic, and hexagonal crystal structures. Alternatively, the ferroelectric layer may have an amorphous structure. In that case, the ferroelectric layer may have a composite structure including an amorphous structure and a crystal structure.

A metal oxide containing one or both of hafnium and zirconium is also an insulating material having a function of capturing or fixing hydrogen. Thus, with the use of a metal oxide containing one or both of hafnium and zirconium for at least part of the gate insulating layer, hydrogen contained in the oxide semiconductor layer can be captured or fixed and the hydrogen concentration in the oxide semiconductor layer can be reduced. The transistor including the gate insulating layer can function as a ferroelectric field-effect transistor (FeFET).

A transistor including a metal oxide can have stable electrical characteristics when surrounded by an insulating layer having a function of inhibiting transmission of impurities and oxygen. The insulating layer having a function of inhibiting transmission of impurities and oxygen can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting transmission of impurities and oxygen, a metal oxide such as aluminum oxide, magnesium oxide, germanium oxide, yttrium oxide, zirconium oxide, lanthanum oxide, neodymium oxide, hafnium oxide, or tantalum oxide, a nitride such as aluminum nitride or silicon nitride, or a nitride oxide such as silicon nitride oxide can be used.

Specific examples of the material for the insulating layer having a function of inhibiting transmission of oxygen and impurities such as water and hydrogen include metal oxides such as aluminum oxide, magnesium oxide, germanium oxide, yttrium oxide, zirconium oxide, lanthanum oxide, neodymium oxide, hafnium oxide, tantalum oxide, and an oxide containing aluminum and hafnium (hafnium aluminate). Other examples include nitrides such as aluminum nitride, aluminum titanium nitride, and silicon nitride. Other examples include a nitride oxide such as silicon nitride oxide. Examples of the material for the insulating layer having a function of inhibiting transmission of oxygen include gallium oxide.

An insulating layer that is in contact with an oxide semiconductor layer or provided in the vicinity of the oxide semiconductor layer, such as a gate insulating layer, preferably includes a region containing excess oxygen. For example, when an insulating layer including a region containing excess oxygen is in contact with an oxide semiconductor layer or positioned in the vicinity of the oxide semiconductor layer, oxygen vacancies in the oxide semiconductor layer can be reduced. For the insulating layer in which the region containing excess oxygen is easily formed, the description in <Structure of semiconductor device> can be referred to.

As the insulating layer that is in contact with the oxide semiconductor layer or provided in the vicinity of the oxide semiconductor layer, a barrier insulating layer against hydrogen is preferably used. When the insulating layer has a barrier property against hydrogen, diffusion of hydrogen into the oxide semiconductor layer can be inhibited. The barrier insulating layer against hydrogen can be rephrased as an insulating layer having a function of inhibiting diffusion of hydrogen.

Examples of an insulating material having a function of capturing or fixing hydrogen include metal oxides such as an oxide containing hafnium, an oxide containing magnesium, an oxide containing aluminum, an oxide containing aluminum and hafnium (hafnium aluminate), and hafnium silicate. Furthermore, these metal oxides may further contain zirconium, and an example of such a metal oxide is an oxide containing hafnium and zirconium.

The insulating layer having a function of capturing or fixing hydrogen preferably has an amorphous structure. In a metal oxide having an amorphous structure, some oxygen atoms have a dangling bond, which allows the metal oxide to have a high property of capturing or fixing hydrogen. Thus, when the insulating layer has an amorphous structure, the function of capturing or fixing hydrogen can be enhanced.

When the insulating layer has an amorphous structure, formation of a crystal grain boundary can be inhibited. Inhibiting formation of a crystal grain boundary can increase the flatness of the insulating layer. This enables the insulating layer to have uniform thickness distribution and a reduced number of extremely thin portions, so that the withstand voltage of the insulating layer can be increased. In addition, the thickness distribution of the film provided over the insulating layer can be uniform. Furthermore, inhibiting formation of a crystal grain boundary in the insulating layer can reduce a leakage current due to the defect states in the crystal grain boundary. Thus, the insulating layer can function as an insulating film with a low leakage current.

Note that a function of capturing or fixing a target substance can also be referred to as a property that does not easily allow diffusion of a target substance. Thus, a function of capturing or fixing a target substance can be rephrased as a barrier property.

In this specification and the like, a barrier insulating layer refers to an insulating layer having a barrier property. In addition, the barrier property refers to a property that does not easily allow diffusion of a target substance (also referred to as a property that does not easily allow transmission of a target substance, a property with low permeability of a target substance, or a function of inhibiting diffusion of a target substance). Note that hydrogen described as a target substance refers to at least one of a hydrogen atom, a hydrogen molecule, and a substance bonded to hydrogen, such as a water molecule or OH⁻, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), a copper atom, and the like. Oxygen described as a target substance refers to, for example, at least one of an oxygen atom, an oxygen molecule, and the like.

Examples of a material for the barrier insulating layer against hydrogen include aluminum oxide, magnesium oxide, hafnium oxide, zirconium oxide, an oxide containing aluminum and hafnium (hafnium aluminate), an oxide containing hafnium and zirconium (hafnium zirconium oxide), silicon nitride, and silicon nitride oxide.

The inorganic insulating layers given as examples of the insulating layer having a function of capturing or fixing hydrogen and the insulating layer having a function of inhibiting diffusion of hydrogen also have a barrier property against oxygen. Examples of a material for a barrier insulating layer against oxygen include an oxide containing one or both of aluminum and hafnium, magnesium oxide, gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and hafnium silicate.

### [Conductive Layer]

For each of the conductive layers included in the semiconductor device (e.g., the conductive layers 205, 220, 240, 242a, 242b, 243a, 243b, and 260), it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, palladium, iridium, strontium, lanthanum, and the like; an alloy containing any of the above metal elements as its component; an alloy containing a combination of the above metal elements; or the like. As an alloy containing any of the above metal elements as its component, a nitride of the alloy or an oxide of the alloy may be used. For example, tantalum nitride, titanium nitride, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. A semiconductor having high electrical conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting diffusion of oxygen, or a material maintaining its conductivity even after absorbing oxygen. Examples of the conductive material containing oxygen include indium oxide containing tungsten oxide, indium oxide containing titanium oxide, ITO, indium tin oxide containing titanium oxide, ITSO, In—Zn oxide, and indium zinc oxide containing tungsten oxide. In this specification and the like, a conductive film formed using the conductive material containing oxygen may be referred to as an oxide conductive film.

Conductive layers formed using any of the above materials may be stacked. For example, a stacked-layer structure combining a material containing any of the above metal elements and a conductive material containing oxygen may be employed. Alternatively, a stacked-layer structure combining a material containing any of the above metal elements and a conductive material containing nitrogen may be employed. Further alternatively, a stacked-layer structure combining a material containing any of the above metal elements, a conductive material containing oxygen, and a conductive material containing nitrogen may be employed.

In the case where a metal oxide is used for the channel formation region of the transistor, the conductive layer functioning as the gate electrode preferably employs a stacked-layer structure combining a material containing any of the above metal elements and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

### [Substrate]

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Other examples include any of the above semiconductor substrates including an insulator region, e.g., a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. Other examples include a substrate which is an insulator substrate provided with a conductor or a semiconductor, a substrate which is a semiconductor substrate provided with a conductor or an insulator, and a substrate which is a conductor substrate provided with a semiconductor or an insulator. Alternatively, these substrates provided with elements may be used. Examples of the element provided over the substrate include a capacitor, a resistor, a switching element, a light-emitting element, and a memory element.

The above is the description of materials that can be used for the semiconductor device of this embodiment.

This embodiment can be combined with any of the other embodiments and examples as appropriate. In this specification, in the case where a plurality of structure examples are shown in one embodiment, the structure examples can be combined as appropriate.

### Embodiment 3

In this embodiment, a semiconductor device 900 of one embodiment of the present invention will be described. The semiconductor device 900 can function as a memory device.

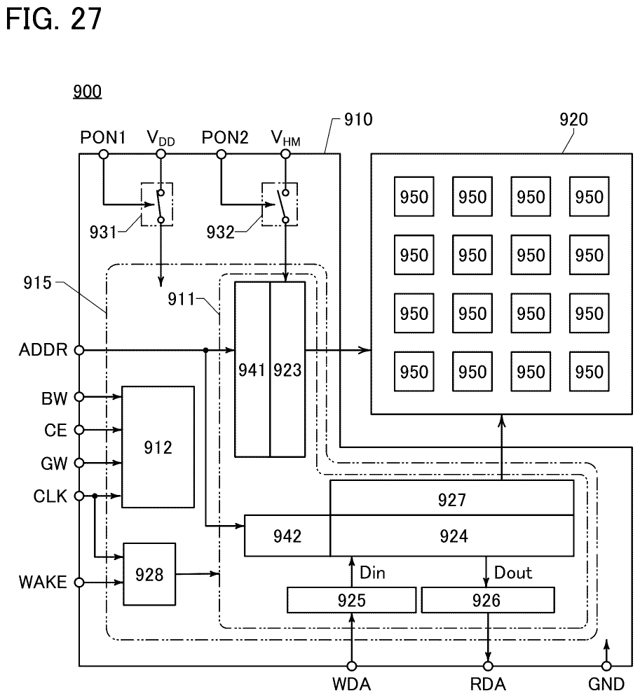

FIG. 27 is a block diagram illustrating a structure example of the semiconductor device 900. The semiconductor device 900 illustrated in FIG. 27 includes a driver circuit 910 and a memory array 920. The memory array 920 includes at least one memory cell 950. FIG. 27 illustrates an example in which the memory array 920 includes a plurality of memory cells 950 arranged in a matrix.

The semiconductor device (the transistor 200, the transistor 200A, or the transistor 200B) described in Embodiment 2 can be used in the memory cells 950. With the use of the transistor described in Embodiment 2, the operation speed of the memory device can be increased. This also enables further miniaturization and higher integration of the memory device. In addition, the capacity per area of the memory device can be increased.

The driver circuit 910 includes a power switch (PSW) 931, a PSW 932, and a peripheral circuit 915. The peripheral circuit 915 includes a peripheral circuit 911, a control circuit 912, and a voltage generator circuit 928.

In the semiconductor device 900, the circuits, signals, and voltages can be appropriately selected as needed. Another circuit or another signal may be added. Signals BW, CE, GW, CLK, WAKE, ADDR, WDA, PON1, and PON2 are signals input from the outside, and a signal RDA is a signal output to the outside. The signal CLK is a clock signal.

The signals BW, CE, and GW are control signals. The signal CE is a chip enable signal. The signal GW is a global write enable signal. The signal BW is a byte write enable signal. The signal ADDR is an address signal. The signal WDA is a write data signal, and the signal RDA is a read data signal. The signals PON1 and PON2 are power gating control signals. Note that the signals PON1 and PON2 may be generated in the control circuit 912.

The control circuit 912 is a logic circuit having a function of controlling the overall operation of the semiconductor device 900. For example, the control circuit 912 performs logical operation on the signals CE, GW, and BW to determine the operating mode (e.g., write operation or read operation) of the semiconductor device 900. The control circuit 912 generates a control signal for the peripheral circuit 911 so that the operating mode is executed.

The voltage generator circuit 928 has a function of generating a negative voltage. The signal WAKE has a function of controlling the input of the signal CLK to the voltage generator circuit 928. For example, when an H-level signal is supplied as the signal WAKE, the signal CLK is input to the voltage generator circuit 928, and the voltage generator circuit 928 generates a negative voltage.

The peripheral circuit 911 is a circuit for writing and reading data to/from the memory cell 950. The peripheral circuit 911 includes a row decoder 941, a column decoder 942, a row driver 923, a column driver 924, an input circuit 925, an output circuit 926, and the sense amplifier 927.

The row decoder 941 and the column decoder 942 have a function of decoding the signal ADDR. The row decoder 941 is a circuit for specifying a row to be accessed. The column decoder 942 is a circuit for specifying a column to be accessed. The row driver 923 has a function of selecting the row specified by the row decoder 941. The column driver 924 has a function of writing data to the memory cell 950, a function of reading data from the memory cell 950, and a function of retaining the read data, for example.

The input circuit 925 has a function of retaining the signal WDA. Data retained in the input circuit 925 is output to the column driver 924. Data output from the input circuit 925 is data (Din) written to the memory cell 950. Data (Dout) read from the memory cell 950 by the column driver 924 is output to the output circuit 926. The output circuit 926 has a function of retaining Dout. Moreover, the output circuit 926 has a function of outputting Dout to the outside of the semiconductor device 900. The data output from the output circuit 926 is the signal RDA.

The PSW 931 has a function of controlling supply of VDD to the peripheral circuit 915. The PSW 932 has a function of controlling supply of VHM to the row driver 923. Here, in the semiconductor device 900, a high power supply potential is VDD and a low power supply potential is a ground potential (GND). In addition, VHM is a high power supply potential used for setting a word line at a high level, and is higher than VDD. The on/off state of the PSW 931 is controlled by the signal PON1, and the on/off state of the PSW 932 is controlled by the signal PON2. The number of power domains to which VDD is supplied is one in the peripheral circuit 915 in FIG. 27 but can be more than one. In that case, a power switch is provided for each power domain.

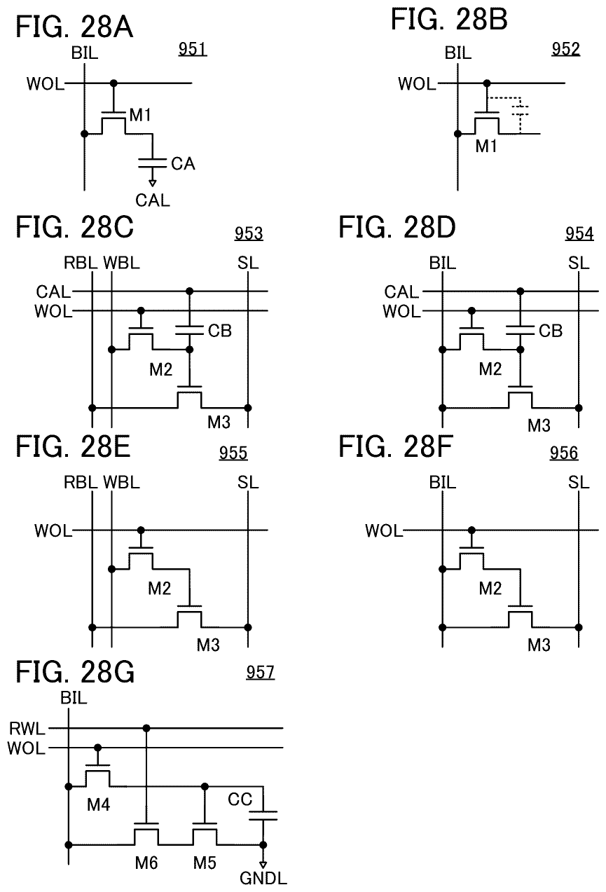

Structure examples of memory cells each of which can be used as the memory cell 950 are described with reference to FIGS. 28A to 28G.

### [DOSRAM]

FIG. 28A illustrates a circuit configuration example of a memory cell for a dynamic random access memory (DRAM). In this specification and the like, a DRAM including an OS transistor is referred to as a dynamic oxide semiconductor random access memory (DOSRAM). The memory cell 951 includes the transistor M1 and the capacitor CA.

Note that the transistor M1 may include a front gate (sometimes simply referred to as a gate) and a back gate. Here, the back gate may be connected to a wiring supplied with a constant potential or a signal, and the front gate and the back gate may be connected to each other.

A first terminal of the transistor M1 is connected to a first terminal of the capacitor CA. A second terminal of the transistor M1 is connected to the wiring BIL. A gate of the transistor M1 is connected to the wiring WOL. A second terminal of the capacitor CA is connected to the wiring CAL.

The wiring BIL functions as a bit line, and the wiring WOL functions as a word line. The wiring CAL functions as a wiring for applying a predetermined potential to the second terminal of the capacitor CA. At the time of data writing and data reading, a low-level potential (sometimes referred to as a reference potential) is preferably applied to the wiring CAL.

Data writing and data reading are performed as follows: a high-level potential is applied to the wiring WOL to turn on the transistor M1 so that electrical continuity is established between the wiring BIL and the first terminal of the capacitor CA (a current can flow therebetween).

The memory cell that can be used as the memory cell 950 is not limited to the memory cell 951, and the circuit structure can be changed. For example, the structure of a memory cell 952 illustrated in FIG. 28B may be employed. The memory cell 952 is an example including neither the capacitor CA nor the wiring CAL. The first terminal of the transistor M1 is in an electrically floating state.

In the memory cell 952, a potential written through the transistor M1 is retained in a capacitor (also referred to as parasitic capacitance) between the first terminal and the gate, which is shown by a dashed line. With such a structure, the structure of the memory cell can be greatly simplified.

Note that an OS transistor is preferably used as the transistor M1. With the use of the OS transistor, the operating speed of the memory device can be increased. An OS transistor has a characteristic of an extremely low off-state current. The use of an OS transistor as the transistor M1 enables an extremely low leakage current of the transistor M1. That is, with the use of the transistor M1, written data can be retained for a long time, and thus the frequency of refresh operation for the memory cell can be decreased. Alternatively, refresh operation for the memory cell can be omitted. In addition, owing to an extremely low leakage current, multilevel data or analog data can be retained in the memory cells 951 and 952.

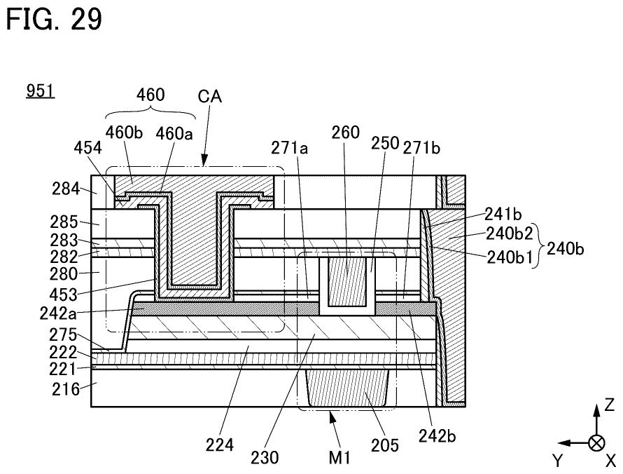

Here, an example of the structure of a DOSRAM is described with reference to FIG. 29. In FIG. 29, the X direction is parallel to the channel width direction of an illustrated transistor, the Y direction is perpendicular to the X direction, and the Z direction is perpendicular to the X direction and the Y direction.

As illustrated in FIG. 29, the memory cell 951 includes the transistor M1 and the capacitor CA. An insulating layer 284 is provided over the transistor M1. For the insulating layer 284, an insulator that can be used for the insulating layer 216 can be used. Note that the transistor M1 has the same structure as the transistor 200A described in the Embodiment 2, and the same components may be denoted by the same reference numerals. Embodiment 2 can be referred to for the details of the transistor 200A. The conductive layer 240b (conductive layers 240b1 and 240b2) is provided in contact with one of a source electrode and a drain electrode (the conductive layer 242b) of the transistor M1. The conductive layer 240b extends in the Z direction and functions as the wiring BIL. The conductive layer 260 of the transistor M1 extends in the X direction and functions as the wiring WOL.

The capacitor CA includes a conductive layer 453 over the conductive layer 242a, an insulating layer 454 over the conductive layer 453, and a conductive layer 460 (conductive layers 460a and 460b) over the insulating layer 454.

At least parts of the conductive layer 453, the insulating layer 454, and the conductive layer 460 are positioned inside an opening portion formed in the insulating layers 271a, 275, 280, 282, 283, and 285. End portions of the conductive layer 453, the insulating layer 454, and the conductive layer 460 are positioned at least over the insulating layer 283, and preferably positioned over the insulating layer 285. The insulating layer 454 is provided to cover the end portion of the conductive layer 453. This enables the conductive layers 453 and 460 to be electrically insulated from each other.

The deeper the opening portion formed in the insulating layers 271a, 275, 280, 282, 283, and 285 is (i.e., the larger the thickness of at least one of the insulating layers 271a, 275, 280, 282, 283, and 285 is), the larger the electrostatic capacitance of the capacitor CA can be. Increasing the electrostatic capacitance per unit area of the capacitor CA enables further miniaturization and higher integration of the memory device. For example, the electrostatic capacitance of the capacitor CA can be set by adjusting the thickness of the insulating layer 285. Specifically, the thickness of the insulating layer 285 can be set within the range from 50 nm to 250 nm, and the depth of the opening portion can be approximately greater than or equal to 150 nm and less than or equal to 350 nm. When the capacitor CA is formed with the thickness of the insulating layer 285 and the depth of the opening within the above-described ranges, the capacitor CA can have adequate electrostatic capacitance, and the height of one layer can be prevented from being excessively large in a semiconductor device in which a plurality of memory cell layers are stacked. Note that capacitors provided in memory cells may have different electrostatic capacitances between the plurality of memory cell layers. In this structure, the insulating layers 285 provided in the memory cell layers may have different thicknesses, for example.

In the capacitor CA, the conductive layer 453 includes a region functioning as one electrode (lower electrode), the insulating layer 454 includes a region functioning as a dielectric, and the conductive layer 460 includes a region functioning as the other electrode (upper electrode). An upper portion of the conductive layer 460 can be extended to function as the wiring CAL. The capacitor CA is a metal-insulator-metal (MIM) capacitor.

The conductive layer 242a provided over the semiconductor layer 230 to overlap with the semiconductor layer 230 functions as an electrode that is electrically connected to the lower electrode of the capacitor CA.

The conductive layers 453 and 460 can each be formed using a conductor that can be used for the conductive layer 205 or 260. The conductive layers 453 and 460 are preferably deposited by a formation method that enables excellent coverage, such as an ALD method or a CVD method. For example, titanium nitride or tantalum nitride deposited by an ALD method or a CVD method can be used for the conductive layer 453.

The top surface of the conductive layer 242a is in contact with the bottom surface of the conductive layer 453. Here, the contact resistance between the conductive layer 453 and the conductive layer 242a can be reduced when the conductive layer 242a is formed using a conductive material with high conductivity.

Titanium nitride deposited by an ALD method or a CVD method can be used for the conductive layer 460a, and tungsten deposited by a CVD method can be used for the conductive layer 460b. In the case where the adhesion of tungsten to the insulating layer 454 is sufficiently high, the conductive layer 460 may have a single-layer structure of tungsten deposited by a CVD method.

For the insulating layer 454 included in the capacitor CA, the high-k material described in the above embodiment is preferably used. Using such a high-k material allows the insulating layer 454 to be thick enough to inhibit a leakage current and a sufficiently high capacitance of the capacitor CA to be ensured. The insulating layer 454 is preferably deposited by a formation method that enables excellent coverage, such as an ALD method or a CVD method.

It is preferable to use stacked insulating layers each formed of any of the above-described materials. A stacked-layer structure including a high high-k material and a material having higher dielectric strength than the high high-k material is preferably used. For example, as the insulating layer 454, an insulating film in which zirconium oxide, aluminum oxide, and zirconium oxide are stacked in this order can be used. An insulating film in which zirconium oxide, aluminum oxide, zirconium oxide, and aluminum oxide are stacked in this order can be used, for example. For another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit electrostatic breakdown of the capacitor CA.

For the insulating layer 454, any of the materials that can have ferroelectricity, which are described in [Insulating layer] in Embodiment 2, may be used.

The ferroelectric refers to an insulator having properties of causing internal polarization by application of an electric field from the outside and maintaining the polarization even after the electric field is made zero. Thus, with the use of a capacitor containing this material as a dielectric (hereinafter, such a capacitor is sometimes referred to as a ferroelectric capacitor), a nonvolatile memory element can be formed. A nonvolatile memory element including a ferroelectric capacitor is sometimes referred to as a ferroelectric random access memory (FeRAM), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor CA, the memory device described in this embodiment functions as a ferroelectric memory.

Note that the sidewall of the opening portion in which the capacitor CA is positioned may be perpendicular or substantially perpendicular to the top surface of the insulating layer 222 or may be tapered. The tapered sidewall can increase the coverage with the conductive layer 453 and the like provided in the opening portion and thus can reduce the number of defects such as voids.

The conductive layer 242b provided over the semiconductor layer 230 to overlap with the semiconductor layer 230 functions as a wiring electrically connected to the conductive layer 240b. For example, in FIG. 29, the top surface and a side end portion of the conductive layer 242b are connected to the conductive layer 240b extending the Z direction.

When the conductive layer 240b is directly in contact with at least one of the top surface and the side end portion of the conductive layer 242b, a separate electrode for connection does not need to be provided, so that the area occupied by the memory array can be reduced. In addition, the integration degree of the memory cells is increased, so that the memory capacity of the memory device can be increased. Note that the conductive layer 240b is preferably in contact with the side end portion and part of the top surface of the conductive layer 242b. When the conductive layer 240b is in contact with a plurality of surfaces of the conductive layer 242b, the contact resistance between the conductive layers 240b and 242b can be reduced.

The conductive layer 240b is provided in an opening formed in the insulating layers 216, 221, 222, 271b, 275, 280, 282, 283, 285, and 284.

As illustrated in FIG. 29, the insulating layer 241b is preferably provided in contact with a side surface of the conductive layer 240b. Specifically, the insulative layer 241b is provided in contact with an inner wall of the opening portion formed in the insulating layers 216, 221, 222, 224, 271b, 275, 280, 282, 283, 285, and 284. The insulating layer 241b is formed also on a side surface of the semiconductor layer 230 protruding in the opening portion. Note that at least part of the conductive layer 242b not covered with the insulating layer 241b is exposed and is in contact with the conductive layer 240b. That is, the conductive layer 240b is provided to fill the opening portion with the insulating layer 241b between the inner wall of the opening portion and the conducting layer 240b.

Note that as illustrated in FIG. 29, an uppermost portion of the insulating layer 241b formed below the conductive layer 242b is preferably positioned below the top surface of the conductive layer 242b. With such a structure, the conductive layer 240b can be in contact with at least part of the side end portion of the conductive layer 242b. The insulating layer 241b formed below the conductive layer 242b preferably includes a region in contact with the side surface of the semiconductor layer 230. This structure can inhibit impurities contained in the insulating layer 280 and the like, such as water and hydrogen, from entering the semiconductor layer 230 through the conductive layer 240b.

The sidewall of the opening portion in which the conductive layer 240b and the insulating layer 241b are provided may be perpendicular or substantially perpendicular to the top surface of the insulating layer 222 or may be tapered. The tapered sidewall can improve the coverage with the insulating layer 241b and the like provided in the opening portion.

### [NOSRAM]

FIG. 28C illustrates a circuit configuration example of a gain-cell memory cell including two transistors and one capacitor. A memory cell 953 includes the transistor M2, the transistor M3, and a capacitor CB. In this specification and the like, a memory device including a gain-cell memory cell using an OS transistor as the transistor M2 is referred to as a nonvolatile oxide semiconductor RAM (NOSRAM).

A first terminal of the transistor M2 is connected to a first terminal of the capacitor CB. A second terminal of the transistor M2 is connected to the wiring WBL. The gate of the transistor M2 is connected to the wiring WOL. A second terminal of the capacitor CB is connected to the wiring CAL. A first terminal of the transistor M3 is connected to the wiring RBL. A second terminal of the transistor M3 is connected to the wiring SL. The gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. At the time of data writing, data retention, and data reading, a low-level potential (sometimes referred to as a reference potential) is preferably applied to the wiring CAL.

Data writing is performed as follows: a high-level potential is applied to the wiring WOL to turn on the transistor M2 so that electrical continuity is established between the wiring WBL and the first terminal of the capacitor CB. Specifically, when the transistor M2 is on, a potential corresponding to data to be stored is applied to the wiring WBL, and the potential is written to the first terminal of the capacitor CB and the gate of the transistor M3. Then, a low-level potential is applied to the wiring WOL to turn off the transistor M2, whereby the potential of the first terminal of the capacitor CB and the potential of the gate of the transistor M3 are retained.

Data reading is performed by applying a predetermined potential to the wiring SL. A current flowing between the source and the drain of the transistor M3 and the potential of the first terminal of the transistor M3 are determined by the potential of the gate of the transistor M3 and the potential of the second terminal of the transistor M3. Accordingly, by reading the potential of the wiring RBL connected to the first terminal of the transistor M3, a potential retained in the first terminal of the capacitor CB (or the gate of the transistor M3) can be read. That is, data written to the memory cell can be read on the basis of the potential retained in the first terminal of the capacitor CB (or the gate of the transistor M3).

For another example, one wiring BIL may be provided instead of the wiring WBL and the wiring RBL. A circuit configuration example of the memory cell is illustrated in FIG. 28D. In a memory cell 954, one wiring BIL is provided instead of the wiring WBL and the wiring RBL in the memory cell 953, and the second terminal of the transistor M2 and the first terminal of the transistor M3 are connected to the wiring BIL. That is, one wiring BIL operates as the write bit line and the read bit line in the memory cell 954.

The memory cell 955 illustrated in FIG. 28E is an example in which the capacitor CB and the wiring CAL in the memory cell 953 are omitted. A memory cell 956 illustrated in FIG. 28F is an example in which the capacitor CB and the wiring CAL in the memory cell 954 are omitted. Such configurations enable high integration of the memory cells.

An OS transistor is preferably used as at least the transistor M2. An OS transistor is particularly preferably used as each of the transistors M2 and M3. With use of an OS transistor as the transistor M2, written data can be retained for a long time, and thus the frequency of the refresh operation for the memory cell can be decreased. Alternatively, refresh operation for the memory cell can be omitted. In addition, owing to an extremely low leakage current, multilevel data or analog data can be retained in the memory cells 953 to 956.

The memory cells 953 to 956 each using the OS transistor as the transistor M2 are embodiments of a NOSRAM.

Note that a Si transistor may be used as the transistor M3. The Si transistor can have high field-effect mobility and can be formed as a p-channel transistor, so that circuit design flexibility can be increased.

FIG. 28G illustrates a gain-cell memory cell 957 including three transistors and one capacitor. The memory cell 957 includes transistors M4 to M6 and a capacitor CC.

A first terminal of the transistor M4 is connected to a first terminal of the capacitor CC. A second terminal of the transistor M4 is connected to the wiring BIL. A gate of the transistor M4 is connected to the wiring WOL. A second terminal of the capacitor CC is connected to a first terminal of the transistor M5 and a wiring GNDL. A second terminal of the transistor M5 is connected to a first terminal of the transistor M6. A gate of the transistor M5 is connected to the first terminal of the capacitor CC. A second terminal of the transistor M6 is connected to the wiring BIL. A gate of the transistor M6 is connected to a wiring RWL.

The wiring BIL functions as a bit line. The wiring WOL functions as a write word line. The wiring RWL functions as a read word line. The wiring GNDL is a wiring for supplying a low-level potential.

Data writing is performed as follows: a high-level potential is applied to the wiring WOL to turn on the transistor M4 so that electrical continuity is established between the wiring BIL and the first terminal of the capacitor CC. Specifically, when the transistor M4 is on, a potential corresponding to data to be stored is applied to the wiring BIL, and the potential is written to the first terminal of the capacitor CC and the gate of the transistor M5. Then, a low-level potential is applied to the wiring WOL to turn off the transistor M4, whereby the potential of the first terminal of the capacitor CC and the potential of the gate of the transistor M5 are retained.

Data reading is performed by precharging the wiring BIL with a predetermined potential, and then making the wiring BIL in an electrically floating state and applying a high-level potential to the wiring RWL. Since the wiring RWL has the high-level potential, the transistor M6 is turned on, so that electrical continuity is established between the wiring BIL and the second terminal of the transistor M5. At this time, the potential of the wiring BIL is applied to the second terminal of the transistor M5; the potential of the second terminal of the transistor M5 and the potential of the wiring BIL change depending on the potential retained in the first terminal of the capacitor CC (or the gate of the transistor M5). Here, the potential retained in the first terminal of the capacitor CC (or the gate of the transistor M5) can be read by reading the potential of the wiring BIL. That is, data written to the memory cell can be read on the basis of the potential retained in the first terminal of the capacitor CC (or the gate of the transistor M5).

Note that an OS transistor is preferably used as at least the transistor M4.

Note that Si transistors may be used as the transistors M5 and M6. As described above, a Si transistor may have higher field-effect mobility than an OS transistor depending on the crystal state of silicon used in a semiconductor layer, for example.

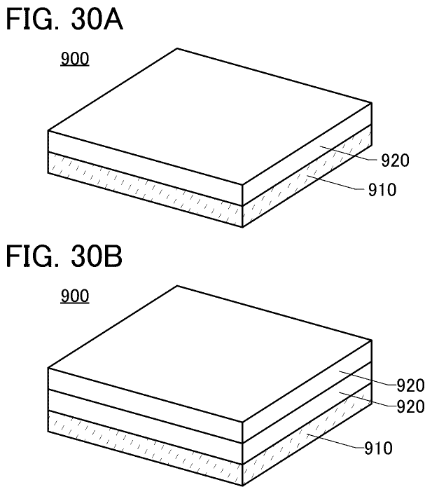

The driver circuit 910 and the memory array 920 included in the semiconductor device 900 may be provided on the same plane. Alternatively, as illustrated in FIG. 30A, the driver circuit 910 and the memory array 920 may be provided to overlap with each other. Providing the driver circuit 910 and the memory array 920 to overlap with each other can shorten a signal propagation distance. As illustrated in FIG. 30B, a plurality of memory arrays 920 may be stacked over the driver circuit 910.

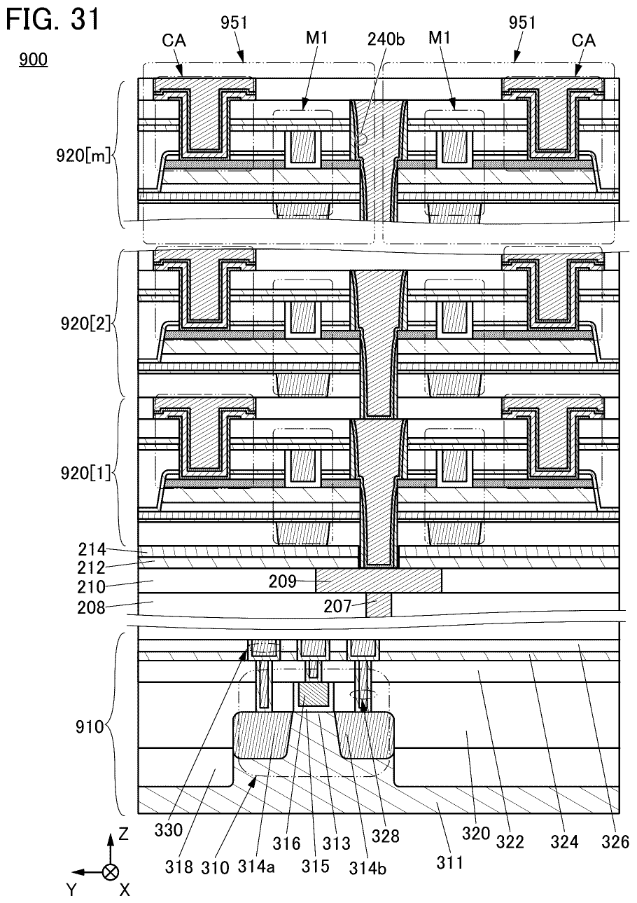

Here, a structure example of the semiconductor device 900 in which a plurality of memory arrays 920 are stacked is described with reference to FIG. 31.

The semiconductor device 900 illustrated in FIG. 31 includes the driver circuit 910 that is a layer including a transistor 310 and the like and memory arrays 920[1] to 920[m] over the driver circuit 910. Here, FIG. 31 illustrates the memory array 920[1] as the layer provided in the first layer (the bottom layer), the memory array 920[2] as the layer provided in the second layer, and the memory array 920[m] as the layer provided in the m-th layer (the top layer). In other words, the memory device of one embodiment of the present invention may include a plurality of layers including memory cells and have a structure in which the plurality of layers are stacked.

FIG. 31 illustrates an example of the transistor 310 included in the driver circuit 910. The transistor 310 is provided on a substrate 311 and includes a conductive layer 316 functioning as a gate, an insulating layer 315 functioning as a gate insulating layer, a semiconductor region 313 that includes part of the substrate 311, and a low-resistance region 314a and a low-resistance region 314b each functioning as a source region or a drain region. An element isolation layer 318 is preferably provided between adjacent transistors 310. The transistor 310 may be either a p-channel transistor or an n-channel transistor. As the substrate 311, a single crystal silicon substrate can be used, for example.

In the transistor 310, the semiconductor region 313 (part of the substrate 311) where a channel is formed has a protruding shape. Furthermore, the conductive layer 316 is provided to cover the side surface and top surface of the semiconductor region 313 with the insulating layer 315 therebetween. Note that the conductive layer 316 may be formed using a material for adjusting the work function. The transistor 310 is also referred to as a FIN-type transistor because it utilizes a projecting portion of a semiconductor substrate. Note that an insulating layer functioning as a mask for forming the projecting portion may be provided in contact with the top of the projecting portion. Although the case where the projecting portion is formed by processing part of the semiconductor substrate is described here, a semiconductor film having a projecting shape may be formed by processing an SOI substrate.

Note that the transistor 310 illustrated in FIG. 31 is just an example and is not limited to having the structure illustrated therein; an appropriate transistor can be used in accordance with a circuit structure or a driving method.

A wiring layer including an interlayer film, a wiring, a plug, and the like may be provided between components. A plurality of wiring layers can be provided in accordance with the design. Note that a plurality of conductive layers functioning as plugs or wirings are collectively denoted by the same reference numeral in some cases. In this specification and the like, a wiring and a plug electrically connected to the wiring may be a single component. That is, in some cases, part of a conductive layer functions as a wiring or part of a conductive layer functions as a plug.

For example, an insulating layer 320, an insulating layer 322, an insulating layer 324, and an insulating layer 326 are stacked over the transistor 310 in this order as interlayer films. A conductive layer 328 and the like are embedded in the insulating layers 320 and 322. A conductive layer 330 and the like are embedded in the insulating layers 324 and 326. Note that the conductive layer 328 and the conductive layer 330 function as contact plugs or wirings.

The insulating layer functioning as an interlayer film may function as a planarization film that covers a roughness thereunder. For example, the top surface of the insulating layer 322 may be planarized by a CMP method to improve the flatness.

Examples of an insulator that can be used for an interlayer film include an insulating oxide, an insulating nitride, an insulating oxynitride, an insulating nitride oxide, an insulating metal oxide, an insulating metal oxynitride, and an insulating metal nitride oxide.

For example, when a material having a low relative permittivity is used for the insulating layer functioning as an interlayer film, the parasitic capacitance between wirings can be reduced. Thus, a material is preferably selected depending on the function of an insulating layer.

An insulating layer 208 is provided over the driver circuit 910, and a conductive layer 207 is provided in an opening formed in the insulating layer 208. The insulating layer 210 is provided over the insulating layer 208, and a conductive layer 209 is provided in an opening formed in the insulating layer 210. Furthermore, the insulating layer 212 is provided over the insulating layer 210, and the insulating layer 214 is provided over the insulating layer 212. Part of the conductive layer 240b provided in the memory array 920[1] is embedded in an opening formed in the insulating layers 212 and 214. Here, for the insulating layers 208 and 210, an insulator that can be used for the insulating layer 216 can be used.

The conductive layer 207 functions as a wiring electrically connected to the driver circuit 910. The top surface of the conductive layer 207 is provided in contact with the bottom surface of the conductive layer 209. The top surface of the conductive layer 209 is provided in contact with the bottom surface of the conductive layer 240b provided in the memory array 920[1]. With this structure, the conductive layer 240b corresponding to the wiring BIL can be electrically connected to the driver circuit 910.

Each of the memory arrays 920[1] to 920[m] includes a plurality of the memory cells 951. The conductive layer 240b of each of the memory cells 951 is electrically connected to the conductive layer 240b in an upper layer and to the conductive layer 240b in a lower layer.

As illustrated in FIG. 31, the conductive layer 240b is shared between the adjacent memory cells 951. The structures of the adjacent memory cells 951 are symmetrical with respect to the conductive layer 240b.

In the above memory array 920, the plurality of memory arrays 920[1] to 920[m] can be stacked. The memory arrays 920[1] to 920[m] included in the memory array 920 are provided in a direction perpendicular to the surface of a substrate on which the driver circuit 910 is provided, in which case the memory density of the memory cells 951 can be increased. The memory array 920 can be formed by repeating the same manufacturing process in the perpendicular direction. The manufacturing cost of the memory array 920 in the semiconductor device 900 can be reduced.

Next, description is made on an example of an arithmetic processing device that can include the semiconductor device such as the memory device described above.

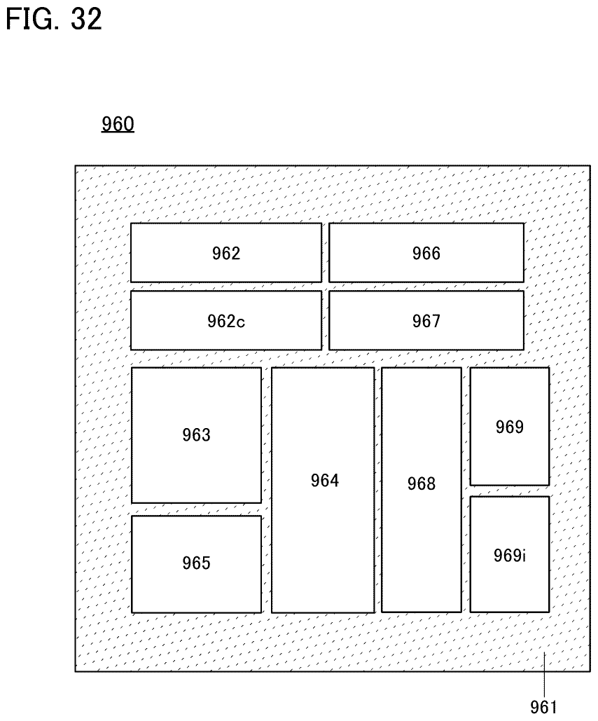

FIG. 32 is a block diagram of an arithmetic device 960. The arithmetic device 960 illustrated in FIG. 32 can be used as a CPU, for example. The arithmetic device 960 can also be used as a processor including a larger number of (several tens to several hundreds of) processor cores capable of parallel processing than a CPU, such as a graphics processing unit (GPU), a tensor processing unit (TPU), or a neural processing unit (NPU).

The arithmetic device 960 illustrated in FIG. 32 includes, over a substrate 961, an arithmetic logic unit (ALU) 962, an ALU controller 962c, an instruction decoder 963, an interrupt controller 964, a timing controller 965, a register 966, a register controller 967, a bus interface 968, a cache 969, and a cache interface 969i. A semiconductor substrate, an SOI substrate, a glass substrate, or the like is used as the substrate 961. The arithmetic device 960 may also include a rewritable ROM and a ROM interface. The cache 969 and the cache interface 969i may be provided in a separate chip.

The cache 969 is connected via the cache interface 969i to a main memory provided in another chip. The cache interface 969i has a function of supplying part of data retained in the main memory to the cache 969. The cache interface 969i also has a function of outputting part of data retained in the cache 969 to the ALU 962, the register 966, or the like through the bus interface 968.

As described later, the memory array 920 can be stacked over the arithmetic device 960. The memory array 920 can be used as a cache. Here, the cache interface 969i may have a function of supplying data retained in the memory array 920 to the cache 969. Moreover, in that case, the driver circuit 910 is preferably included in part of the cache interface 969i.

Note that it is also possible that the cache 969 is not provided and only the memory array 920 is used as a cache.

The arithmetic device 960 illustrated in FIG. 32 is just an example with a simplified structure, and the actual arithmetic device 960 has a variety of structures depending on the application. For example, what is called a multicore structure is preferably employed in which a plurality of cores each including the arithmetic device 960 in FIG. 32 operate in parallel. The larger number of cores can further enhance the arithmetic performance. The number of cores is preferably larger; for example, the number is preferably 2, further preferably 4, still further preferably 8, yet further preferably 12, yet still further preferably 16 or larger. For application requiring extremely high arithmetic performance, e.g., a server, it is preferable to employ the multicore structure including 16 or more, preferably 32 or more, further preferably 64 or more cores. The number of bits that the arithmetic device 960 can handle with an internal arithmetic circuit, a data bus, or the like can be 8, 16, 32, or 64, for example.

An instruction input to the arithmetic device 960 through the bus interface 968 is input to the instruction decoder 963 and decoded, and then input to the ALU controller 962c, the interrupt controller 964, the register controller 967, and the timing controller 965.

The ALU controller 962c, the interrupt controller 964, the register controller 967, and the timing controller 965 conduct various controls in accordance with the decoded instruction. Specifically, the ALU controller 962c generates signals for controlling the operation of the ALU 962. The interrupt controller 964 judges and processes an interrupt request from an external input/output device, a peripheral circuit, or the like on the basis of its priority, a mask state, or the like while the arithmetic device 960 is executing a program. The register controller 967 generates the address of the register 966, and reads/writes data from/to the register 966 in accordance with the state of the arithmetic device 960.

The timing controller 965 generates signals for controlling operation timings of the ALU 962, the ALU controller 962c, the instruction decoder 963, the interrupt controller 964, and the register controller 967. For example, the timing controller 965 includes an internal clock generator for generating an internal clock signal on the basis of a reference clock signal, and supplies the internal clock signal to the above circuits.

In the arithmetic device 960 illustrated in FIG. 32, the register controller 967 selects operation of retaining data in the register 966 in accordance with an instruction from the ALU 962. That is, the register controller 967 selects whether data is retained by a flip-flop or by a capacitor in a memory cell included in the register 966. When data retention by the flip-flop is selected, a power supply potential is supplied to the memory cell in the register 966. When data retention by the capacitor is selected, the data is rewritten into the capacitor, and supply of the power supply potential to the memory cell in the register 966 can be stopped.

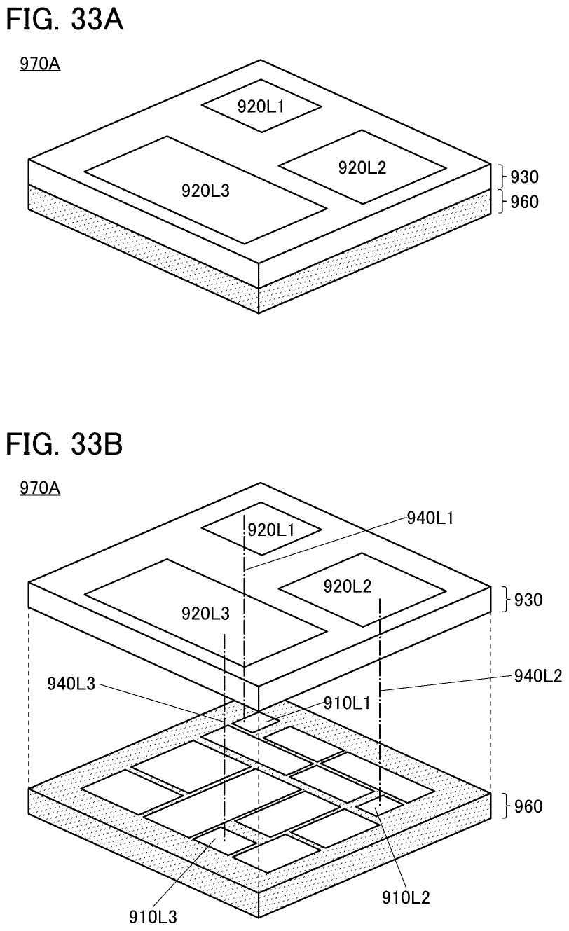

The memory array 920 and the arithmetic device 960 can be provided to overlap with each other. FIGS. 33A and 33B are perspective views of a semiconductor device 970A. The semiconductor device 970A includes a layer 930 provided with memory arrays over the arithmetic device 960. A memory array 920L1, a memory array 920L2, and a memory array 920L3 are provided in the layer 930. The arithmetic device 960 and each of the memory arrays overlap with each other. For easy understanding of the structure of the semiconductor device 970A, the arithmetic device 960 and the layer 930 are separately illustrated in FIG. 33B.

Providing the arithmetic device 960 and the layer 930 including the memory arrays to overlap with each other can shorten the connection distance therebetween. Accordingly, the communication speed therebetween can be increased. Moreover, a short connection distance leads to lower power consumption.

As a method for stacking the arithmetic device 960 and the layer 930 including the memory arrays, either of the following methods may be employed: a method in which the layer 930 including the memory arrays is stacked directly on the arithmetic device 960, which is also referred to as monolithic stacking, and a method in which the arithmetic device 960 and the layer 930 are formed over two different substrates, the substrates are bonded to each other, and the arithmetic device 960 and the layer 930 are connected to each other with a through via or by a technique for bonding conductive films (e.g., Cu—Cu bonding). The former method does not require consideration of misalignment in bonding; thus, not only the chip size but also the manufacturing cost can be reduced.

Here, it is possible that the arithmetic device 960 does not include the cache 969 and the memory arrays 920L1, 920L2, and 920L3 provided in the layer 930 are each used as a cache. In that case, for example, the memory array 920L1, the memory array 920L2, and the memory array 920L3 can be used as an L1 cache (also referred to as a level 1 cache), an L2 cache (also referred to as a level 2 cache), and an L3 cache (also referred to as a level 3 cache), respectively. Among the three memory arrays, the memory array 920L3 has the highest capacity and the lowest access frequency. The memory array 920L1 has the lowest capacity and the highest access frequency.

Note that in the case where the cache 969 provided in the arithmetic device 960 is used as the L1 cache, the memory arrays provided in the layer 930 can each be used as the lower-level cache or the main memory. The main memory has higher capacity and lower access frequency than the cache.

As illustrated in FIG. 33B, a driver circuit 910L1, a driver circuit 910L2, and a driver circuit 910L3 are provided. The driver circuit 910L1 is connected to the memory array 920L1 through a connection electrode 940L1. Similarly, the driver circuit 910L2 is connected to the memory array 920L2 through a connection electrode 940L2, and the driver circuit 910L3 is connected to the memory array 920L3 through a connection electrode 940L3.

Although the case where three memory arrays function as caches is described here, the number of memory arrays may be one, two, or four or more.

In the case where the memory array 920L1 is used as a cache, the driver circuit 910L1 may function as part of the cache interface 969i or the driver circuit 910L1 may be connected to the cache interface 969i. Similarly, each of the driver circuits 910L2 and 910L3 may function as part of the cache interface 969i or be connected thereto.

Whether the memory array 920 functions as the cache or the main memory is determined by the control circuit 912 included in each of the driver circuits 910. The control circuit 912 can make some of the memory cells 950 in the semiconductor device 900 function as RAM in accordance with a signal supplied from the arithmetic device 960.

In the semiconductor device 900, some of the memory cells 950 can function as the cache and the other memory cells 950 can function as the main memory. That is, the semiconductor device 900 can have both the function of the cache and the function of the main memory. The semiconductor device 900 of one embodiment of the present invention can function as a universal memory, for example.

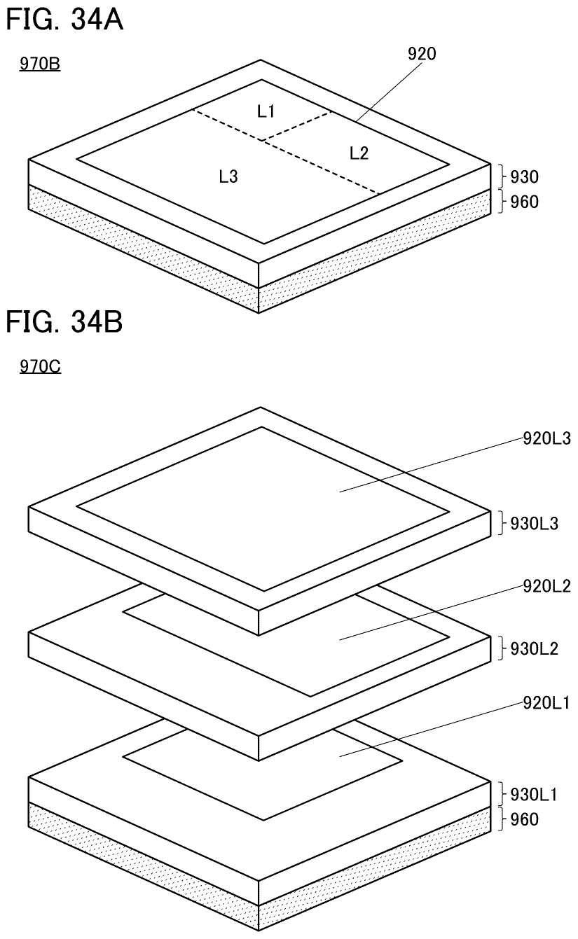

The layer 930 including one memory array 920 may be provided to overlap with the arithmetic device 960. FIG. 34A is a perspective view of a semiconductor device 970B.

In the semiconductor device 970B, one memory array 920 can be divided into a plurality of areas having different functions. FIG. 34A illustrates an example in which a region L1, a region L2, and a region L3 are used as the L1 cache, the L2 cache, and the L3 cache, respectively.

In the semiconductor device 970B, the capacity of each of the regions L1 to L3 can be changed depending on circumstances. For example, the capacity of the L1 cache can be increased by increasing the area of the region L1. With such a structure, the arithmetic processing efficiency can be improved and the processing speed can be improved.

Alternatively, a plurality of memory arrays may be stacked. FIG. 34B is a perspective view of a semiconductor device 970C.

In the semiconductor device 970C, a layer 930L1 including the memory array 920L1, a layer 930L2 including the memory array 920L2 over the layer 930L1, and a layer 930L3 including the memory array 920L3 over the layer 930L2 are stacked. The memory array 920L1 physically closest to the arithmetic device 960 can be used as a high-level cache, and the memory array 920L3 physically farthest from the arithmetic device 960 can be used as a low-level cache or a main memory. Such a structure can increase the capacity of each memory array, leading to higher processing capability.

This embodiment can be combined with any of the other embodiments or Example as appropriate. In this specification, in the case where a plurality of structure examples are shown in one embodiment, the structure examples can be combined as appropriate.

### Embodiment 4

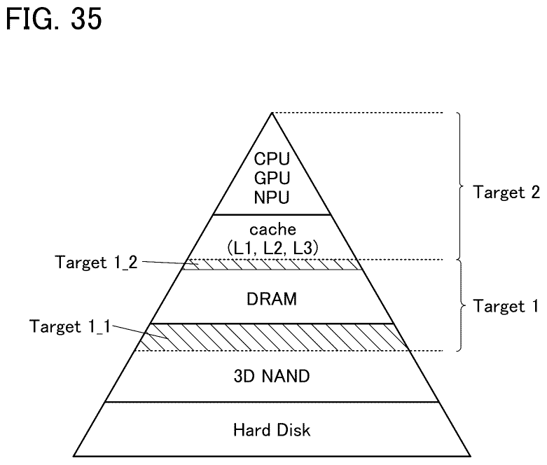

In this embodiment, an example of an application range of a semiconductor device of one embodiment of the present invention is described with reference to FIG. 35. A memory device of one embodiment of the present invention includes a transistor including an oxide as a semiconductor (hereinafter, referred to as an OS transistor in some cases) and a capacitor. Since the OS transistor has an extremely low off-state current, the memory device including the OS transistor has excellent retention characteristics and can function as a nonvolatile memory.

A variety of memory devices are used in semiconductor devices such as computers in accordance with the intended use. FIG. 35 is a conceptual diagram showing a hierarchy of memory devices used in semiconductor devices. In the conceptual diagram in FIG. 35, the hierarchy of memory devices is shown by a triangle; the memory devices at higher levels in the triangle require higher operation speed, and the memory devices at lower levels in the triangle require higher memory capacity and higher recording density.

In FIG. 35, memories included as registers in arithmetic processing devices such as a CPU, a GPU, and an NPU, cache memories (sometimes simply referred to as caches, typically L1, L2, and L3 caches), main memories typified by DRAMs, 3D NANDs, and storage memories typified by hard disks (also referred to as hard disk drives (HDDs)) are shown in this order from the highest level in the triangle.

A memory included as a register in an arithmetic processing device such as a CPU, a GPU, or an NPU is used for temporary storage of arithmetic operation results, for example, and thus is very frequently accessed by the arithmetic processing device. Accordingly, high operation speed is required rather than high memory capacity. The register also has a function of retaining settings of the arithmetic processing device, for example.

The cache memory has a function of duplicating and retaining part of data retained in the DRAM. Duplicating frequently used data and retaining the duplicated data in the cache memory facilitates rapid data access. The cache memory requires lower memory capacity but requires higher operation speed than the DRAM. Data that is rewritten in the cache memory is duplicated, and the duplicated data is supplied to the DRAM.

The memory device of one embodiment of the present invention can be used as a DRAM.

Only L1 to L3 caches are shown as the cache memories in the example illustrated FIG. 35, but one embodiment of the present invention is not limited to the example. For example, a memory device of one embodiment of the present invention can be used as the last level cache (LLC) or a final level cache (FLC) positioned at the lowest level among the caches.

The DRAM has a function of retaining a program, data, or the like read from the 3D NAND.

The 3D NAND has a function of retaining data that needs to be stored for a long time, a variety of programs used in an arithmetic device (e.g., a model of an artificial neural network), and the like. Therefore, the 3D NAND requires high memory capacity and high recording density rather than high operating speed.

The hard disk has high capacity and a nonvolatile function. Instead of the hard disk, a solid state drive (SSD) or the like can be used.

When the memory device of one embodiment of the present invention uses an OS transistor, the memory device and a peripheral circuit can form a monolithic structure. Furthermore, with the use of an OS transistor, the memory device can be monolithically stacked over a peripheral circuit. Thus, the memory device has an advantage in terms of data access to the peripheral circuit. Furthermore, since the memory device can be provided to be stacked over the peripheral circuit, the integration degree can be increased. The memory device of one embodiment of the present invention can retain data for a long time by using an OS transistor. Thus, in the case of using the memory device as a DRAM, a reduction of the refresh frequency is possible.

In the memory device of one embodiment of the present invention, the use of an OS transistor can reduce the leakage current. Accordingly, the capacitor can sufficiently retain data even when having a small capacitance value, for example. Thus, for example, when the memory device of one embodiment of the present invention is used as a DRAM, the operation speed of the DRAM, e.g., the speed in rewriting, is increased in some cases.

The memory device of one embodiment of the present invention can retain data for a long time by including a capacitor including a ferroelectric. Thus, in the case of using the memory device as a DRAM, the refresh frequency can be reduced. Furthermore, the reliability of the memory device can be increased.

The memory device of one embodiment of the present invention can be used for the region of Target 2 and the region of Target 1 illustrated in FIG. 35. The memory device is especially suitable for the region of Target 1.

As indicated by the hatching of oblique lines in FIG. 35, Target 1 includes a boundary region (Target 1_1) between the DRAM and the 3D NAND and a boundary region (Target 1_2) between the DRAM and the cache (L1, L2, and L3). Examples of the Target 1_2 include the above-described LLC and FLC.

When the memory device of one embodiment of the present invention is used as a DRAM, power consumption can be reduced. With this structure, power consumption can be reduced to less than or equal to a half, preferably less than or equal to a tenth, further preferably less than or equal to a hundredth, still further preferably less than or equal to a thousandth of the power consumption of a structure including a conventional DRAM. Thus, the memory device of one embodiment of the present invention can be suitably used for Target 1.

The memory device of one embodiment of the present invention can retain data for a long time and has an advantage in terms of data access. Thus, the memory device of one embodiment of the present invention is especially suitable for Target 1_1, which is a region with a relatively low rewrite frequency in Target 1. When the memory device of one embodiment of the present invention is used for Target 1_1, the reliability of the memory device can be increased. In addition, the integration degree of the memory device is increased in some cases. Furthermore, the power consumption of the memory device is reduced in some cases.

In addition, the memory device of one embodiment of the present invention operates at high speed and has an advantage in terms of data access; thus, the memory device is also suitable for Target 1_2 having a higher rewrite frequency in Target 1. The use of the memory device of one embodiment of the present invention for Target 1_2 can increase the computational efficiency of the memory device and reduce power consumption thereof.

Another means of reducing power consumption is a structure in which a memory device such as a DRAM or an FeRAM (including the semiconductor device of one embodiment of the present invention) is stacked over an arithmetic processing device such as a CPU, a GPU, or an NPU. A structure in which an arithmetic processing device and a memory device are stacked is referred to as monolithic stacking. The monolithically stacked structure of the arithmetic processing device and the memory device can significantly reduce power consumption required for data access between the arithmetic processing device and the memory device, for example. Thus, global expansion of information processing devices, such as supercomputers (also referred to as a high performance computers (HPCs)), computers, and servers, having such a structure will greatly contribute to global warming mitigation.

As described above, the memory device including the oxide semiconductor of one embodiment of the present invention can be applied to a wide range of memories covering from a memory included as a register in an arithmetic processing device such as a CPU, a GPU, or an NPU to a memory in the boundary region between a DRAM and a 3D NAND.

This embodiment can be combined with the other embodiments or Example as appropriate. In this specification, in the case where a plurality of structure examples are shown in one embodiment, the structure examples can be combined as appropriate.

### Embodiment 5

In this embodiment, a display device of one embodiment of the present invention will be described.

The semiconductor device of one embodiment of the present invention can be used for a display device or a module including the display device. Examples of the module including the display device include a module in which a connector such as a flexible printed circuit board (hereinafter, referred to as an FPC) or a tape carrier package (TCP) is attached to the display device and a module in which the display device is mounted with an integrated circuit (IC) by a chip on glass (COG) method, a chip on film (COF) method, or the like.

### [Display Module]

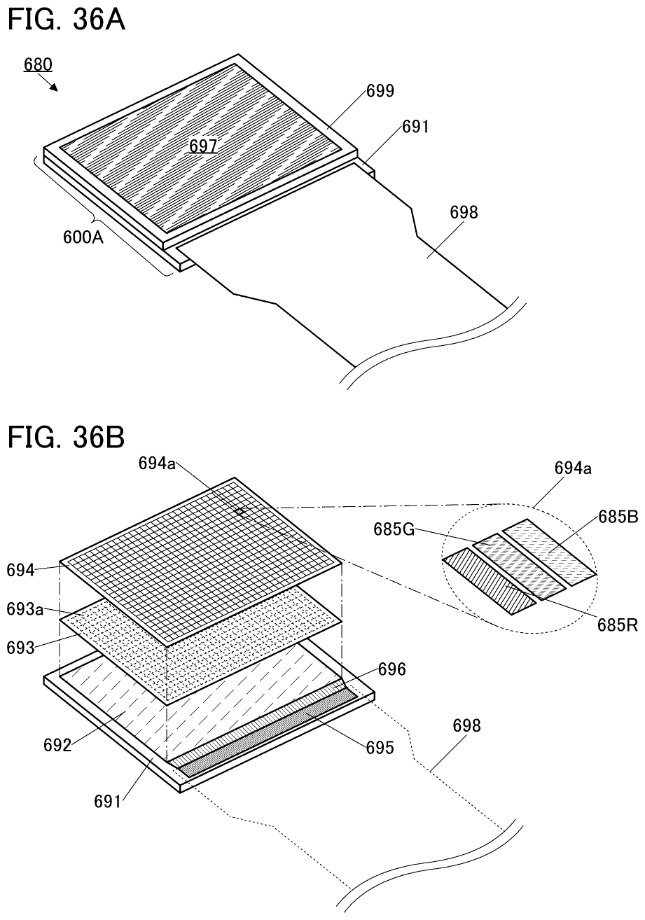

FIG. 36A is a perspective view of a display module 680. The display module 680 includes a display device 600A and an FPC 698. Note that the display device included in the display module 680 is not limited to the display device 600A and may be a display device 600B described later.

The display module 680 includes a substrate 691 and a substrate 699. The display module 680 includes a display portion 697. The display portion 697 is a region of the display module 680 where an image is displayed, and is a region where light emitted from pixels provided in a pixel portion 694 described later can be seen.

FIG. 36B is a perspective view schematically illustrating the structure on the substrate 691 side. Over the substrate 691, a circuit portion 692, a pixel circuit portion 693 over the circuit portion 692, and the pixel portion 694 over the pixel circuit portion 693 are stacked. In addition, a terminal portion 695 for connection to the FPC 698 is included in a portion over the substrate 691 that does not overlap with the pixel portion 694. The terminal portion 695 and the circuit portion 692 are connected to each other through a wiring portion 696 formed of a plurality of wirings.

The semiconductor device of one embodiment of the present invention can be used for one or both of the circuit portion 692 and the pixel circuit portion 693.

The pixel portion 694 includes a plurality of pixels 694a arranged periodically. An enlarged view of one pixel 694a is illustrated on the right side in FIG. 36B. FIG. 36B illustrates an example in which one pixel 694a includes a subpixel 685R emitting red light, a subpixel 685G emitting green light, and a subpixel 685B emitting blue light.

The subpixel includes a display element. Any of a variety of elements can be used as the display element, and a liquid crystal element or a light-emitting element can be used, for example. Alternatively, a micro electro mechanical systems (MEMS) shutter element, an optical interference type MEMS element, or a display element using a microcapsule method, an electrophoretic method, an electrowetting method, an Electronic Liquid Powder (registered trademark) method, or the like can be used. Alternatively, a quantum-dot LED (QLED) employing a light source and color conversion technology using quantum dot materials may be used.

As the light-emitting element, for example, a self-luminous light-emitting element such as a light-emitting diode (LED), an organic LED (OLED), or a semiconductor laser can be used. Examples of the LED include a mini LED and a micro LED.

There is no particular limitation on the arrangement of pixels in the display device of one embodiment of the present invention, and a variety of arrangements can be employed. Examples of the arrangement of pixels include stripe arrangement, S-stripe arrangement, matrix arrangement, delta arrangement, Bayer arrangement, and PenTile arrangement. FIG. 36B illustrates an example in which stripe arrangement is employed as the pixel arrangement.

The pixel circuit portion 693 includes a plurality of pixel circuits 693a arranged periodically.

One pixel circuit 693a is a circuit that controls driving of a plurality of elements included in one pixel 694a. One pixel circuit 693a can be provided with three circuits each of which controls light emission of one light-emitting element. For example, the pixel circuit 693a can include at least one selection transistor, one current control transistor (driving transistor), and a capacitor for one light-emitting element. In that case, a gate signal is input to a gate of the selection transistor, and a source signal is input to a source of the selection transistor. With such a structure, an active-matrix display device is achieved.

The circuit portion 692 includes a circuit for driving the pixel circuits 693a in the pixel circuit portion 693. For example, one or both of a gate line driver circuit and a source line driver circuit are preferably included. The circuit portion 692 may also include at least one of an arithmetic circuit, a memory circuit, a power supply circuit, and the like.

The FPC 698 functions as a wiring for supplying a video signal, a power supply potential, or the like to the circuit portion 692 from the outside. An IC may be mounted on the FPC 698.

The display module 680 can have a structure in which one or both of the pixel circuit portion 693 and the circuit portion 692 are stacked below the pixel portion 694; thus, the aperture ratio (the effective display area ratio) of the display portion 697 can be significantly high. Furthermore, the pixels 694a can be arranged extremely densely and thus the display portion 697 can have an extremely high resolution.

Such a display module 680 has an extremely high resolution, and thus is suitable for a device for virtual reality (VR) such as a head-mounted display (HMD) or a glasses-type device for augmented reality (AR). For example, even in the case of a structure in which the display portion of the display module 680 is seen through a lens, pixels of the extremely-high-resolution display portion 697 included in the display module 680 are prevented from being seen when the display portion is enlarged by the lens, so that display providing a high level of immersion can be performed. Without being limited thereto, the display module 680 is suitable for electronic devices including a relatively small display portion. For example, the display module 680 is suitable for a display portion of a wearable electronic device, such as a wrist watch.

In this specification and the like, a device formed using a metal mask or a fine metal mask (FMM or high-resolution metal mask) may be referred to as a device having a metal mask (MM) structure. In this specification and the like, a device formed without using a metal mask or an FMM may be referred to as a device having a metal maskless (MML) structure.

### Structure Example 1 of Display Device

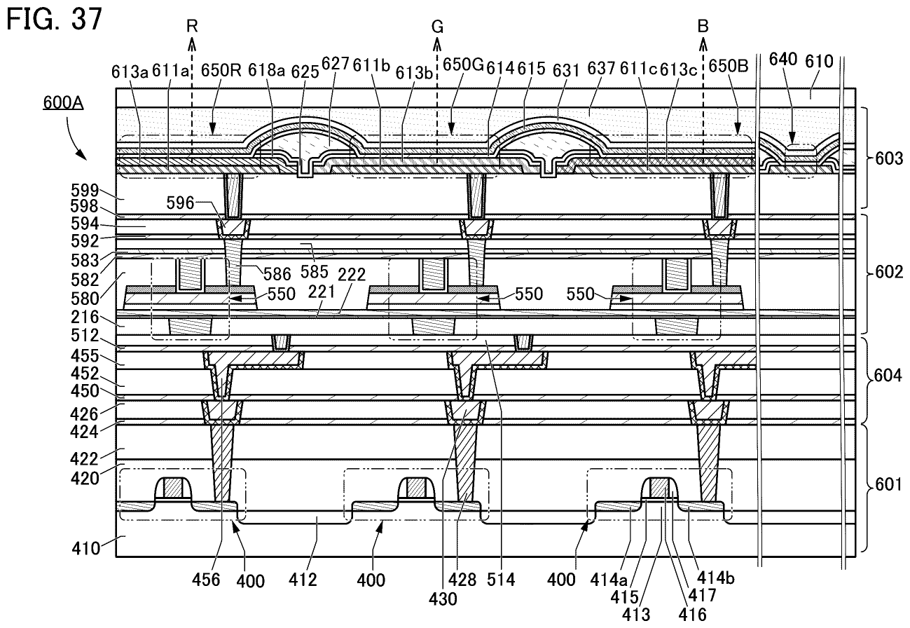

FIG. 37 is a cross-sectional view of the display device 600A. The display device 600A is an example of a display device having a metal maskless (MML) structure.

An island-shaped light-emitting layer of the light-emitting element included in the display device having the MML structure is formed in the following manner: a light-emitting layer is formed on the entire surface and then the light-emitting layer is processed by a photolithography method. Accordingly, a high-resolution display device or a display device with a high aperture ratio, which has been difficult to achieve so far, can be obtained. Moreover, light-emitting layers can be formed separately for the respective colors, enabling the display device to perform extremely clear display with high contrast and high display quality. For example, in the case where the display device includes three kinds of light-emitting elements, which are a light-emitting element emitting blue light, a light-emitting element emitting green light, and a light-emitting element emitting red light, three kinds of island-shaped light-emitting layers can be formed by repeating formation of a light-emitting layer and processing by photolithography three times.

A device having the MML structure can be manufactured without using a metal mask, and thus can break through the resolution limit due to alignment accuracy of the metal mask. Furthermore, manufacturing a device without using a metal mask can eliminate the need for the manufacturing equipment of a metal mask and the cleaning step of the metal mask. For processing by photolithography, an apparatus that is the same as or similar to an apparatus used for manufacturing a transistor can be used; thus, there is no need to introduce a special apparatus to manufacture the device having the MML structure. The MML structure can reduce the manufacturing cost as described above, and thus is suitable for mass production of devices.

A display device having the MML structure does not require a pseudo improvement in resolution by employing unique pixel arrangement such as PenTile arrangement, for example; thus, the display device can achieve a high resolution (e.g., higher than or equal to 500 ppi, higher than or equal to 1000 ppi, higher than or equal to 2000 ppi, higher than or equal to 3000 ppi, or higher than or equal to 5000 ppi) while having what is called stripe arrangement where R, G, and B subpixels are arranged in one direction.

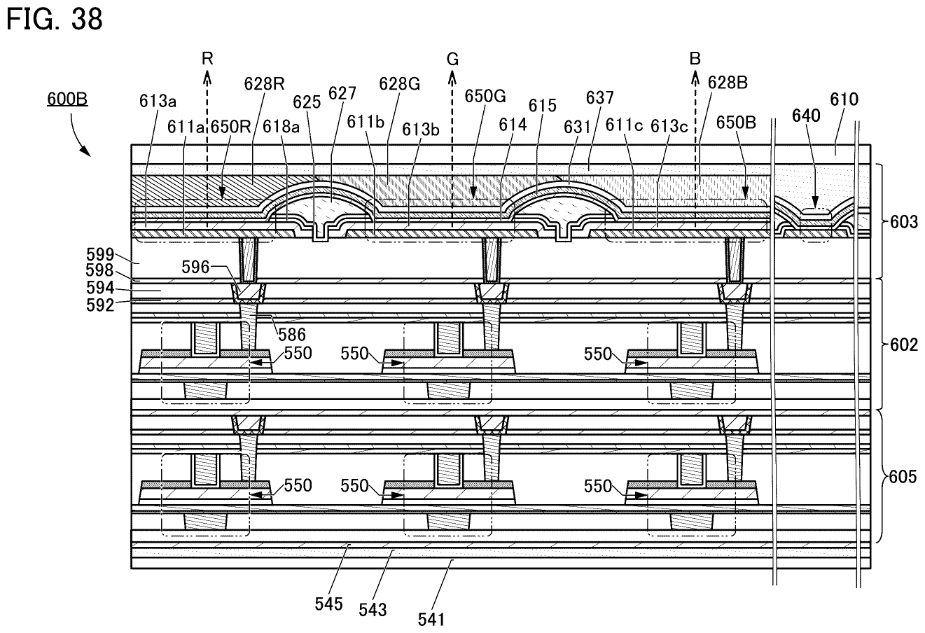

Providing a sacrificial layer over the light-emitting layer can reduce damage to the light-emitting layer in the fabrication process of the display device, resulting in an increase in reliability of the light-emitting element. Note that the sacrificial layer may remain in the completed display device or may be removed in the fabrication process. For example, a sacrificial layer 618a illustrated in FIG. 37 and FIG. 38 is part of the sacrificial layer provided over the light-emitting layer.

Employing a film formation step using an area mask and a processing step using a resist mask enables a light-emitting element to be fabricated by a relatively easy process.

FIG. 37 is a schematic cross-sectional view of the display device 600A that is a display device (a semiconductor device) of one embodiment of the present invention. The display device 600A is provided with a pixel circuit, a driver circuit, and the like over a substrate 410. In the display device 600A in FIG. 37, a wiring layer 604 is illustrated in addition to an element layer 601, an element layer 602, and an element layer 603. The wiring layer 604 is a layer provided with a wiring.

The pixel circuit of the display device is preferably provided in the element layer 602. The driver circuit (one or both of a gate driver and a source driver) of the display device is preferably provided in the element layer 601. One or more of a variety of circuits such as an arithmetic circuit and a memory circuit may be provided in the element layer 601.

For example, the element layer 601 includes the substrate 410 on which a transistor 400 is formed. The wiring layer 604 is provided above the transistor 400, and a wiring for connecting the transistor 400 to a conductive layer, a transistor, or the like provided in the element layer 602 is provided in the wiring layer 604. The element layers 602 and 603 are provided above the wiring layer 604, and the element layer 602 includes a transistor 550 and the like, for example. The element layer 603 includes a light-emitting element (a light-emitting element 650R, a light-emitting element 650G, and a light-emitting element 650B in FIG. 37) and the like.

The transistor 400 is an example of a transistor included in the element layer 601. The transistor 550 is an example of a transistor included in the element layer 602. The light-emitting element (the light-emitting elements 650R, 650G, and 650B) is an example of a light-emitting element included in the element layer 603.

As the substrate 410, a semiconductor substrate (e.g., a single crystal substrate formed of silicon or germanium) can be used, for example. Besides such a semiconductor substrate, any of the following can be used as the substrate 410: an SOI substrate, a glass substrate, a quartz substrate, a plastic substrate, a sapphire glass substrate, a metal substrate, a stainless steel substrate, a substrate including stainless steel foil, a tungsten substrate, a substrate including tungsten foil, a flexible substrate, an attachment film, and paper and a base film each including a fibrous material. As the substrate 410, a structure body in which a single crystal oxide semiconductor film (typically, indium oxide film) is provided over a stabilized zirconia substrate can also be used. In the description of this embodiment, the substrate 410 is a semiconductor substrate containing silicon as a material. Thus, a transistor included in the element layer 601 can be a Si transistor.

The transistor 400 includes an element isolation layer 412, a conductive layer 416, an insulating layer 415, an insulating layer 417, a semiconductor region 413 that is part of the substrate 410, a low-resistance region 414a, and a low-resistance region 414b. Although FIG. 37 illustrates the structure in which one of a source and a drain of the transistor 400 is connected to the conductive layer (not illustrated) provided in the element layer 602 through a conductive layer 428, a conductive layer 430, and a conductive layer 456, the connection structure of the display device of one embodiment of the present invention is not limited thereto. For example, one of the source and the drain of the transistor 400 may be connected to one of a source and a drain of the transistor 550 through the conductive layer 428, the conductive layer 430, the conductive layer 456, and the like.

The transistor 400 can have a fin-type structure when, for example, the top surface of the semiconductor region 413 and the side surface thereof in the channel width direction are covered with the conductive layer 416 functioning as a gate electrode with the insulating layer 415 functioning as a gate insulating layer therebetween. The effective channel width can be increased in the fin-type transistor 400, so that the on-state characteristics of the transistor 400 can be improved. In addition, contribution of the electric field of the gate electrode can be increased, so that the off-state characteristics of the transistor 400 can be improved. The transistor 400 may have a planar structure instead of a fin-type structure.

Note that the transistor 400 may be either a p-channel transistor or an n-channel transistor. Alternatively, a plurality of transistors 400 may be provided and both the p-channel transistor and the n-channel transistor may be used.

Over the transistor 400 illustrated in FIG. 37, an insulating layer 420 and an insulating layer 422 are stacked in this order. In addition, the conductive layer 428 is embedded in the insulating layer 420 and the insulating layer 422.

In the display device 600A, the wiring layer 604 is provided over the transistor 400. In FIG. 37, an insulating layer 424, an insulating layer 426, an insulating layer 450, an insulating layer 452, and an insulating layer 455 are stacked in this order. Furthermore, the conductive layer 430 is embedded in the insulating layer 424 and the insulating layer 426, and the conductive layer 456 is embedded in the insulating layer 450, the insulating layer 452, and the insulating layer 455.

An insulating layer 512 and an insulating layer 514 are stacked in this order above the insulating layer 455 and the conductive layer 456. A conductive layer functioning as a plug or a wiring is embedded in the insulating layer 512 and the insulating layer 514. Thus, the transistor 400 can be connected to a conductive layer (not illustrated) provided in the element layer 602. Alternatively, one of the source and the drain of the transistor 550 and one of the source and the drain of the transistor 400 may be connected to each other.

The transistor 550 is provided over the insulating layer 514. The semiconductor device (the transistor 200, the transistor 200A, or the transistor 200B) described in Embodiment 2 can be used as the transistor 550. FIG. 37 illustrates an example in which the transistor 200A described in Embodiment 2 is used as the transistor 550.

An insulating layer 580, an insulating layer 582, an insulating layer 583, an insulating layer 585, an insulating layer 592, an insulating layer 594, an insulating layer 598, and an insulating layer 599 are stacked in this order over the transistor 550. A conductive layer 586 is embedded in the insulating layer 580, the insulating layer 582, the insulating layer 583, and the insulating layer 585, and a conductive layer 596 is embedded in the insulating layer 592 and the insulating layer 594. The conductive layer 586 is in contact with the conductive layer 242a or the conductive layer 242b. The conductive layer 586 and the conductive layer 596 are connected to a light-emitting element or the like.

The insulating layer 420, the insulating layer 422, the insulating layer 426, the insulating layer 452, the insulating layer 455, the insulating layer 514, the insulating layer 580, the insulating layer 282, the insulating layer 585, the insulating layer 594, and the insulating layer 599 function as interlayer films. As the interlayer insulating films, insulating layers with relatively low relative permittivities are preferably used. For example, one or more selected from silicon oxide, silicon oxynitride, silicon nitride oxide, silicon nitride, aluminum oxide, aluminum oxynitride, aluminum nitride oxide, and aluminum nitride can be used. A resin can be used, for example. Thus, parasitic capacitance generated between wirings can be reduced. The concentration of impurities such as water and hydrogen in the interlayer insulating films is preferably reduced.

The interlayer insulating film may function as a planarization film that covers roughness due to an underlying layer. For example, the top surface of the insulating layer 422 may be planarized by planarization treatment using a CMP method or the like to improve the flatness.

For each of the insulating layer 424, the insulating layer 450, the insulating layer 512, the insulating layer 583, the insulating layer 592, and the insulating layer 598, an insulating film having a barrier property against at least one of hydrogen, oxygen, and water (also referred to as a barrier insulating film) is preferably used. For example, one or more selected from aluminum oxide and silicon nitride can be used.

The conductive layer 428, the conductive layer 430, the conductive layer 456, the conductive layer 586, and the conductive layer 596 each function as a plug or a wiring. Here, a plurality of conductive layers functioning as plugs or wirings are collectively denoted by the same reference numeral in some cases. In this specification and the like, a wiring and a plug connected to the wiring may be a single component. That is, in some cases, part of a conductive layer functions as a wiring or part of a conductive layer functions as a plug.

As a material for each of the conductive layers functioning as plugs or wirings, one or more conductive materials selected from a metal material, an alloy material, a metal nitride material, and a metal oxide material can be used in a single-layer structure or a stacked-layer structure. It is preferable to use a high-melting-point material that has both heat resistance and conductivity, such as tungsten or molybdenum, and it is particularly preferable to use tungsten. A low-resistance conductive material such as aluminum or copper is preferably used. The use of a low-resistance conductive material can reduce wiring resistance. Alternatively, a conductive material having a barrier property against at least one of hydrogen, oxygen, and water is preferably used. For example, tantalum nitride is preferably used. The use of a stack including tantalum nitride and tungsten, which has high conductivity, can inhibit diffusion of hydrogen while the conductive layer maintains the conductivity as a wiring.

The light-emitting elements and a connection portion 640 are formed over the insulating layer 599.

The connection portion 640 is referred to as a cathode contact portion in some cases, and is connected to cathodes of the light-emitting elements 650R, 650G, and 650B. In the connection portion 640 illustrated in FIG. 37, a conductive layer formed using the same material in the same step as a conductive layer 611a, a conductive layer 611b, and a conductive layer 611c is connected to a common electrode 615 described later. Although FIG. 37 illustrates an example in which the conductive layer is connected to the common electrode 615 through a common layer 614 described later, the conductive layer and the common electrode 615 may be in direct contact with each other.

Note that the connection portion 640 may be provided to surround four sides of the display portion in a plan view or may be provided in the display portion (e.g., between adjacent light-emitting elements) (not illustrated).

The light-emitting element 650R includes the conductive layer 611a as a pixel electrode. Similarly, the light-emitting element 650G includes the conductive layer 611b as a pixel electrode, and the light-emitting element 650B includes the conductive layer 611c as a pixel electrode.

The conductive layers 611a to 611c are connected to the conductive layer 596 embedded in the insulating layer 594 through a conductive layer (plug) embedded in the insulating layer 599.

The light-emitting element 650R includes a layer 613a, the common layer 614 over the layer 613a, and the common electrode 615 over the common layer 614. The light-emitting element 650G includes a layer 613b, the common layer 614 over the layer 613b, and the common electrode 615 over the common layer 614. The light-emitting element 650B includes a layer 613c, the common layer 614 over the layer 613c, and the common electrode 615 over the common layer 614.

For the pair of electrodes (the pixel electrode and the common electrode) of the light-emitting element, a metal, an alloy, an electrically conductive compound, a mixture thereof, and the like can be used as appropriate. Specific examples of the material include metals such as aluminum, magnesium, titanium, chromium, manganese, iron, cobalt, nickel, copper, gallium, zinc, indium, tin, molybdenum, tantalum, tungsten, palladium, gold, platinum, silver, yttrium, and neodymium, and an alloy containing any of these metals in appropriate combination. Other examples of the material include ITO, ITSO, In—Zn oxide, and In—W—Zn oxide. Other examples of the material include an alloy containing aluminum (aluminum alloy), such as an alloy of aluminum, nickel, and lanthanum (Al—Ni—La), and an alloy containing silver, such as an alloy of silver and magnesium and an alloy of silver, palladium, and copper (also referred to as Ag—Pd—Cu or APC). Other examples of the material include an element belonging to Group 1 or Group 2 of the periodic table that is not described above (e.g., lithium, cesium, calcium, or strontium), a rare earth metal such as europium or ytterbium, an alloy containing an appropriate combination of any of these elements, and graphene.

The display device 600A employs an SBS structure.

Note that the layer 613a is formed to cover the top and side surfaces of the conductive layer 611a. Similarly, the layer 613b is formed to cover the top and side surfaces of the conductive layer 611b. Similarly, the layer 613c is formed to cover the top and side surfaces of the conductive layer 611c. Accordingly, regions provided with the conductive layers 611a, 611b, and 611c can be entirely used as the light-emitting regions of the light-emitting elements 650R, 650G, and 650B, thereby increasing the aperture ratio of the pixels.

In the light-emitting element 650R, the layer 613a and the common layer 614 can be collectively referred to as an EL layer. Similarly, in the light-emitting element 650G, the layer 613b and the common layer 614 can be collectively referred to as an EL layer. Similarly, in the light-emitting element 650B, the layer 613c and the common layer 614 can be collectively referred to as an EL layer.

The EL layer includes at least a light-emitting layer. The light-emitting layer contains one or more kinds of light-emitting substances. As the light-emitting substance, a substance emitting light of blue, violet, bluish violet, green, yellowish green, yellow, orange, red, or the like is used as appropriate. As the light-emitting substance, a substance emitting near-infrared light can also be used.

Examples of a light-emitting substance contained in the light-emitting element include a substance emitting fluorescent light (a fluorescent material), a substance emitting phosphorescent light (a phosphorescent material), a substance exhibiting thermally activated delayed fluorescence (a thermally activated delayed fluorescent (TADF) material), and an inorganic compound (e.g., a quantum dot material).

The light-emitting layer may contain one or more kinds of organic compounds (e.g., a host material or an assist material) in addition to the light-emitting substance (a guest material). As one or more kinds of organic compounds, one or both of a substance with a high hole-transport property (a hole-transport material) and a substance with a high electron-transport property (an electron-transport material) can be used. As the one or more kinds of organic compounds, a substance with a bipolar property (a substance with a high electron-transport property and a high hole-transport property) or a TADF material may be used.

In addition to the light-emitting layer, the EL layer can include one or more of a layer containing a substance having a high hole-injection property (a hole-injection layer), a layer containing a hole-transport material (a hole-transport layer), a layer containing a substance having a high electron-blocking property (an electron-blocking layer), a layer containing a substance having a high electron-injection property (an electron-injection layer), a layer containing an electron-transport material (an electron-transport layer), and a layer containing a substance having a high hole-blocking property (a hole-blocking layer). The EL layer may further contain one or both of a bipolar substance and a TADF material.

Either a low molecular compound or a high molecular compound can be used in the light-emitting element, and an inorganic compound may also be included. Each layer included in the light-emitting element can be formed by any of the following methods: an evaporation method (including a vacuum evaporation method), a transfer method, a printing method, an inkjet method, a coating method, and the like.

The light-emitting element may employ a single structure (a structure including only one light-emitting unit) or a tandem structure (a structure including a plurality of light-emitting units). The light-emitting unit includes at least one light-emitting layer. In a tandem structure, a plurality of light-emitting units are connected in series with a charge-generation layer therebetween. The charge-generation layer has a function of injecting electrons into one of two light-emitting units and injecting holes to the other when voltage is applied between the pair of electrodes. The tandem structure enables a light-emitting element to emit light at high luminance. Furthermore, the amount of current needed for obtaining a predetermined luminance can be smaller in the tandem structure than in the single structure; thus, the tandem structure enables higher reliability. The tandem structure can also be referred to as a stack structure.

When the light-emitting element has a microcavity structure, higher color purity can be achieved.

The layers 613a to 613c are each processed into an island shape by a photolithography method. At each of end portions of the layers 613a to 613c, an angle between the top surface and the side surface is approximately 90°. By contrast, an organic film formed using an FMM has a thickness that tends to gradually decrease with decreasing distance to an end portion, and has a top surface forming a slope in an area extending greater than or equal to 1 μm and less than or equal to 10 μm from the end portion, for example; thus, such an organic film has a shape whose top surface and side surface cannot be easily distinguished from each other.

The top and side surfaces of each of the layers 613a to 613c are clearly distinguished from each other. Accordingly, as for the layers 613a and 613b which are adjacent to each other, one of the side surfaces of the layer 613a and one of the side surfaces of the layer 613b face each other. The same applies to a combination of any two of the layers 613a to 613c.

The layers 613a to 613c each include at least a light-emitting layer. Preferably, the layer 613a, the layer 613b, and the layer 613c include a light-emitting layer emitting red (R) light, a light-emitting layer emitting green (G) light, and a light-emitting layer emitting blue (B) light, respectively, for example. Other than the above colors, cyan, magenta, yellow, or white can be employed as colors of light emitted from the light-emitting layers.

The layers 613a to 613c each preferably include a light-emitting layer and a carrier-transport layer (an electron-transport layer or a hole-transport layer) over the light-emitting layer. Since the surfaces of the layers 613a to 613c are exposed in the fabrication process of the display device in some cases, providing the carrier-transport layer over the light-emitting layer inhibits the light-emitting layer from being exposed on the outermost surface, so that damage to the light-emitting layer can be reduced. Thus, the reliability of the light-emitting element can be increased.

The common layer 614 includes, for example, an electron-injection layer or a hole-injection layer. Alternatively, the common layer 614 may be a stack of an electron-transport layer and an electron-injection layer, or may be a stack of a hole-transport layer and a hole-injection layer. The common layer 614 is shared by the light-emitting elements 650R, 650G, and 650B. Note that the common layer 614 is not necessarily provided, and the whole EL layer included in the light-emitting element may be provided in an island shape like the layers 613a to 613c.

The common electrode 615 is shared by the light-emitting elements 650R, 650G, and 650B. As illustrated in FIG. 37, the common electrode 615 shared by the plurality of light-emitting elements is connected to the conductive layer included in the connection portion 640.

An insulating layer 625 preferably has a function of a barrier insulating layer against at least one of water and oxygen. This can inhibit entry of impurities (typically, one or both of water and oxygen) that would diffuse into the light-emitting elements from the outside. With this structure, a highly reliable light-emitting element and a highly reliable display device can be provided.

As the insulating layer 625, the above-described barrier insulating layer against oxygen can be used, and aluminum oxide or silicon nitride is preferably used.

The insulating layer 625 preferably has a low impurity concentration. Accordingly, degradation of the EL layer, which is caused by entry of impurities into the EL layer from the insulating layer 625, can be inhibited. In addition, when the impurity concentration is reduced in the insulating layer 625, a barrier property against at least one of water and oxygen can be increased. For example, the insulating layer 625 preferably has a sufficiently low hydrogen concentration or a sufficiently low carbon concentration, and further preferably has both a sufficiently low hydrogen concentration and a sufficiently low carbon concentration.

As an insulating layer 627, an insulating layer containing an organic material can be suitably used. As the organic material, a photosensitive resin is preferably used, and for example, a photosensitive resin composite containing an acrylic resin can be used. In this specification and the like, an acrylic resin refers not only to a polymethacrylic acid ester or a methacrylic resin, but also to all the acrylic polymer in a broad sense in some cases.

An organic material that can be used for the insulating layer 627 is not limited to the above. For example, for the insulating layer 627, an acrylic resin, a polyimide resin, an epoxy resin, a polyamide resin, a polyimide-amide resin, a silicone resin, a siloxane resin, a benzocyclobutene-based resin, a phenol resin, or precursors of these resins can be used in some cases. An organic material such as polyvinyl alcohol (PVA), polyvinylbutyral (PVB), polyvinylpyrrolidone, polyethylene glycol, polyglycerin, pullulan, water-soluble cellulose, or an alcohol-soluble polyamide resin can be used for the insulating layer 627 in some cases. A photoresist, which is a photosensitive resin, can be used for the insulating layer 627 in some cases. Examples of the photosensitive resin include positive-type materials and negative-type materials.

The insulating layer 627 may be formed using a material absorbing visible light. When the insulating layer 627 absorbs light emitted from the light-emitting element, light leakage (stray light) from the light-emitting element to an adjacent light-emitting element through the insulating layer 627 can be suppressed. Thus, the display quality of the display device can be improved. Since no polarizing plate is required to improve the display quality of the display device, the weight and thickness of the display device can be reduced.

Examples of the material absorbing visible light include materials containing pigment of black or the like, materials containing dye, light-absorbing resin materials (e.g., polyimide), and resin materials that can be used for color filters (color filter materials). Using a resin material obtained by stacking or mixing color filter materials of two or three or more colors is particularly preferable to enhance the effect of blocking visible light. In particular, mixing color filter materials of three or more colors enables the formation of a black or nearly black resin layer.

Note that the side surface of the insulating layer 627 preferably has a tapered shape. When the end portion of the side surface of the insulating layer 627 has a forward tapered shape (with an angle less than 90°, preferably less than or equal to 60°, further preferably less than or equal to) 45°, the common layer 614 and the common electrode 615 that are provided over the end portion of the side surface of the insulating layer 627 can be formed with good coverage without disconnection, local thinning, or the like. Consequently, the in-plane uniformity of the common layer 614 and the common electrode 615 can be increased, so that the display quality of the display device can be improved.

In a cross-sectional view of the display device, the top surface of the insulating layer 627 preferably has a convex shape. The convex top surface of the insulating layer 627 preferably has a shape that expands gradually toward the center. When the insulating layer 627 has such a shape, the common layer 614 and the common electrode 615 can be formed with good coverage over the whole insulating layer 627.

The insulating layer 627 is formed in a region between two EL layers (e.g., a region between the layers 613a and 613b). In that case, part of the insulating layer 627 is positioned between the end portion of the side surface of one of the two EL layers (e.g., the layer 613a) and the end portion of the side surface of the other of the two EL layers (e.g., the layer 613b).

It is preferable that one end portion of the insulating layer 627 overlap with the conductive layer 611a functioning as a pixel electrode and the other end portion of the insulating layer 627 overlap with the conductive layer 611b functioning as a pixel electrode. Such a structure enables the end portion of the insulating layer 627 to be formed over a flat or substantially flat region of the layer 613a (the layer 613b). This makes it relatively easy to process the insulating layer 627 to have a tapered shape as described above.

By providing the insulating layer 627 and the like in the above manner, a disconnected portion and a locally thinned portion can be prevented from being formed in the common layer 614 and the common electrode 615 from a flat or substantially flat region of the layer 613a to a flat or substantially flat region of the layer 613b. Thus, a connection defect due to a disconnected portion and an increase in electric resistance due to a locally thinned portion can be inhibited from occurring in the common layer 614 and the common electrode 615 between the light-emitting elements.

In the display device of this embodiment, the distance between the light-emitting elements can be short. Specifically, the distance between the light-emitting elements, the distance between the EL layers, or the distance between the pixel electrodes can be less than 10 μm, less than or equal to 8 μm, less than or equal to 5 μm, less than or equal to 3 μm, less than or equal to 2 μm, less than or equal to 1 μm, less than or equal to 500 nm, less than or equal to 200 nm, less than or equal to 100 nm, less than or equal to 90 nm, less than or equal to 70 nm, less than or equal to 50 nm, less than or equal to 30 nm, less than or equal to 20 nm, less than or equal to 15 nm, or less than or equal to 10 nm. In other words, the display device in this embodiment includes a region where a distance between two adjacent island-shaped EL layers is less than or equal to 1 μm, preferably less than or equal to 0.5 μm (500 nm), further preferably less than or equal to 100 nm. Shortening the distance between the light-emitting elements in this manner enables a display device to have a high resolution and a high aperture ratio.

A protective layer 631 is provided over the light-emitting elements. The protective layer 631 functions as a passivation film for protecting the light-emitting elements. Providing the protective layer 631 that covers the light-emitting elements can inhibit entry of impurities such as water and oxygen into the light-emitting elements and increase the reliability of the light-emitting elements. The protective layer 631 preferably has a single-layer structure or a stacked-layer structure at least including an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material such as In—Ga oxide or IGZO may be used for the protective layer 631. Although the protective layer 631 includes an inorganic insulating film in this example, the present invention is not limited thereto. For example, the protective layer 631 may have a stacked-layer structure of an inorganic insulating film and an organic insulating film.

The protective layer 631 and a substrate 610 are bonded to each other with an adhesive layer 637. A solid sealing structure, a hollow sealing structure, or the like can be employed to seal the light-emitting elements. In FIG. 37, a solid sealing structure is employed, in which a space between the substrate 410 and the substrate 610 is filled with the adhesive layer 637. Alternatively, a hollow sealing structure may be employed, in which the space is filled with an inert gas (e.g., nitrogen or argon). In that case, the adhesive layer 637 may be provided not to overlap with the light-emitting elements. Furthermore, the space may be filled with a resin other than the frame-like adhesive layer 637.

As the adhesive layer 637, any of a variety of curable adhesives such as a reactive curable adhesive, a thermosetting adhesive, an anaerobic adhesive, and a photocurable adhesive such as an ultraviolet curable adhesive can be used. Examples of these adhesives include an epoxy resin, an acrylic resin, a silicone resin, a phenol resin, a polyimide resin, a polyvinyl chloride (PVC) resin, a PVB resin, and an ethylene-vinyl acetate (EVA) resin. In particular, a material with low moisture permeability, such as an epoxy resin, is preferable. A two-component-mixture-type resin may be used. An adhesive sheet may be used.

The display device 600A is a top-emission display device. The aperture ratio of pixels in a top-emission structure can be higher than that of pixels in a bottom-emission structure because a transistor and the like can be provided to overlap with a light-emitting region of a light-emitting element in the top-emission structure. Light from the light-emitting elements is emitted to the substrate 610 side. For this reason, a material having a high visible-light-transmitting property is preferably used for the substrate 610. For example, a substrate having a high visible-light-transmitting property is preferably selected as the substrate 610 among substrates usable as the substrate 410. The pixel electrode contains a material reflecting visible light, and the counter electrode (the common electrode 615) contains a material transmitting visible light.

Note that the display device of one embodiment of the present invention may be not a top-emission display device but a bottom-emission display device where light from the light-emitting elements is emitted to the substrate 410 side. In that case, a substrate having a high visible-light-transmitting property is selected as the substrate 410.

### Structure Example 2 of Display Device

FIG. 38 is a cross-sectional view of the display device 600B.

The display device 600B can be a flexible display device when a flexible substrate is used as each of a substrate 541 and the substrate 610. The substrate 541 is bonded to an insulating layer 545 with an adhesive layer 543. The substrate 610 is bonded to the protective layer 631 with the adhesive layer 637.

The element layer 603 of the display device 600B is different from the element layer 603 of the display device 600A mainly in that the layers 613a to 613c have the same structure and a coloring layer 628R, a coloring layer 628G, and a coloring layer 628B are provided.

The layers 613a to 613c are formed using the same material in the same step. The layers 613a to 613c are isolated from each other. When the EL layer is provided in an island shape for each light-emitting element, a leakage current between adjacent light-emitting elements (sometimes referred to as a horizontal-direction leakage current, a horizontal leakage current, or a lateral leakage current) can be inhibited. Accordingly, unintentional light emission due to crosstalk can be prevented, and color mixture between adjacent light-emitting elements can be inhibited, so that a display device with extremely high contrast can be obtained.

The light-emitting elements 650R, 650G, and 650B illustrated in FIG. 38 emit white light, for example. White light emitted from the light-emitting elements 650R, 650G, and 650B passes through the coloring layers 628R, 628G, and 628B, whereby light of a desired color can be obtained.

Light emitted from the light-emitting element 650R, the light-emitting element 650G, and the light-emitting element 650B is extracted as red light, green light, and blue light to the outside of the display device 600B through the coloring layer 628R, the coloring layer 628G, and the coloring layer 628B, respectively.

For another example, the light-emitting elements 650R, 650G, and 650B illustrated in FIG. 38 emit blue light. In that case, the layers 613a to 613c each include one or more light-emitting layers emitting blue light. In a subpixel emitting blue light, blue light emitted from the light-emitting element 650B can be extracted. In each of the subpixel emitting red light and the subpixel emitting green light, a color conversion layer is provided between the light-emitting element 650R and the coloring layer 628R and between the light-emitting element 650G and the coloring layer 628G, so that blue light emitted from the light-emitting element 650R or 650G is converted into light with a longer wavelength and red light or green light can be extracted. When light passing through the color conversion layer is extracted through the coloring layer, light other than light of a desired color can be absorbed by the coloring layer, and color purity of light emitted from a subpixel can be improved.

The coloring layer is a colored layer that selectively transmits light in a specific wavelength range and absorbs light in the other wavelength ranges. For example, a red color filter for transmitting light in the red wavelength range, a green color filter for transmitting light in the green wavelength range, a blue color filter for transmitting light in the blue wavelength range, or the like can be used. Each coloring layer can be formed using one or more of a metal material, a resin material, a pigment, and a dye.

The element layer 602 of the display device 600B has a structure similar to that of the element layer 602 of the display device 600A; thus, the detailed description thereof is omitted.

The display device 600B is different from the display device 600A in not including the element layer 601 but including an element layer 605. The element layer 605 has a structure similar to that of the element layer 602.

At least part of a transistor included in the element layer 605 is connected to a conductive layer or a transistor included in the element layer 602 through a plug, a wiring, and the like. Note that the wiring layer 604 may be provided between the element layer 602 and the element layer 605.

One or both of a pixel circuit and a driver circuit of the display device are preferably provided in the element layer 605.

Although FIG. 38 illustrates an example in which two element layers (the element layers 602 and 605) including OS transistors are stacked, the number of stacked element layers is not limited thereto, and three or more layers may be stacked. For example, in the case where three or more element layers including OS transistors are stacked, it is preferable that the lowermost layer be used for the driver circuit (one or both of the gate driver and the source driver) of the display device, the uppermost layer be used for the pixel circuit of the display device, and one or more layers between them be used for the pixel circuit or the driver circuit.

A Si transistor is typically formed on a single crystal Si wafer, and thus is difficult to have flexibility. Meanwhile, as illustrated in FIG. 38, in the case where the display device is formed using only OS transistors without using a Si transistor, the display device can have flexibility through a relatively simple manufacturing process.

This embodiment can be combined with any of the other embodiments or Example as appropriate. In this specification, in the case where a plurality of structure examples are shown in one embodiment, the structure examples can be combined as appropriate.

### Embodiment 6

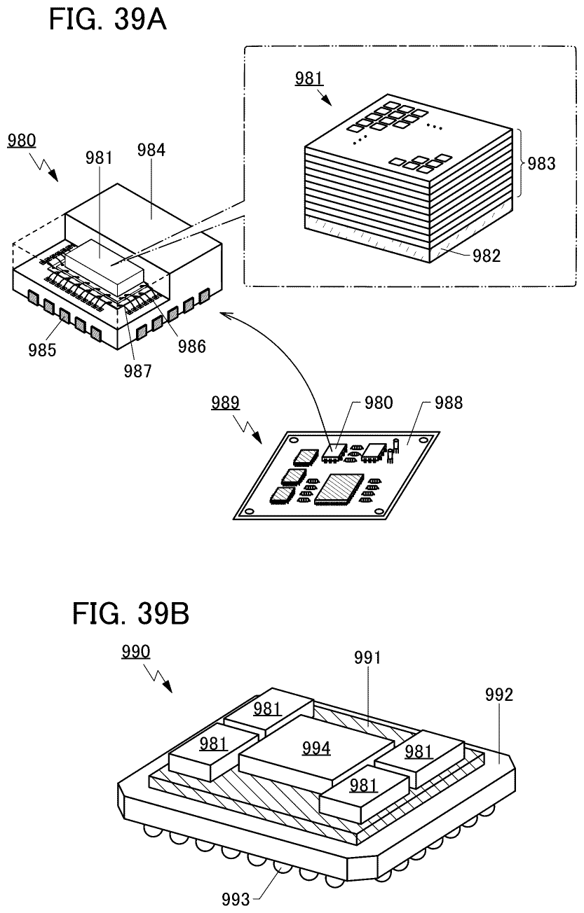

In this embodiment, application examples of the semiconductor device of one embodiment of the present invention will be described with reference to FIG. 39A to FIG. 41F.

The semiconductor device of one embodiment of the present invention can be used for an electronic component, a large computer, space equipment, a data center (also referred to as DC), and a variety of electronic devices, for example. With the use of the semiconductor device of one embodiment of the present invention, an electronic component, a large computer, space equipment, a data center, and a variety of electronic devices can have lower power consumption and higher performance.

A display device including the semiconductor device of one embodiment of the present invention can be used for a display portion of any of a variety of electronic devices. The display device including the semiconductor device of one embodiment of the present invention can be easily increased in resolution and definition.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop computers, a monitor of a computer and the like, digital signage, and a large game machine such as a pachinko machine.

In particular, the display device of one embodiment of the present invention can have a high resolution, and thus is suitable for an electronic device having a relatively small display portion. Examples of such an electronic device include watch-type and bracelet-type information terminal devices (wearable devices) and wearable devices that can be worn on the head, such as a VR device like a head-mounted display, a glasses-type AR device, and a mixed reality (MR) device.

The definition of the display device of one embodiment of the present invention is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, a definition of 4K, 8K, or higher is preferable. The pixel density (resolution) of the display device of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. The use of the display device having one or both of such a high definition and a high resolution can further increase realistic sensation, sense of depth, and the like. There is no particular limitation on the screen ratio (aspect ratio) of the display device of one embodiment of the present invention. For example, the display device is compatible with a variety of screen ratios such as 1:1 (a square), 4:3, 16:9, and 16:10.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, an electric field, a current, a voltage, electric power, radiation, a flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

### [Electronic Component]

FIG. 39A is a perspective view of a substrate (a circuit board 989) provided with an electronic component 980. The electronic component 980 illustrated in FIG. 39A includes a semiconductor device 981 in a mold 984. FIG. 39A omits some components to show the inside of the electronic component 980. The electronic component 980 includes a land 985 outside the mold 984. The land 985 is electrically connected to an electrode pad 986, and the electrode pad 986 is electrically connected to the semiconductor device 981 through a wire 987. The electronic component 980 is mounted on a printed circuit board 988, for example. A plurality of such electronic components are combined and electrically connected to each other on the printed circuit board 988, which forms the circuit board 989.

The semiconductor device 981 includes a driver circuit layer 982 and a memory layer 983. The memory layer 983 has a structure in which a plurality of memory cell arrays are stacked. A stacked-layer structure of the driver circuit layer 982 and the memory layer 983 can be a monolithic stacked-layer structure. In the monolithic stacked-layer structure, layers can be connected to each other without using a through electrode technique such as a through silicon via (TSV) technique and a bonding technique such as Cu—Cu direct bonding. Monolithically stacking the driver circuit layer 982 and the memory layer 983 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as TSV is used, which means that the number of connection pins can be increased. The increase in the number of connection pins enables parallel operations, which can improve the bandwidth of the memory (also referred to as a memory bandwidth).

It is preferable that the plurality of memory cell arrays included in the memory layer 983 be formed with OS transistors and be monolithically stacked. Monolithically stacking the plurality of memory cell arrays can improve one or both of a memory bandwidth and a memory access latency. Note that the bandwidth refers to the data transfer volume per unit time, and the access latency refers to a period of time from data access to the start of data transmission. In the case where the memory layer 983 is formed with Si transistors, the monolithic stacked-layer structure is difficult to form as compared with the case where the memory layer 983 is formed with OS transistors. Thus, an OS transistor is superior to a Si transistor in the monolithic stacked-layer structure.

The semiconductor device 981 may be called a die. In this specification and the like, a die refers to a chip obtained by, for example, forming a circuit pattern on a disc-like substrate (also referred to as a wafer) or the like and cutting the substrate with the pattern into dices in a process of manufacturing a semiconductor chip. Examples of semiconductor materials that can be used for the die include silicon (Si), silicon carbide (SiC), and gallium nitride (GaN). For example, a die obtained from a silicon substrate (also referred to as a silicon wafer) is referred to as a silicon die in some cases.

FIG. 39B is a perspective view of an electronic component 990. The electronic component 990 is an example of a system in package (SiP) or a multi-chip module (MCM). In the electronic component 990, an interposer 991 is provided over a package substrate 992 (printed circuit board), and a semiconductor device 994 and a plurality of semiconductor devices 981 are provided over the interposer 991.

The electronic component 990 using the semiconductor device 981 as a high bandwidth memory (HBM) is illustrated as an example. The semiconductor device 994 can be used for an integrated circuit such as a CPU, a GPU, or a field programmable gate array (FPGA).

As the package substrate 992, a ceramic substrate, a plastic substrate, or a glass epoxy substrate can be used, for example. As the interposer 991, a silicon interposer or a resin interposer can be used, for example.

The interposer 991 includes a plurality of wirings and has a function of connecting a plurality of integrated circuits with different terminal pitches. The plurality of wirings are provided in a single layer or multiple layers. In addition, the interposer 991 has a function of connecting an integrated circuit provided on the interposer 991 to an electrode provided on the package substrate 992. Accordingly, the interposer is referred to as a “redistribution substrate” or an “intermediate substrate” in some cases. Furthermore, a through electrode is provided in the interposer 991 and the through electrode is used to connect an integrated circuit and the package substrate 992 in some cases. Moreover, in the case of using a silicon interposer, a TSV can also be used as the through electrode.

An HBM needs to be connected to many wirings to achieve a wide memory bandwidth. Thus, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is unlikely to occur. Furthermore, a surface of a silicon interposer has high flatness; thus, poor connection between the silicon interposer and an integrated circuit provided on the silicon interposer is unlikely to occur. It is particularly preferable to use a silicon interposer for a 2.5D package (2.5-dimensional mounting) in which a plurality of integrated circuits are arranged side by side on the interposer.

In the case where a plurality of integrated circuits with different terminal pitches are connected with use of a silicon interposer, a TSV, and the like, a space for a width of the terminal pitch and the like is needed. Accordingly, in the case where the size of the electronic component 990 is to be reduced, the width of the terminal pitch becomes an issue, which sometimes makes it difficult to provide a large number of wirings for obtaining a wide memory bandwidth. For this reason, the above-described monolithic stacked-layer structure with use of OS transistors is suitable. A composite structure combining memory cell arrays stacked using a TSV and monolithically stacked memory cell arrays may be employed.

A heat sink (a radiator plate) may be provided to overlap with the electronic component 990. In the case of providing a heat sink, the heights of integrated circuits provided on the interposer 991 are preferably equal to each other. For example, in the electronic component 990 described in this embodiment, the heights of the semiconductor devices 981 and the semiconductor device 994 are preferably equal to each other.

To mount the electronic component 990 on another substrate, an electrode 993 may be provided on a bottom portion of the package substrate 992. FIG. 39B illustrates an example in which the electrode 993 is formed of a solder ball. Solder balls are provided in a matrix on the bottom portion of the package substrate 992, so that ball grid array (BGA) mounting can be achieved. Alternatively, the electrode 993 may be formed of a conductive pin. When conductive pins are provided in a matrix on the bottom portion of the package substrate 992, pin grid array (PGA) mounting can be achieved.

The electronic component 990 can be mounted on another substrate by various mounting methods other than BGA and PGA. Examples of a mounting method include staggered pin grid array (SPGA), land grid array (LGA), quad flat package (QFP), quad flat J-leaded package (QFJ), and quad flat non-leaded package (QFN).

### [Large Computer]

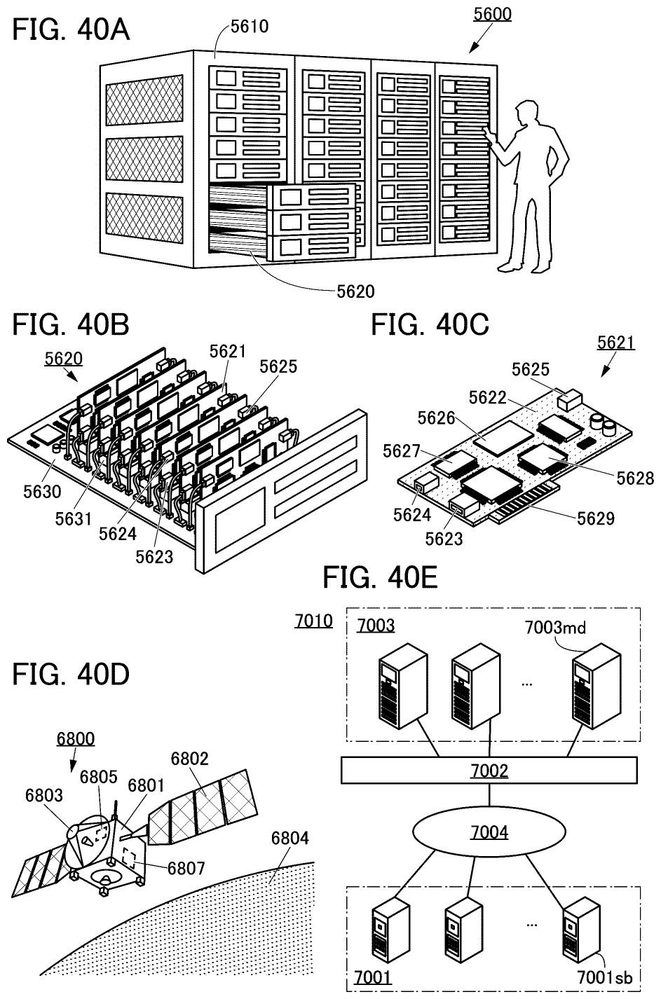

FIG. 40A is a perspective view of a large computer 5600. In the large computer 5600 illustrated in FIG. 40A, a plurality of rack mount computers 5620 are stored in a rack 5610. Note that the large computer 5600 may be referred to as a supercomputer.

The computer 5620 can have a structure illustrated in a perspective view of FIG. 40B, for example. In FIG. 40B, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 40C is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 40C also illustrates semiconductor devices other than the semiconductor devices 5626, 5627, and 5628, and the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminals 5623, 5624, and 5625 can each serve as, for example, an interface for performing power supply, signal input, or the like to the PC card 5621. For another example, they can each serve as an interface for outputting a signal calculated by the PC card 5621. Examples of the standard for each of the connection terminals 5623, 5624, and 5625 include Universal Serial Bus (USB), Serial ATA (SATA), and Small Computer System Interface (SCSI). In the case where video signals are output from the connection terminals 5623, 5624, and 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be connected to each other.

The semiconductor device 5627 includes a plurality of terminals, and when the terminals are reflow-soldered, for example, to wirings of the board 5622, the semiconductor device 5627 and the board 5622 can be connected to each other. Examples of the semiconductor device 5627 include an FPGA, a GPU, and a CPU. As the semiconductor device 5627, the electronic component 990 can be used, for example.

The semiconductor device 5628 includes a plurality of terminals, and when the terminals are reflow-soldered, for example, to wirings of the board 5622, the semiconductor device 5628 and the board 5622 can be connected to each other. An example of the semiconductor device 5628 is a memory device. As the semiconductor device 5628, the electronic component 990 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention is suitable as space equipment.

The semiconductor device of one embodiment of the present invention includes an OS transistor. A change in electrical characteristics due to radiation irradiation is smaller in an OS transistor than in a Si transistor. That is, the OS transistor is highly resistant to radiation, and thus has high reliability and is suitable in an environment where radiation can enter. For example, the OS transistor is suitably used in outer space. Specifically, the OS transistor can be used as a transistor in a semiconductor device provided in a space shuttle, an artificial satellite, or a space probe. Examples of radiation include X-rays and a neutron beam. Note that outer space refers to, for example, space at an altitude greater than or equal to 100 km, and outer space described in this specification can include one or more of thermosphere, mesosphere, and stratosphere.

FIG. 40D illustrates an artificial satellite 6800 as an example of space equipment. The artificial satellite 6800 includes a body 6801, a solar panel 6802, an antenna 6803, a secondary battery 6805, and a control device 6807. In FIG. 40D, a planet 6804 in outer space is illustrated as an example.

Although not illustrated in FIG. 40D, a battery management system (also referred to as BMS) or a battery control circuit may be provided in the secondary battery 6805. The OS transistor is preferably used in the battery management system or the battery control circuit because of its low power consumption and high reliability even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the situation where the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. The control device 6807 is formed with one or more selected from a CPU, a GPU, and a memory device, for example. Note that the semiconductor device including the OS transistor of one embodiment of the present invention is suitably used for the control device 6807.

The artificial satellite 6800 can include a sensor. For example, with a structure including a visible light sensor, the artificial satellite 6800 can have a function of detecting sunlight reflected by a ground-based object. Alternatively, with a structure including a thermal infrared sensor, the artificial satellite 6800 can have a function of detecting thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited to this example. The semiconductor device of one embodiment of the present invention is suitable for space equipment such as a spacecraft, a space capsule, or a space probe, for example.

As described above, the OS transistor has advantageous effects over the Si transistor, such as a wide memory bandwidth and high radiation resistance.

### [Data Center]

The semiconductor device of one embodiment of the present invention is suitable for, for example, a storage system in a data center or the like. Long-term management of data, such as guarantee of data immutability, is required for the data center. In the case where data is managed for a long term, it is necessary to increase the scale of data center facility for installation of storages and servers for storing an enormous amount of data, stable electric power for data retention, cooling equipment for data retention, or the like.

With the use of the semiconductor device of one embodiment of the present invention for the storage system in the data center, electric power required for data retention and the size of a semiconductor device retaining data can be reduced. Thus, the size of the storage system, the amount of electric power for data retention, the size of the cooling equipment, and the like can be reduced. This can reduce the scale of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention enables a data center that operates stably even in a high temperature environment. Thus, the reliability of the data center can be increased.

FIG. 40E illustrates a storage system that can be used in a data center. A storage system 7010 illustrated in FIG. 40E includes a plurality of servers 7001sb as a host 7001. The storage system 7010 includes a plurality of memory devices 7003md as a storage 7003. In the illustrated example, the host 7001 and the storage 7003 are connected to each other through a storage area network 7004 and a storage control circuit 7002.

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in the storage to shorten the time taken for storing and outputting data.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downscaling is possible by stacking memory cell arrays.

### [Electronic Device]

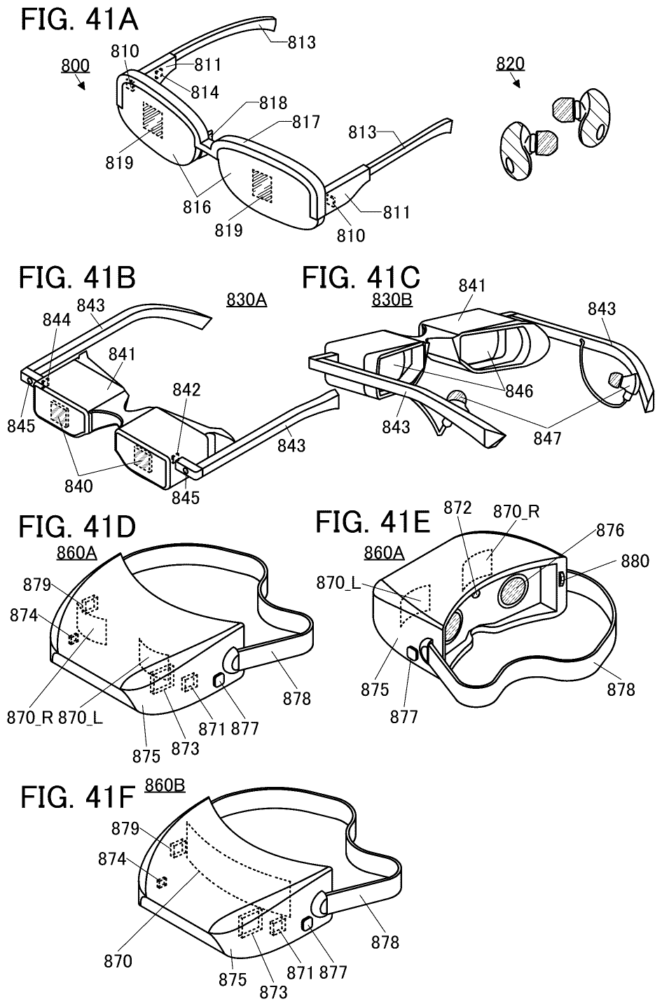

Examples of wearable devices that can be worn on a head will be described with reference to FIGS. 41A to 41F. These wearable devices have at least one of a function of displaying AR contents, a function of displaying VR contents, a function of displaying substitutional reality (SR) contents, and a function of displaying MR contents. The electronic device having a function of displaying contents of at least one of AR, VR, SR, MR, and the like enables the user to feel a higher level of immersion.

An electronic device 800 illustrated in FIG. 41A includes a pair of display panels 810, a pair of housings 811, a communication portion (not illustrated), a pair of wearing portions 813, a control portion 814, an image capturing portion (not illustrated), a pair of optical members 816, a frame 817, and a pair of nose pads 818.

The display device of one embodiment of the present invention can be used for the display panels 810. Thus, the electronic device is capable of performing ultrahigh-resolution display. The semiconductor device of one embodiment of the present invention can be used for the control portion 814. In that case, the power consumption of the electronic device can be reduced.

The electronic device 800 can project images displayed on the display panels 810 onto display regions 819 of the optical members 816. Since the optical members 816 have a light-transmitting property, the user can see images displayed on the display regions, which are superimposed on transmission images seen through the optical members 816. Accordingly, the electronic device 800 is capable of AR display.

In the electronic device 800, a camera capable of capturing images of the front side may be provided as the image capturing portion. When the electronic device 800 is provided with an acceleration sensor such as a gyroscope sensor, the orientation of the user's head can be sensed and an image corresponding to the orientation can be displayed on the display regions 819.

The communication portion includes a wireless communication device, and a video signal and the like can be supplied by the wireless communication device. Instead of or in addition to the wireless communication device, a connector that can be connected to a cable for supplying a video signal and a power supply potential may be provided.

The electronic device 800 is provided with a battery so that charging can be performed wirelessly and/or by wire.

A touch sensor module may be provided in the housing 811. The touch sensor module has a function of detecting a touch on the outer surface of the housing 811. Detecting a tap operation, a slide operation, or the like by the user with the touch sensor module enables various types of processing. For example, a video can be paused or restarted by a tap operation, and can be fast-forwarded or fast-reversed by a slide operation. When the touch sensor module is provided in each of the two housings 811, the range of the operation can be increased.

An electronic device 830A illustrated in FIG. 41B and an electronic device 830B illustrated in FIG. 41C each include a pair of display portions 840, a housing 841, a communication portion 842, a pair of wearing portions 843, a control portion 844, a pair of image capturing portions 845, and a pair of lenses 846.

The display device of one embodiment of the present invention can be used for the display portions 840. Thus, the electronic devices are capable of performing ultrahigh-resolution display. Such electronic devices provide a high level of immersion to the user. The semiconductor device of one embodiment of the present invention can be used for the control portion 844. In that case, the power consumption of the electronic devices can be reduced.

The display portions 840 are positioned inside the housing 841 so as to be seen through the lenses 846. When the pair of display portions 840 display different images, three-dimensional display using parallax can be performed.

The electronic devices 830A and 830B can be regarded as electronic devices for VR. The user wearing the electronic device 830A or the electronic device 830B can see images displayed on the display portions 840 through the lenses 846.

The electronic devices 830A and 830B preferably include a mechanism for adjusting the lateral positions of the lenses 846 and the display portions 840 so that the lenses 846 and the display portions 840 are positioned optimally in accordance with the positions of the user's eyes. Moreover, the electronic devices 830A and 830B preferably include a mechanism for adjusting focus by changing the distance between the lenses 846 and the display portions 840.

The electronic device 830A or the electronic device 830B can be mounted on the user's head with the wearing portions 843. FIG. 41B and the like illustrate examples in which the wearing portion 843 has a shape like a temple of glasses; however, one embodiment of the present invention is not limited thereto. The wearing portion 843 may have any shape with which the user can wear the electronic device, such as a shape of a helmet or a band.

The image capturing portion 845 has a function of obtaining information on the external environment. Data obtained by the image capturing portion 845 can be output to the display portion 840. An image sensor can be used for the image capturing portion 845. Moreover, a plurality of cameras may be provided so as to cover a plurality of fields of view, such as a telescope field of view and a wide field of view.

Although an example in which the image capturing portions 845 are provided is illustrated here, a range sensor (hereinafter, also referred to as a sensing portion) capable of measuring a distance between the user and an object just needs to be provided. That is, the image capturing portion 845 is one embodiment of the sensing portion. As the sensing portion, an image sensor or a range image sensor such as a light detection and ranging (LiDAR) sensor can be used, for example. By using images obtained by the camera and images obtained by the range image sensor, more pieces of information can be obtained and a gesture operation with higher accuracy is possible.

The electronic device 830A may include a vibration mechanism that functions as bone-conduction earphones. For example, at least one of the display portion 840, the housing 841, and the wearing portion 843 can include the vibration mechanism. Thus, without additionally requiring an audio device such as headphones, earphones, or a speaker, the user can enjoy videos and sound only by wearing the electronic device 830A.

The electronic devices 830A and 830B may each include an input terminal. To the input terminal, a cable for supplying a video signal from a video output device or the like, power for charging the battery provided in the electronic device, and the like can be connected.

The electronic device of one embodiment of the present invention may have a function of performing wireless communication with earphones 820. The earphones 820 include a communication portion (not illustrated) and have a wireless communication function. The earphones 820 can receive information (e.g., audio data) from the electronic device with the wireless communication function. For example, the electronic device 800 in FIG. 41A has a function of transmitting information to the earphones 820 with the wireless communication function.

The electronic device may include earphone portions. The electronic device 830B in FIG. 41C includes earphone portions 847. For example, the earphone portion 847 can be connected to the control portion 844 by wire. Part of a wiring that connects the earphone portion 847 and the control portion 844 may be positioned inside the housing 841 or the wearing portion 843. Alternatively, the earphone portions 847 and the wearing portions 843 may include magnets. This is preferable because the earphone portions 847 can be fixed to the wearing portions 843 with magnetic force and thus can be easily housed.

The electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of a headset by including the audio input mechanism.

FIGS. 41D and 41E are perspective views of a goggles-type electronic device 860A for VR. FIGS. 41D and 41E illustrate an example in which a housing 875 includes a pair of curved display devices 870 (a display device 870_R and a display device 870_L). The electronic device 860A includes a motion detection portion 871, an eye-gaze detection portion 872, an arithmetic portion 873, a communication portion 874, lenses 876, an operation button 877, a wearing tool 878, a sensor 879, a dial 880, and the like.

When the two display devices 870 are provided, the user's eyes can see the respective display devices. This allows a high-definition video to be displayed even when three-dimensional display using parallax or the like is performed. In addition, the display device 870 is curved around an arc with an approximate center at the user's eye. This keeps a certain distance between the user's eye and the display surface of the display device 870, enabling the user to see a more natural video. Even when having what is called viewing angle dependence where the luminance or chromaticity of light changes depending on a viewing angle, the display device 870 can have a structure in which the user's eye is positioned in the normal direction of the display surface of the display device 870; accordingly, the influence of the viewing angle dependence particularly in the horizontal direction can be practically ignored, enabling display of a more realistic video.

As illustrated in FIG. 41E, the lenses 876 are positioned between the display devices 870 and the user's eyes. FIG. 41E illustrates an example in which the dial 880 for changing the positions of the lenses for visibility adjustment is provided. In the case where the electronic device 860A has an autofocus function, the dial 880 for visibility adjustment is not necessarily provided.

FIG. 41F illustrates a goggles-type electronic device 860B including one display device 870. Such a structure can reduce the number of components.

The display device 870 can display an image for the right eye and an image for the left eye side by side on a right region and a left region, respectively. Thus, a three-dimensional video using binocular parallax can be displayed. Note that the display device 870 may display two different images side by side using parallax, or may display two same images side by side without using parallax.

One image which can be seen with both eyes may be displayed on the entire display device 870. Thus, a panorama video can be displayed from end to end of the field of view, which can provide a higher sense of reality.

The display device of one embodiment of the present invention can be used as the display device 870. Since the display device of one embodiment of the present invention has an extremely high resolution, even when an image is magnified using the lenses 876, the pixels are not perceived by the user and thus a more realistic video can be displayed.

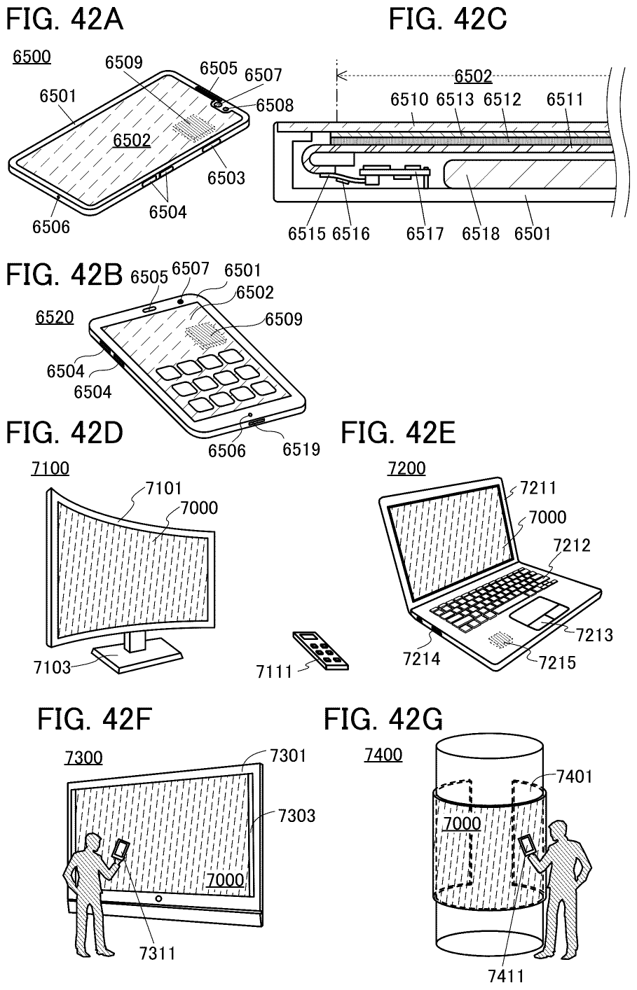

An electronic device 6500 in FIG. 42A is a portable information terminal that can be used as a smartphone.

The electronic device 6500 includes a housing 6501, a display portion 6502, a power button 6503, buttons 6504, a speaker 6505, a microphone 6506, a camera 6507, a light source 6508, a control device 6509, and the like.

An electronic device 6520 in FIG. 42B is a portable information terminal that can be used as a tablet terminal.

The electronic device 6520 includes the housing 6501, the display portion 6502, the buttons 6504, the speaker 6505, the microphone 6506, the camera 6507, the control device 6509, a connection terminal 6519, and the like.

In each of the electronic device 6500 and the electronic device 6520, the display portion 6502 has a touch panel function. The control device 6509 includes, for example, one or more selected from a CPU, a GPU, and a memory device. The semiconductor device of one embodiment of the present invention can be used for one or both of the display portion 6502 and the control device 6509.

FIG. 42C is a schematic cross-sectional view including an end portion of the housing 6501 included in the electronic device 6500 or the electronic device 6520 on the microphone 6506 side.

A protection member 6510 having a light-transmitting property is provided on the display surface side of the housing 6501. A display panel 6511, an optical member 6512, a touch sensor panel 6513, a printed circuit board 6517, a battery 6518, and the like are provided in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

The display device of one embodiment of the present invention can be used as the display panel 6511. Thus, an extremely lightweight electronic device can be obtained. Since the display panel 6511 is extremely thin, the battery 6518 with high capacity can be mounted without an increase in the thickness of the electronic device. An electronic device with a narrow bezel can be obtained when part of the display panel 6511 is folded back such that the portion connected to the FPC 6515 is provided on the back side of a pixel portion.

FIG. 42D illustrates an example of a television device. In a television device 7100, a display portion 7000 is incorporated in a housing 7101. Here, the housing 7101 is supported by a stand 7103.

The display device of one embodiment of the present invention can be used for the display portion 7000.

The television device 7100 illustrated in FIG. 42D can be operated with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 42E illustrates an example of a laptop computer. A laptop computer 7200 includes a housing 7211, a keyboard 7212, a pointing device 7213, an external connection port 7214, a control device 7215, and the like. The display portion 7000 is incorporated in the housing 7211. The control device 7215 includes, for example, one or more selected from a CPU, a GPU, and a memory device. The semiconductor device of one embodiment of the present invention can be used for one or both of the display portion 7000 and the control device 7215.

FIGS. 42F and 42G illustrate examples of digital signage.

Digital signage 7300 illustrated in FIG. 42F includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 42G is digital signage 7400 attached to a cylindrical pillar 7401. The digital signage 7400 includes the display portion 7000 provided along a curved surface of the pillar 7401.

The display device of one embodiment of the present invention can be used for the display portion 7000 illustrated in each of FIGS. 42F and 42G.

A larger area of the display portion 7000 can increase the amount of information that can be provided at a time. The display portion 7000 having a larger area attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIGS. 42F and 42G, it is preferable that the digital signage 7300 or the digital signage 7400 be capable of working with an information terminal 7311 or an information terminal 7411, such as a smartphone of a user, through wireless communication. For example, information of an advertisement displayed on the display portion 7000 can be displayed on a screen of the information terminal 7311 or the information terminal 7411. By operation of the information terminal 7311 or the information terminal 7411, display on the display portion 7000 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

The semiconductor device and the display device of one embodiment of the present invention can be used around a driver's seat in a car, which is a vehicle.

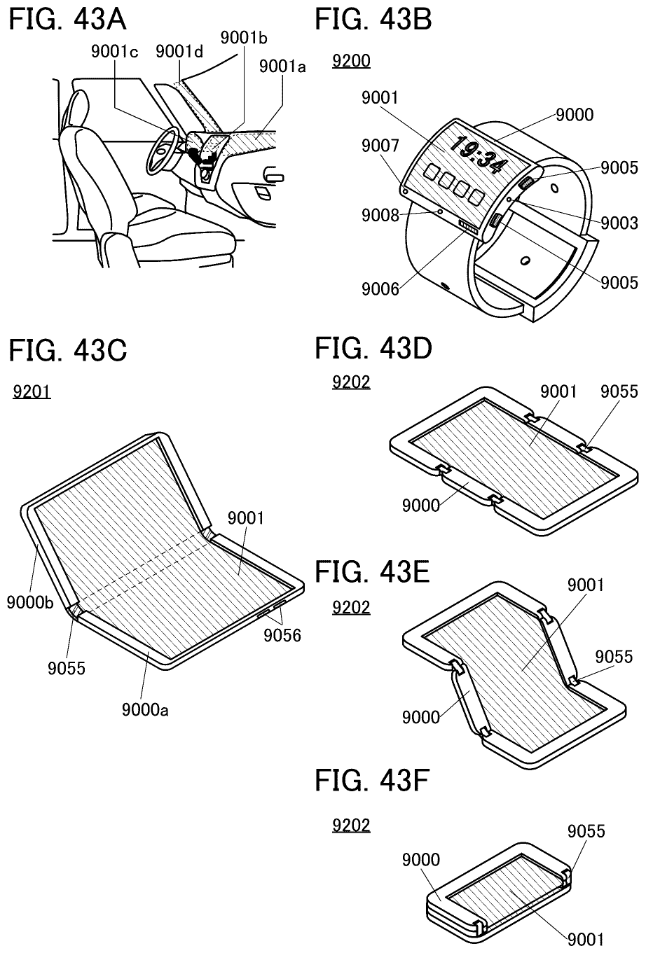

FIG. 43A illustrates the vicinity of a windshield inside a car. FIG. 43A illustrates a display panel 9001a, a display panel 9001b, and a display panel 9001c attached to a dashboard and a display panel 9001d attached to a pillar.

The display panels 9001a to 9001c can provide various kinds of information by displaying navigation data, a speedometer, a tachometer, a mileage, a fuel meter, a gearshift state, air-conditioning settings, and the like. Items displayed on the display panels, their layout, and the like can be changed as appropriate to suit the user's preferences, resulting in more sophisticated design. The display panels 9001a to 9001c can also be used as lighting devices.

The display panel 9001d can compensate for the view hindered by the pillar (blind areas) by displaying a video taken by an imaging unit provided for the car body. That is, displaying an image taken by the imaging unit provided on the outside of the car body leads to elimination of blind areas and enhancement of safety. Moreover, displaying a video to compensate for the area that a driver cannot see makes it possible for the driver to confirm safety more easily and comfortably. The display panel 9001d can also be used as a lighting device.

FIG. 43B is a perspective view of a watch-type portable information terminal 9200. The portable information terminal 9200 can be used as a Smartwatch (registered trademark), for example. The display surface of a display portion 9001 is curved, and display can be performed on the curved display surface. Furthermore, for example, mutual communication between the portable information terminal 9200 and a headset capable of wireless communication can be performed, and thus hands-free calling is possible. With a connection terminal 9006, the portable information terminal 9200 can perform mutual data transmission with another information terminal and charging. Note that the charging operation may be performed by wireless power feeding.

The portable information terminal 9200 illustrated in FIG. 43B includes a housing 9000, the display portion 9001, a speaker 9003, an operation key 9005 (including a power switch or an operation switch), the connection terminal 9006, a sensor 9007 (a sensor having a function of sensing, detecting, or measuring force, displacement, position, speed, acceleration, angular velocity, rotational frequency, distance, light, liquid, magnetism, temperature, a chemical substance, sound, time, hardness, an electric field, a current, a voltage, electric power, radiation, a flow rate, humidity, gradient, oscillation, a smell, or infrared rays), a microphone 9008, and the like.

FIG. 43C is a perspective view of a foldable portable information terminal 9201. The portable information terminal 9201 includes a housing 9000a, a housing 9000b, the display portion 9001, and operation buttons 9056.

The housing 9000a and the housing 9000b are bonded to each other with a hinge 9055 that allows the display portion 9001 to be folded in half.

The display portion 9001 of the portable information terminal 9201 is supported by two housings (the housings 9000a and 9000b) joined together with the hinge 9055.

FIGS. 43D to 43F are perspective views illustrating a foldable portable information terminal 9202. FIG. 43D is a perspective view of an opened state of the portable information terminal 9202, FIG. 43F is a perspective view of a folded state thereof, and FIG. 43E is a perspective view of a state in the middle of change from one of FIG. 43D and FIG. 43F to the other. In this manner, the portable information terminal 9202 can be folded in three.

The display portion 9001 of the portable information terminal 9202 is supported by three housings 9000 joined together with the hinges 9055.

In FIGS. 43C to 43F, the display device of one embodiment of the present invention can be used for the display portion 9001. The display portion 9001 can be folded with a radius of curvature greater than or equal to 0.1 mm and less than or equal to 150 mm, for example.

The portable information terminals 9201 and 9202 are highly portable when folded. When the portable information terminals 9201 and 9202 are opened, a seamless large display region is highly browsable.

The use of the semiconductor device of one embodiment of the present invention for one or more selected from an electronic component, a large computer, space equipment, a data center, and an electronic device can reduce power consumption. While the demand for energy is expected to increase with higher performance or higher integration of semiconductor devices, the emission amount of greenhouse effect gases typified by carbon dioxide (CO₂) can be reduced with use of the semiconductor device of one embodiment of the present invention. Furthermore, the semiconductor device of one embodiment of the present invention has low power consumption and thus is effective as a global warming countermeasure.

This embodiment can be combined with any of the other embodiments or Example as appropriate. In this specification, in the case where a plurality of structure examples are shown in one embodiment, the structure examples can be combined as appropriate.

### Example

In this example, measurement results of the average roughness (Ra) and the root-mean-square roughness (Rq) of a silicon oxide film are described.

In this example, two samples (Sample A1 and Sample A2) were fabricated. Methods for fabricating Sample A1 and Sample A2 are described below.

First, the same silicon substrate was prepared for the two samples. Next, a silicon oxide film with an aimed thickness of 50 nm was deposited over the silicon substrate by a pulsed DC sputtering method. The deposition conditions of the silicon oxide film were such that a silicon target was used, the deposition pressure was 0.6 Pa, the Ar flow rate was 60 sccm, the O₂ flow rate was 60 sccm, the substrate temperature was 200° C., and the distance between the target and the substrate was 62 mm. In the pulsed DC power supply, the electric power was set at 3 kW and the frequency was set at 100 kHz.

Next, CMP treatment was performed on Sample A2, so that the top surface of the silicon oxide film was planarized. In the CMP treatment, a slurry containing colloidal silica abrasive grains was used. The number of head rotations was 93 rpm, the number of stage rotations was 90 rpm, a polishing pressure of 2.0 psi was applied to the wafer, and the slurry flow rate was 150 ml/min. Note that Sample A1 was not subjected to CMP treatment.

In this manner, Samples A1 and A2 were fabricated.

The average roughness (Ra) and the root-mean-square roughness (Rq) of the silicon oxide film in each of the fabricated two samples were measured. Hereinafter, the average roughness (Ra) and the root-mean-square roughness (Rq) are collectively referred to as roughness in some cases. The roughness was measured with an atomic force microscope (AFM). As the AFM, SPA-500 manufactured by SII NanoTechnology Inc. was used. The measurement area was 2 μm×2 μm.

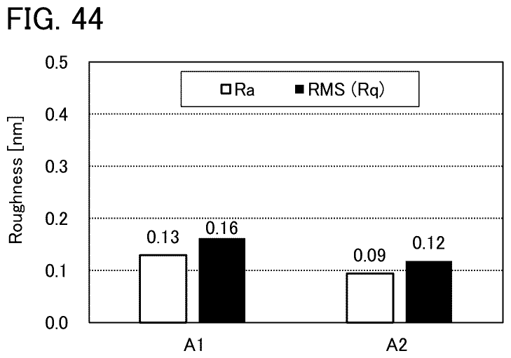

The AFM measurement results are shown in FIG. 44. In FIG. 44, the horizontal axis represents the sample name and the vertical axis represents roughness [nm]. The white bar and the black bar represent the average roughness (Ra) and the root-mean-square roughness (Rq), respectively, of the silicon oxide film included in the sample.

Ra and Rq of the silicon oxide film that was not subjected to the CMP treatment were 0.13 nm and 0.16 nm, respectively. Ra and Rq of the silicon oxide film that was subjected to the CMP treatment were 0.09 nm and 0.12 nm, respectively. From this, it was confirmed that the silicon oxide film can have a flat top surface by being deposited by a sputtering method. It was also confirmed that the top surface of the silicon oxide film can become flatter by being subjected to the CMP treatment.

The configurations, structures, methods, and the like described in this example can be used in an appropriate combination with any of the configurations, structures, methods, and the like described in embodiments and the like.

This application is based on Japanese Patent Application Serial No. 2024-073124 filed with Japan Patent Office on Apr. 26, 2024, Japanese Patent Application Serial No. 2024-077515 filed with Japan Patent Office on May 10, 2024, Japanese Patent Application Serial No. 2024-077556 filed with Japan Patent Office on May 10, 2024, and Japanese Patent Application Serial No. 2025-012375 filed with Japan Patent Office on Jan. 28, 2025, the entire contents of which are hereby incorporated by reference.

What is claimed is:

1. A method for forming a metal oxide layer, comprising the steps of:
forming a crystal part; and
forming a crystalline metal oxide layer using the crystal part as a nucleus,
wherein the metal oxide layer comprises indium.

2. The method for forming a metal oxide layer according to claim 1, wherein the crystal part is formed from one of grains of a polycrystalline film in forming the crystal part.

3. The method for forming a metal oxide layer according to claim 1, further comprising a step of forming an amorphous metal oxide film before forming the crystal part,
wherein the crystal part is formed over the amorphous metal oxide film in forming the crystal part, and
wherein the amorphous metal oxide film is crystallized to form the metal oxide layer in forming the crystalline metal oxide layer.

4. The method for forming a metal oxide layer according to claim 1,
wherein the metal oxide layer is formed by an atomic layer deposition method, and
wherein a substrate heating temperature is higher than or equal to 100° C. and lower than or equal to 300° C.

5. The method for forming a metal oxide layer according to claim 1,
wherein the metal oxide layer is formed by an atomic layer deposition method, and
wherein a substrate heating temperature is higher than or equal to 150° C. and lower than or equal to 250° C.

6. A method for forming a metal oxide layer, comprising the steps of:
forming a crystal part over an insulating layer; and
forming a crystalline metal oxide layer over the crystal part,
wherein the metal oxide layer comprises indium, and
wherein a top surface of the insulating layer is planarized by a chemical mechanical polishing method before forming the crystalline metal oxide layer to make an average roughness of the top surface of the insulating layer greater than or equal to 0 nm and less than 3 nm.

7. The method for forming a metal oxide layer according to claim 6, wherein crystal growth in a lateral direction is performed in the metal oxide layer on or after forming the crystalline metal oxide layer.

8. The method for forming a metal oxide layer according to claim 6, wherein in forming the crystal part, a film to be the crystal part is formed and processed by a wet etching method to form the crystal part.

9. The method for forming a metal oxide layer according to claim 6, wherein a crystal orientation of a crystal grain included in the metal oxide layer is <111>.

10. The method for forming a metal oxide layer according to claim 9, wherein a crystal orientation of the crystal part is <001>.

11. The method for forming a metal oxide layer according to claim 9,
wherein the crystal part comprises indium, gallium, and zinc, and
wherein the crystal part has an atomic ratio of In:Ga:Zn=1:1:1 or in the neighborhood thereof or an atomic ratio of In:Ga:Zn=1:3:2 or in the neighborhood thereof.

12. The method for forming a metal oxide layer according to claim 6, wherein a crystal orientation of a crystal grain included in the metal oxide layer is aligned or substantially aligned with a crystal orientation of the crystal part.

13. The method for forming a metal oxide layer according to claim 12, wherein the crystal part comprises indium.

14. A method for manufacturing a semiconductor device, comprising the steps of:
forming a crystal part over a first insulating layer;
forming a crystalline metal oxide layer using the crystal part as a nucleus;
processing the metal oxide layer into an island shape;
forming a second insulating layer covering the metal oxide layer;
forming an opening portion overlapping with the metal oxide layer in the second insulating layer;
forming a third insulating layer in the opening portion; and
forming a conductive layer over the third insulating layer,
wherein the metal oxide layer comprises indium.

15. The method for manufacturing a semiconductor device according to claim 14, wherein the crystal part is formed from one of grains of a polycrystalline film in forming the crystal part.

16. The method for manufacturing a semiconductor device according to claim 14,
wherein the metal oxide layer is formed by an atomic layer deposition method, and
wherein a substrate heating temperature is higher than or equal to 100° C. and lower than or equal to 300° C.

17. The method for manufacturing a semiconductor device according to claim 14,
wherein the metal oxide layer is formed by an atomic layer deposition method, and
wherein a substrate heating temperature is higher than or equal to 150° C. and lower than or equal to 250° C.

18. The method for manufacturing a semiconductor device according to claim 14, wherein a crystal orientation of a crystal grain included in the metal oxide layer is <111>.

19. The method for manufacturing a semiconductor device according to claim 18, wherein a crystal orientation of the crystal part is <001>.

20. The method for manufacturing a semiconductor device according to claim 18,
wherein the crystal part comprises indium, gallium, and zinc, and
wherein the crystal part has an atomic ratio of In:Ga:Zn=1:1:1 or in the neighborhood thereof or an atomic ratio of In:Ga:Zn=1:3:2 or in the neighborhood thereof.

21. The method for manufacturing a semiconductor device according to claim 14, wherein a crystal orientation of a crystal grain included in the metal oxide layer is aligned or substantially aligned with a crystal orientation of the crystal part.

22. The method for manufacturing a semiconductor device according to claim 21, wherein the crystal part comprises indium.

23. The method for forming a metal oxide layer according to claim 1, wherein a crystal orientation of a crystal grain included in the metal oxide layer is <111>.

24. The method for forming a metal oxide layer according to claim 23, wherein a crystal orientation of the crystal part is <001>.

25. The method for forming a metal oxide layer according to claim 23,
wherein the crystal part comprises indium, gallium, and zinc, and
wherein the crystal part has an atomic ratio of In:Ga:Zn=1:1:1 or in the neighborhood thereof or an atomic ratio of In:Ga:Zn=1:3:2 or in the neighborhood thereof.

26. The method for forming a metal oxide layer according to claim 1, wherein a crystal orientation of a crystal grain included in the metal oxide layer is aligned or substantially aligned with a crystal orientation of the crystal part.

27. The method for forming a metal oxide layer according to claim 26, wherein the crystal part comprises indium.
